(19) United States
(12) Patent Application Publication
(10) Pub. No.: US 2022/0376181 A1
(43) Pub. Date: Nov. 24, 2022

(54) ORGANIC SEMICONDUCTOR DEVICE

(71) Applicant: RAYNERGY TEK INCORPORATION, Hsinchu (TW)

(72) Inventors: YI-MING CHANG, HSINCHU (TW); KUEN-WEI TSAI, HSINCHU (TW); JHAO-LIN WU, HSINCHU (TW); WEI-LONG LI, HSINCHU (TW); YU-TANG HSIAO, HSINCHU (TW); CHUANG-YI LIAO, HSINCHU (TW)

(21) Appl. No.: 17/482,868

(22) Filed: Sep. 23, 2021

(30) Foreign Application Priority Data
Apr. 29, 2021 (TW) 110115650

(51) Int. Cl. H01L 51/00

(52) U.S. Cl. CPC H01L 51/0036; H01L 51/0074; H01L 51/0068; H01L 51/0046; H01L 51/0052; H01L 2251/552; H01L 51/5004

(57) ABSTRACT

An organic semiconductor device is revealed. The organic semiconductor device includes a first electrode, an electron transport layer, an active layer, a hole transport layer, and a second electrode. The active layer includes an electron donor and at least one electron acceptor. The energy barrier between HOMO level of the electron donor and the energy level of PEDOT:PSS or derivatives in the electron transport layer is less than 0.4 eV. The use of the organic semiconductor device and a formulation of materials for the active layer are also disclosed.

### BACKGROUND OF THE INVENTION

### Technical Field

The present invention relates to an organic semiconductor device, especially to an organic semiconductor device composed of electrodes, an electron transport layer, an active layer, and a hole transport layer and having mixing conditions of specific compounds and use of the same.

### Background

It has been thirty years since the first organic photodiode has been developed. In recent years, the electronic products have been widely used and a plurality of devices have been changed into electronic design for compact volume and light weight. To reduce the cost and achieve the product diversification, organic semiconductor materials have been developed and such materials have wide range of applications in different types of devices or equipment. The most common ones include organic field-effect transistors (OFET), organic light emitting diodes (OLED), organic photovoltaic (OPV) cells, sensors, memory elements, and logic circuits. The optimal power conversion efficiency (PCEs) of the OPV devices available now is up to 17%. Such breakthrough shows promising future of the research in the field. Compared with monotonic design of the conventional photodiode, OPV and organic photodetector (OPD) have excellent energy harvesting and optical sensing properties, thus providing high degree of design freedom.

In order to get OPV or OPD with high performance, stability and high cost performance ratio, the strategy now is to use new materials and optimized architecture. As to new materials, now conjugated polymers have been applied to OPV. The advantage of the conjugated polymers is in that they cancan be dissolved in solvents and treated by solvent processing techniques such as rotary casting, dip coating or inkjet printing to produce devices and further achieve high-speed mass production. Compared with the conventional techniques which use inorganic materials to produce inorganic films by evaporation, conjugated polymers are more excellent. Non-fullerene materials are materials for next generation OPV and OPD. This type of material can expand absorption spectrum by adjustment of energy level and further increase short-circuit current density and spectra responsivity. Or the built-in voltage is increased to enhance the open-circuit voltage (Voc).

In terms of optimized architecture, an inverted architecture is introduced in designing the devices. Compared with structure of the conventional organic semiconductor, electrodes on two sides are displaced to prevent ITO used as the electrode from contacting with poly(styrenesulfonate (PEDOT:PSS) on the inner layer directly and further avoids corrosion of the ITO caused by acid poly(styrenesulfonate (PEDOT:PSS) for increasing stability of the device. Moreover, unstable materials are also replaced. To reduce the cost as much as possible, the production is carried out by solvent processing at room temperature. Thus poly(3,4-ethylenedioxythiophene)-poly(styrenesulfonate (PEDOT:PSS) is a representative material used in solvent processing for production and broadly applied worldwide since the material is able to be dispersed in water. Owing to stable dispersion of PEDOT:PSS in water, it can be directly arranged over bulk heterojunction (BHJ) structure without affecting the film on the bottom layer. Thus PEDOT:PSS is widely used in OPV and OPD devices and compatible with mixtures of photoactive layer available on the market.

However, most of highly efficient non-fullerene based OPV and OPD are applied to conventional structure or molybdenum trioxide (MoO₃) is used to form the hole transport layer in the inverted structure by thermal evaporation. In view of the development strategy, a novel combination of wide-bandgap polymer donors with small gap non-fullerene acceptors (NFAs) has a higher power conversion efficiency (PCE). The optimal polymer donor used in combination with NFAs available now requires a low HOMO (highest occupied molecular orbital) level whose negative value is larger than −5.4 eV for maximizing the built-in voltage of the device. Thus there is a large energy barrier between HOMO level of the electron donor and the work function (WF, about −5.0 eV in most papers) of PEDOT:PSS due to low HOMO level of the active layer. Therefore, the inverted device has rather poor electrical performance.

The PCE of OPV can be further improved by adjusting the combinations of energy levels of the materials and interface properties between the respective layers. Thus the research focused on combinations of the materials in the inverted structure has received great attentions. Yet there is a high energy barrier existing between materials for the electron transport layer and electron donor polymers in common use now and this significantly affects electrical properties/performance of the device. This means that the device can't make full use of the material properties when PEDOT:PSS used in the field is combined with electron donors having deeper HOMO level.

Therefore, there is a need to provide a material for the hole transport layer able to be treated by solvent processing and used in combination with PEDOT:PSS for maximizing material performance in order to promote industrialization of OPV/OPD technology. It should be noted that the work function of the hole transport layer and the HOMO level of electron donors should be matched.

### SUMMARY OF THE INVENTION

The primary object of the present invention to provide an organic semiconductor device which addresses energy barrier issue between the HOMO of electron donors and the work function of PEDOT:PSS in the organic semiconductor device for improving electrical properties and lifetime of the semiconductor device.

Another object of the present invention is to provide a formulation of materials for an organic semiconductor device not only used for providing electrical properties required but also able to be dissolved in organic solvents used in wet processes for manufacturing.

To achieve the above main object, the present invention discloses an organic semiconductor device, comprising a substrate, a first electrode, an electron transport layer disposed on the first electrode, an active layer disposed on the electron transport layer, a hole transport layer disposed on the active layer and containing a compound selected from PEDOT:PSS or the derivatives thereof, and a second electrode disposed on the hole transport layer, wherein the active layer comprises an electron donor and at least one electron acceptor, and the energy barrier between HOMO level of the electron donor and the energy level of the electron transport layer is less than 0.4 eV.

In a preferred embodiment, the electron donor in the organic semiconductor device is a conjugated polymer formed by at least two monomers, a first monomer and a second monomer.

In a preferred embodiment, the first monomer of the electron donor in the organic semiconductor device is selected from the group consisting of the following moieties: a benzodithiophene moiety, a carbazole moiety, a silylpentadithiophene moiety, a thiophene moiety, a cyclopentadithiophene moiety, a selenophene moiety, a dithieno[3,2-b:2′,3′-d]pyrrole (DTP) moiety, a cyclopentadithiazole moiety, and a dibenzosilazole moiety.

In a preferred embodiment, the second monomer of the electron donor in the organic semiconductor device is selected from the group consisting of the following moieties: a thiadiazolebenzothiadiazole moiety, a thiadiazoloquinoxaline moiety, a benzoisothiazole moiety, a benzothiazole moiety, a thienothiophene moiety, a tetrahydroisoindole moiety, a thiazolothiazole moiety, a thienopyrazine moiety, a benzoxazole moiety, a quinoxaline moiety, a thiadiazolepyridine moiety, a benzoxadiazole moiety, a benzoselenadiazole moiety, a thienothiadiazole moiety, a thienopyridone moiety, a benzodithiophenedione (BDD) moiety, and a pyrazine moiety.

In a preferred embodiment, the electron donor in the organic semiconductor device is selected from the group consisting of the following chemical structures D1-D25.

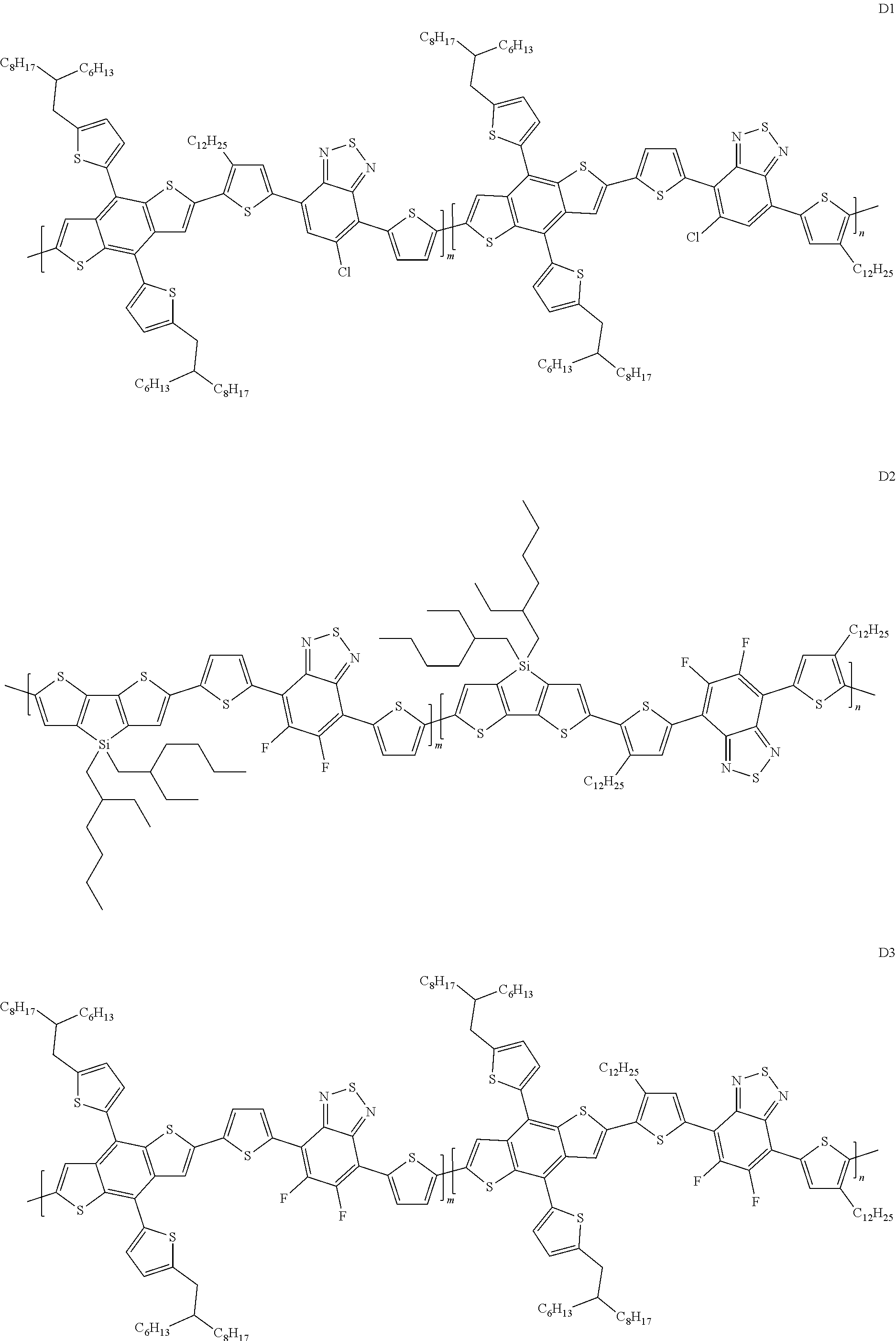

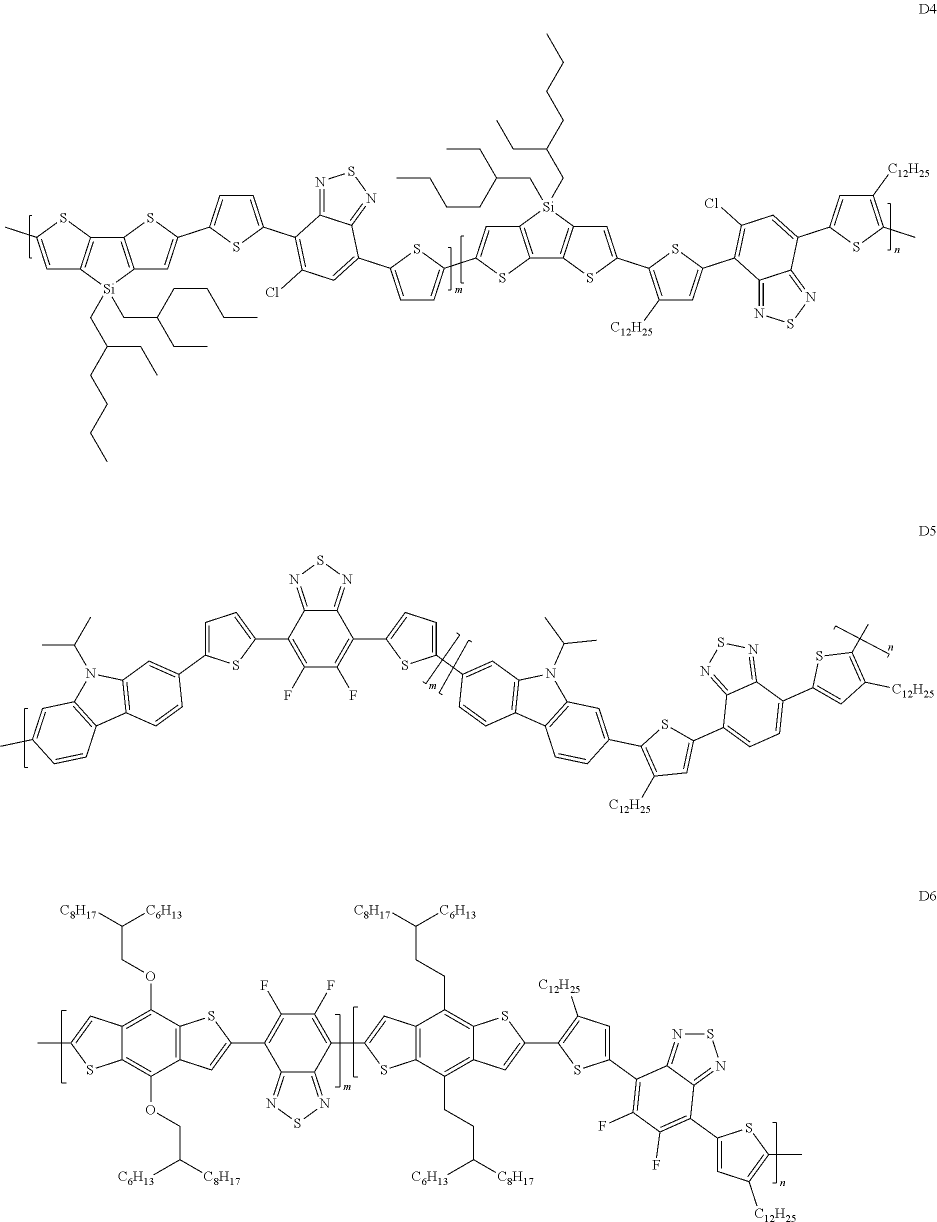

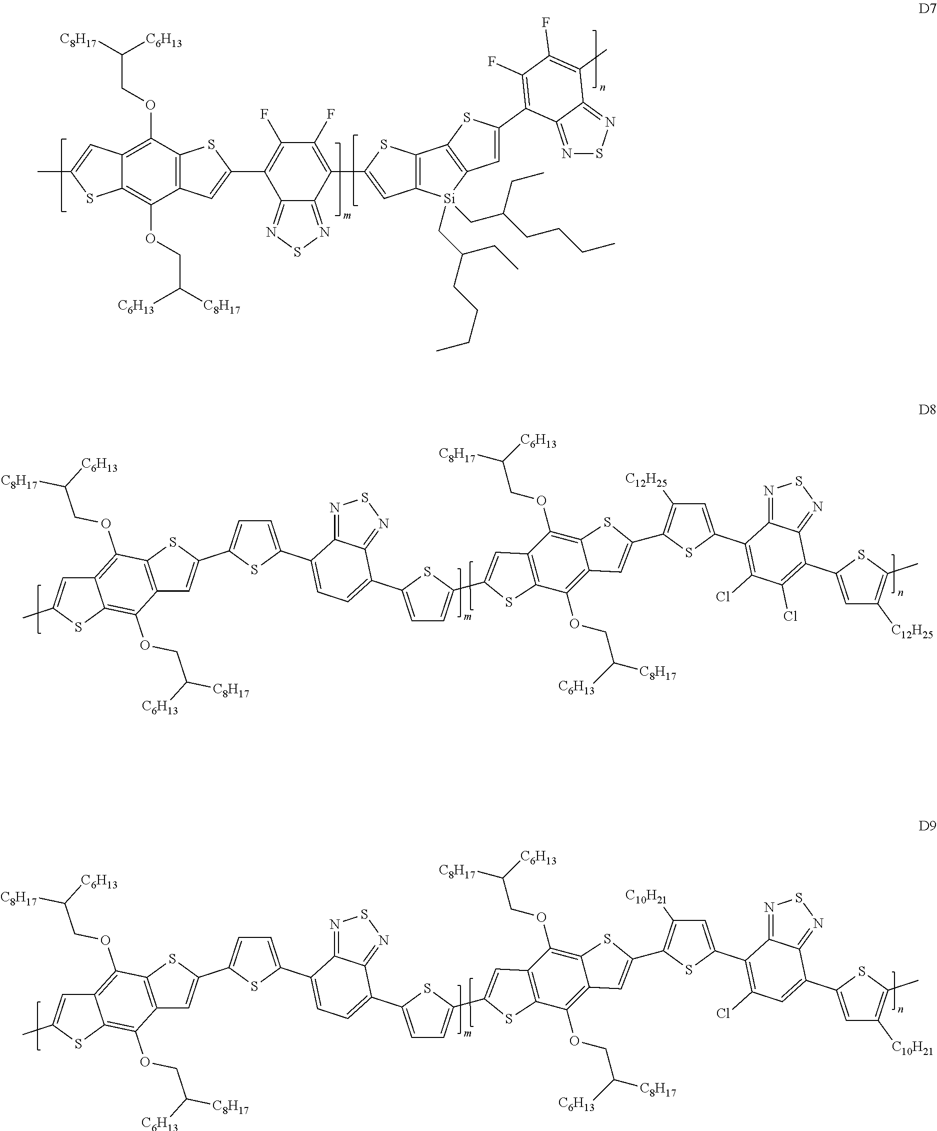

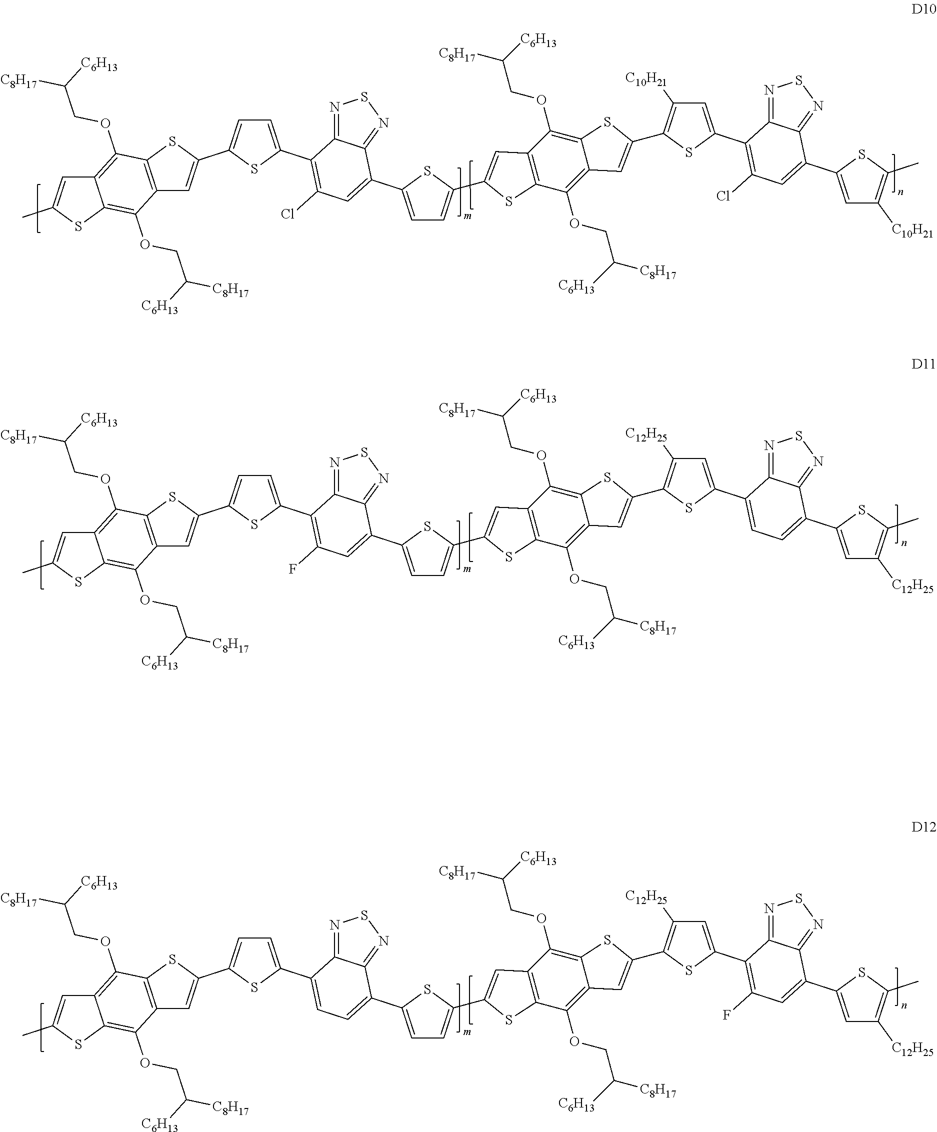

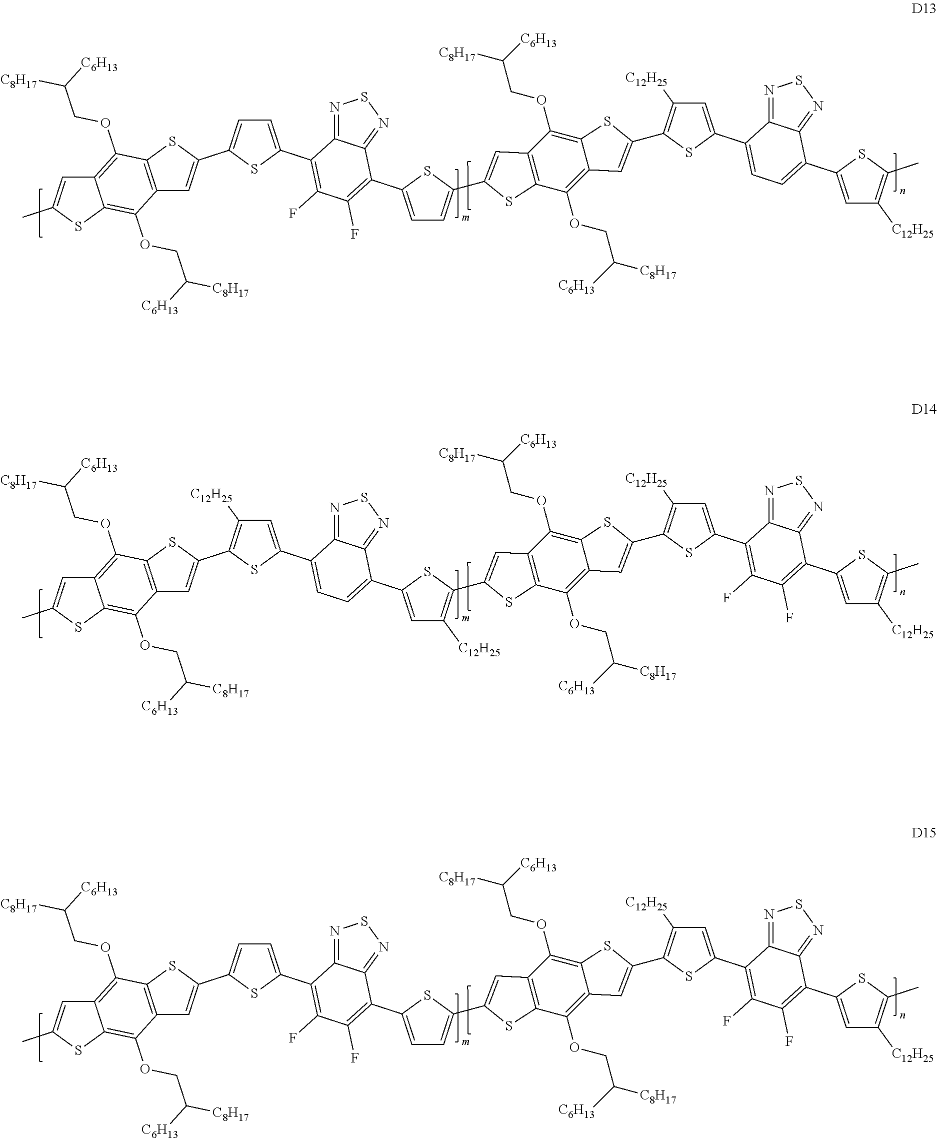

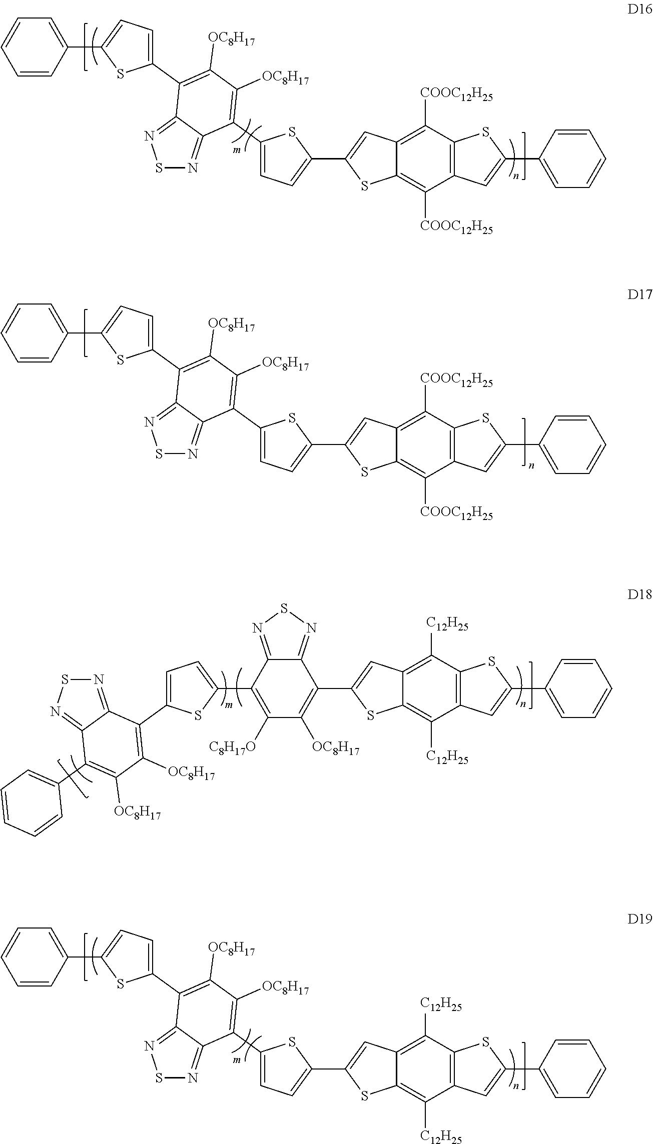

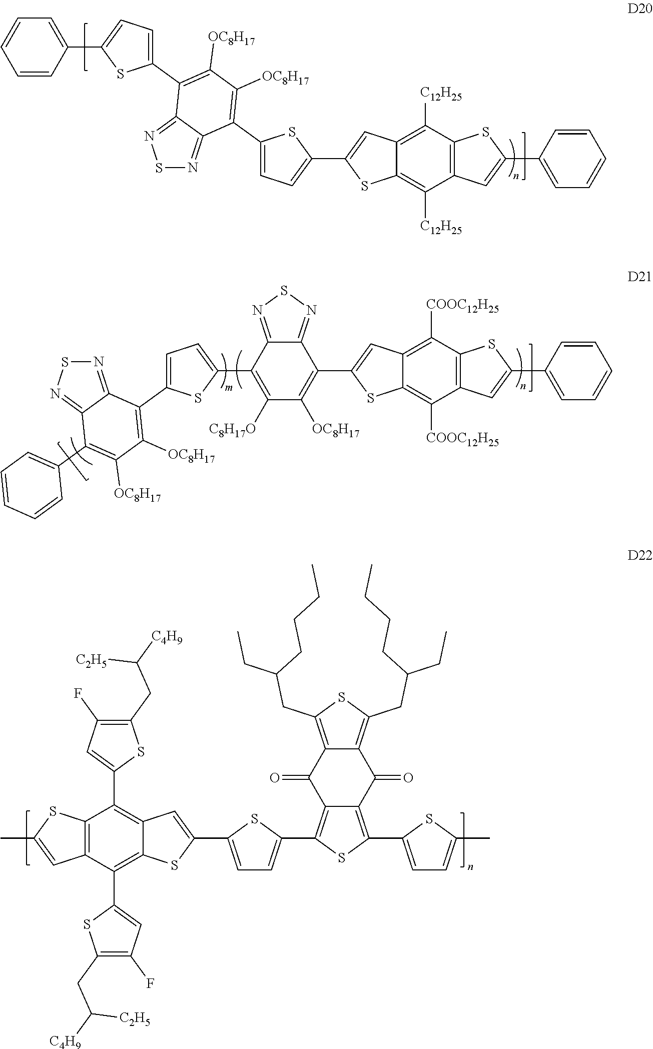

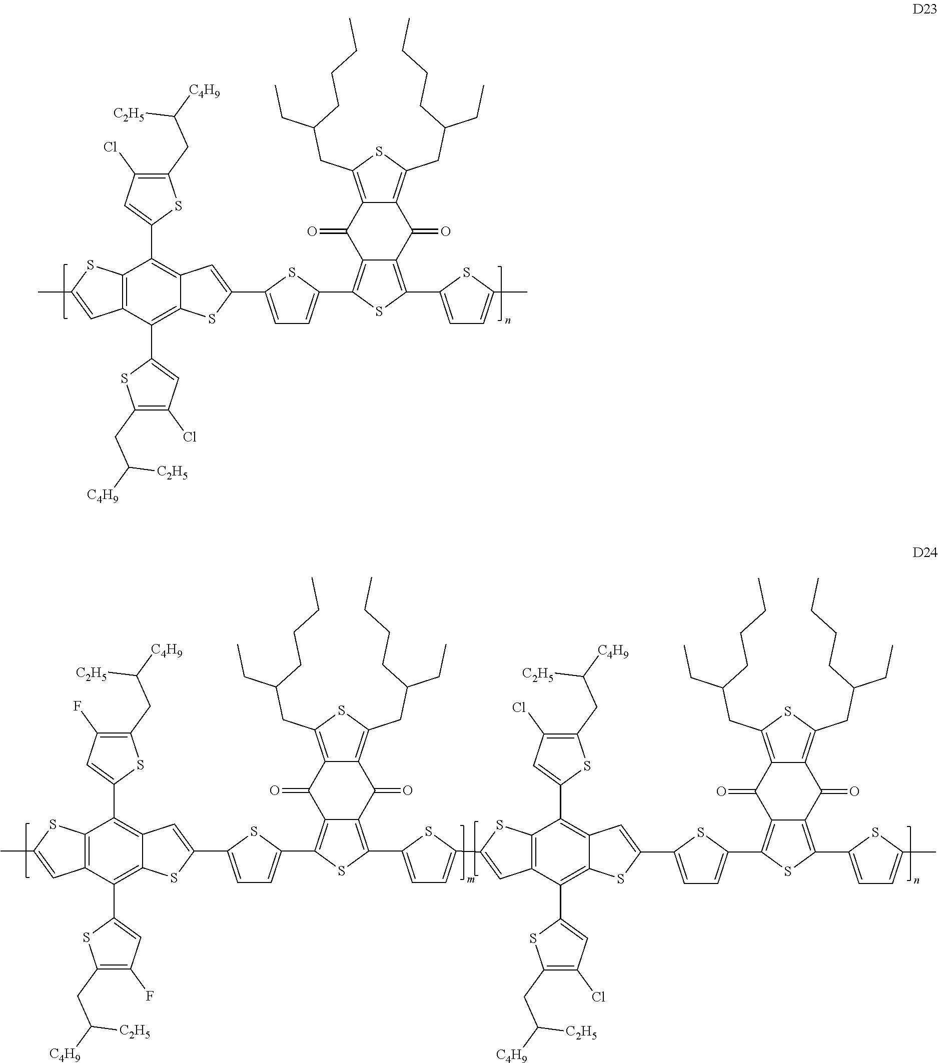

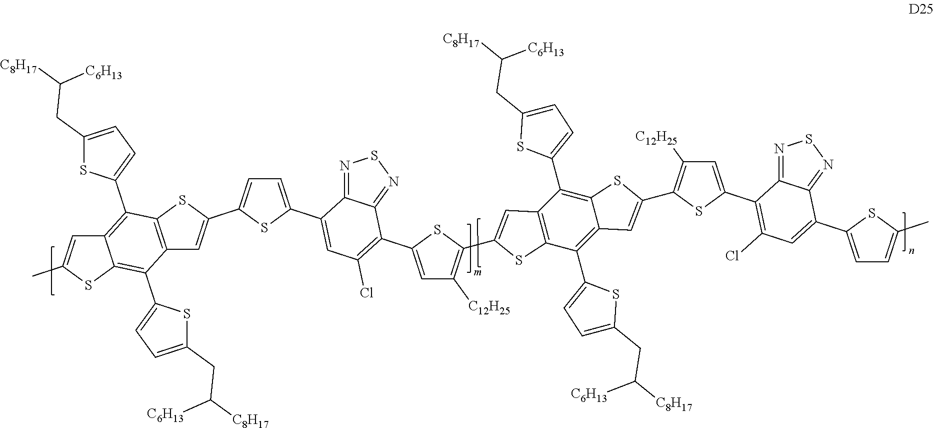

In a preferred embodiment, the electron acceptor of the organic semiconductor device includes a first electron acceptor and a second electron acceptor.

In a preferred embodiment, the first electron acceptor of the organic semiconductor device is selected from the group consisting of the following chemical structures A1-A25:

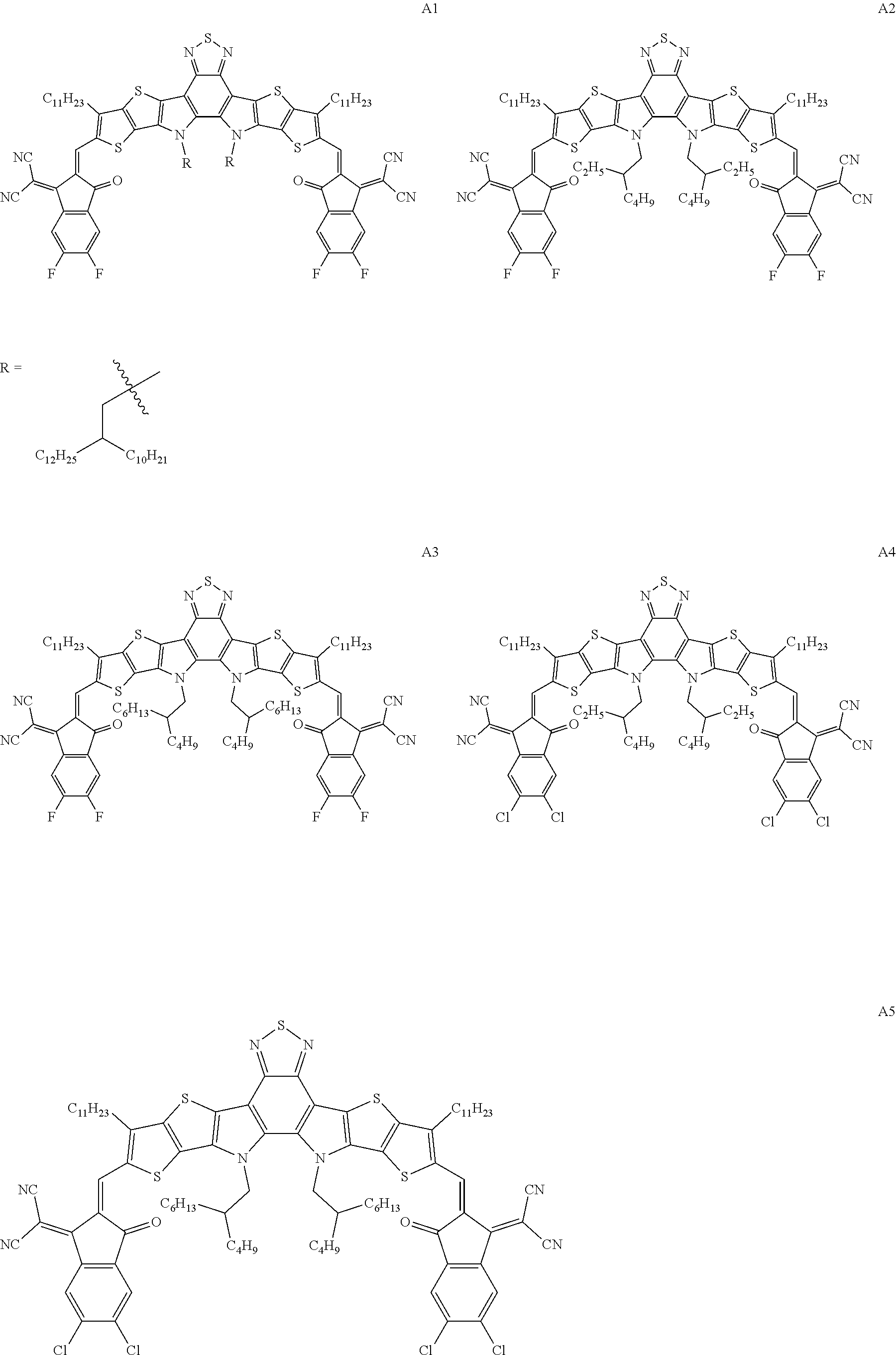

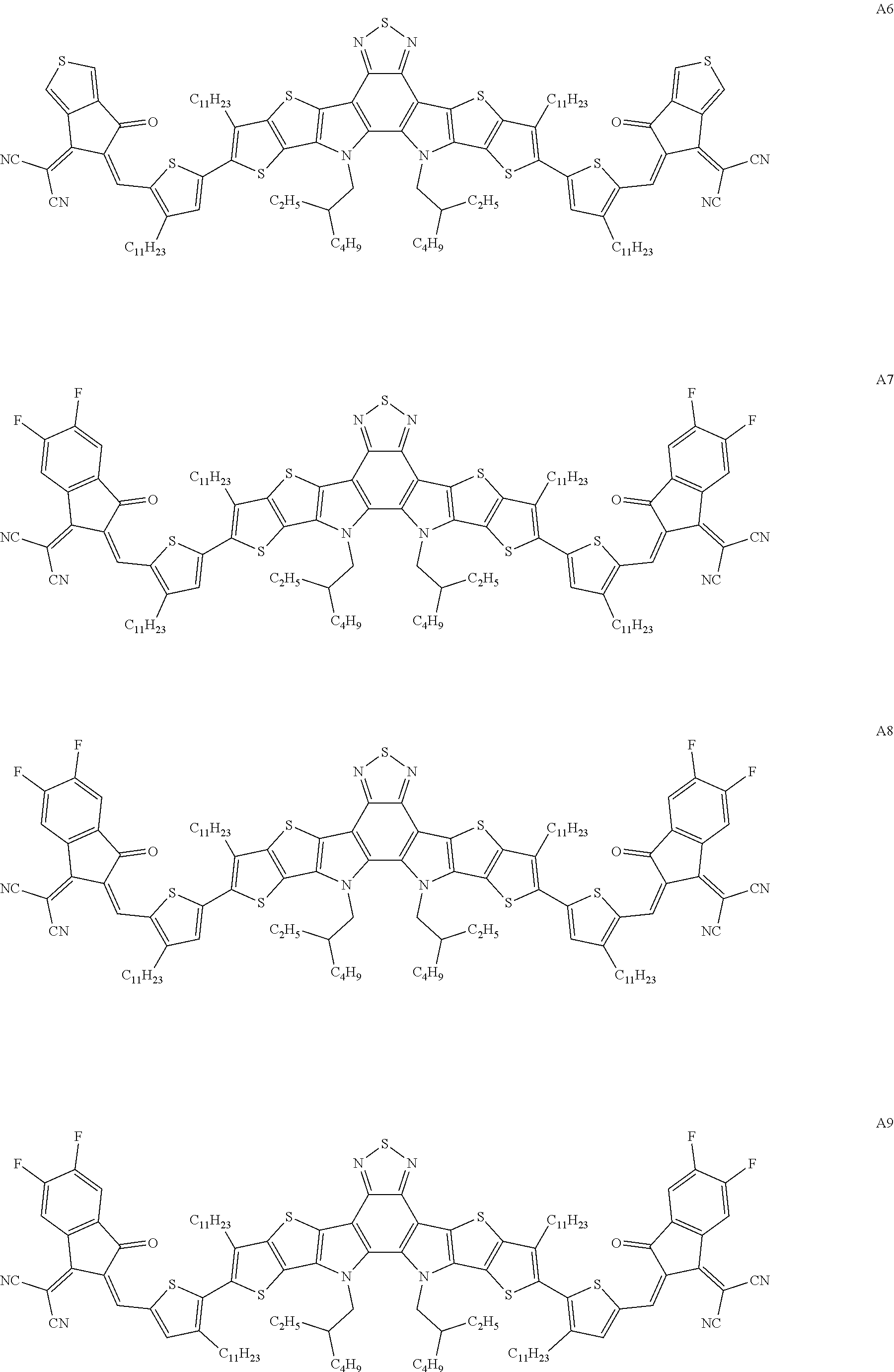

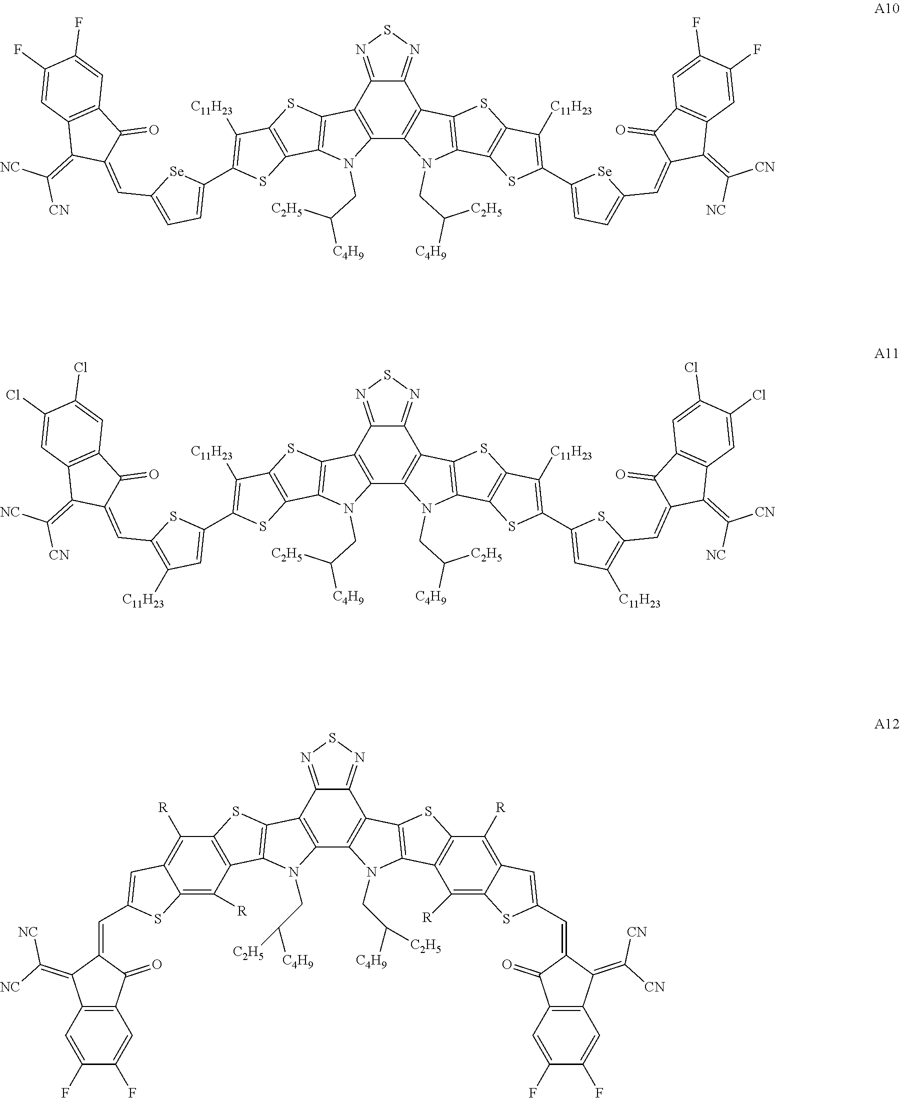

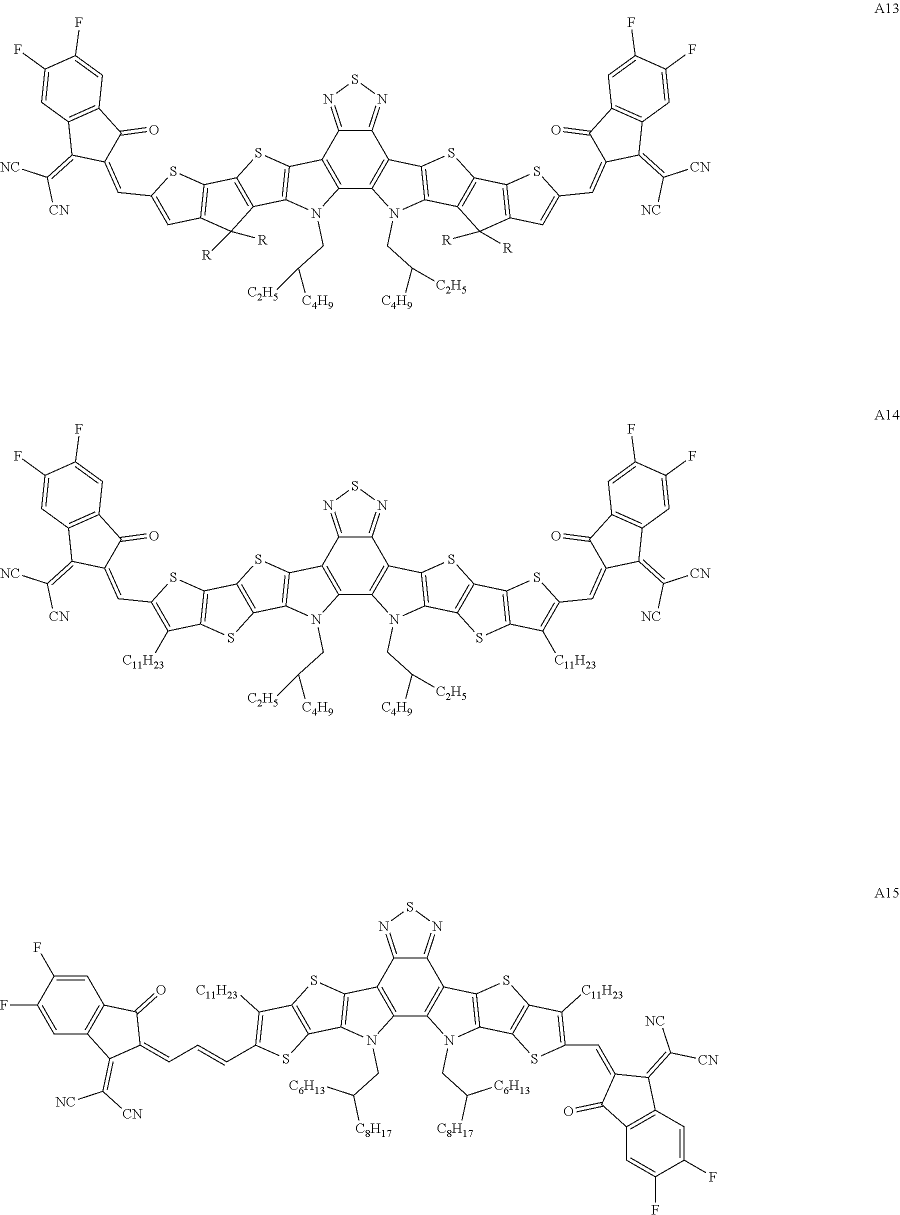

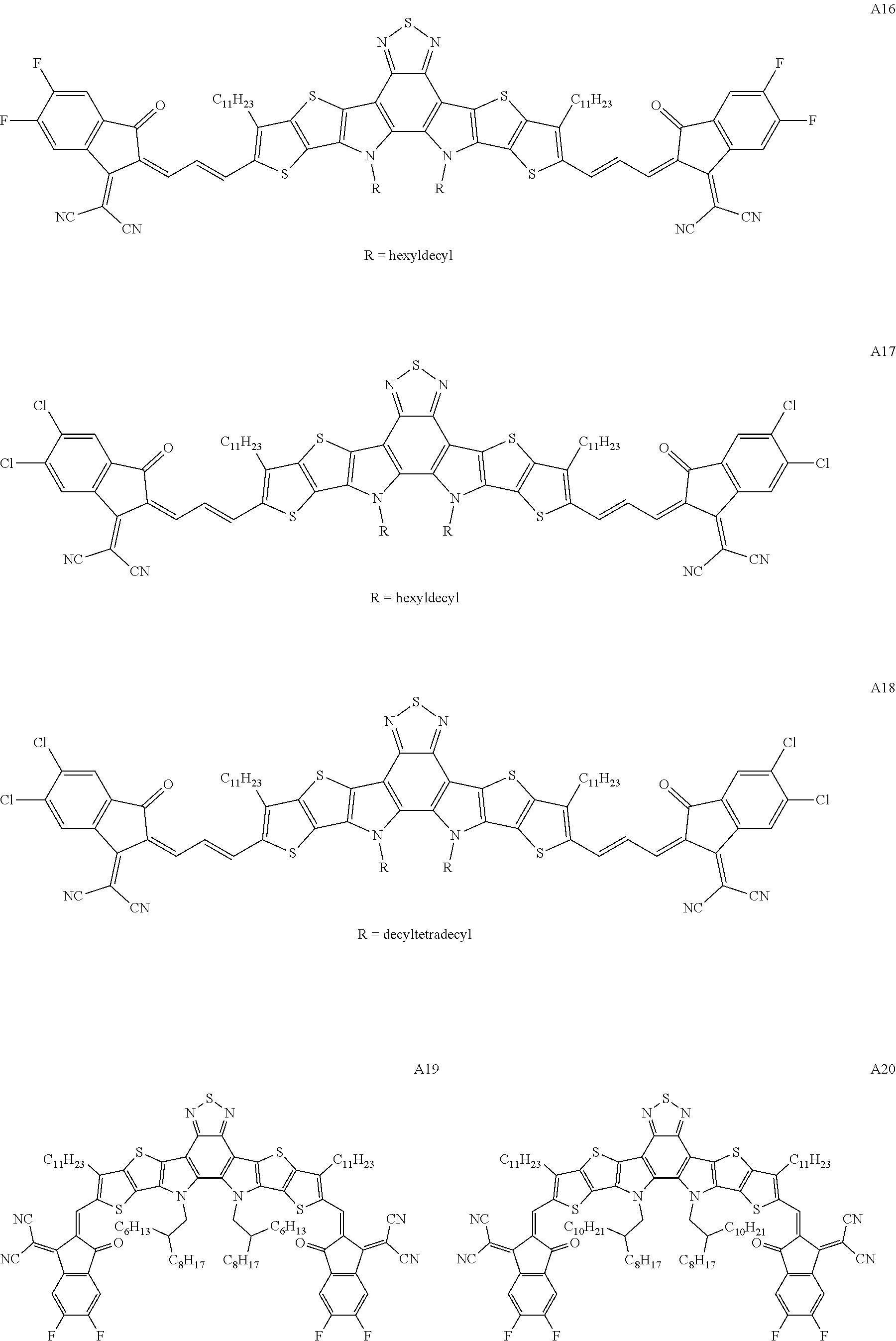

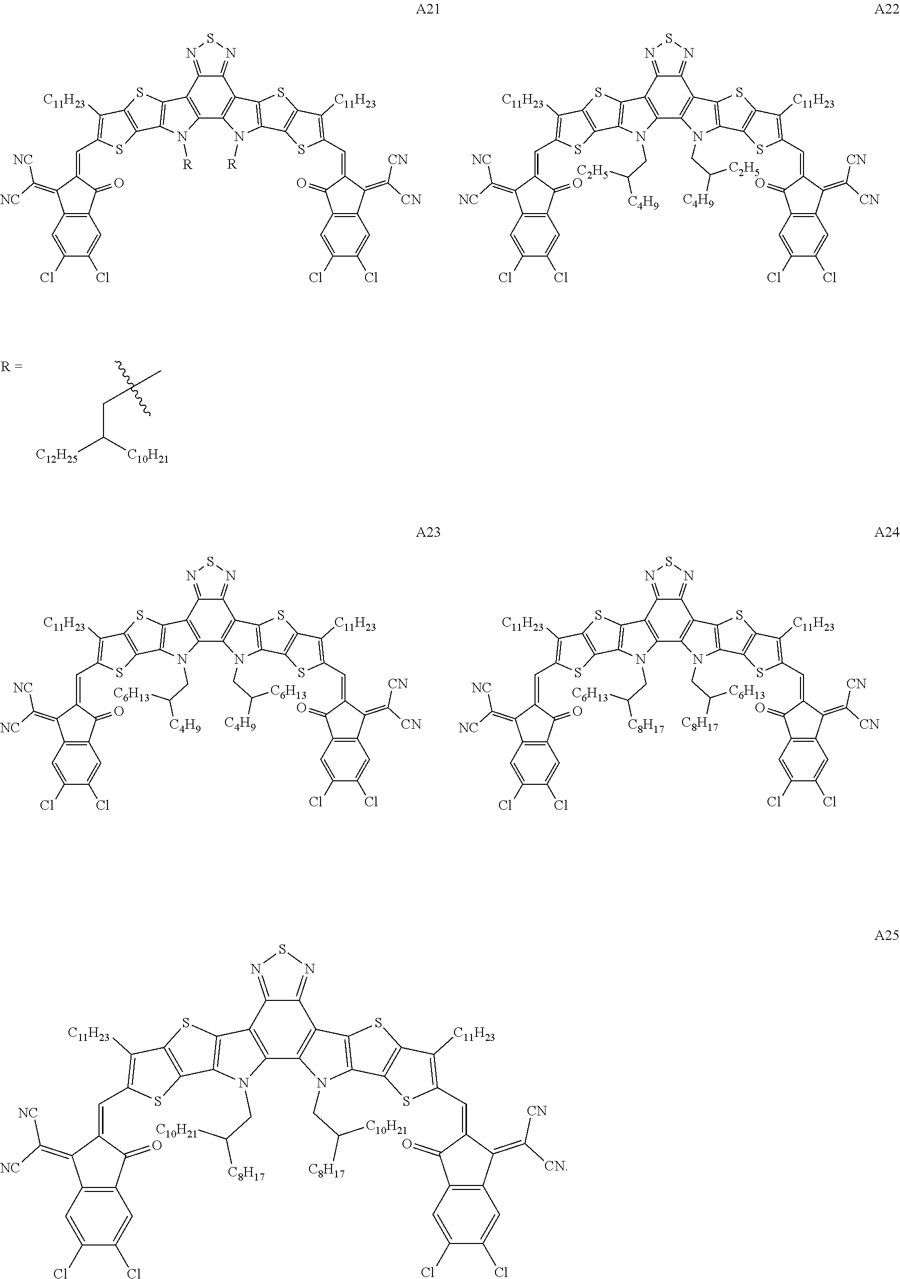

In a preferred embodiment, the second electron acceptor of the organic semiconductor device is selected from the group consisting of the following chemical structures A26-A40:

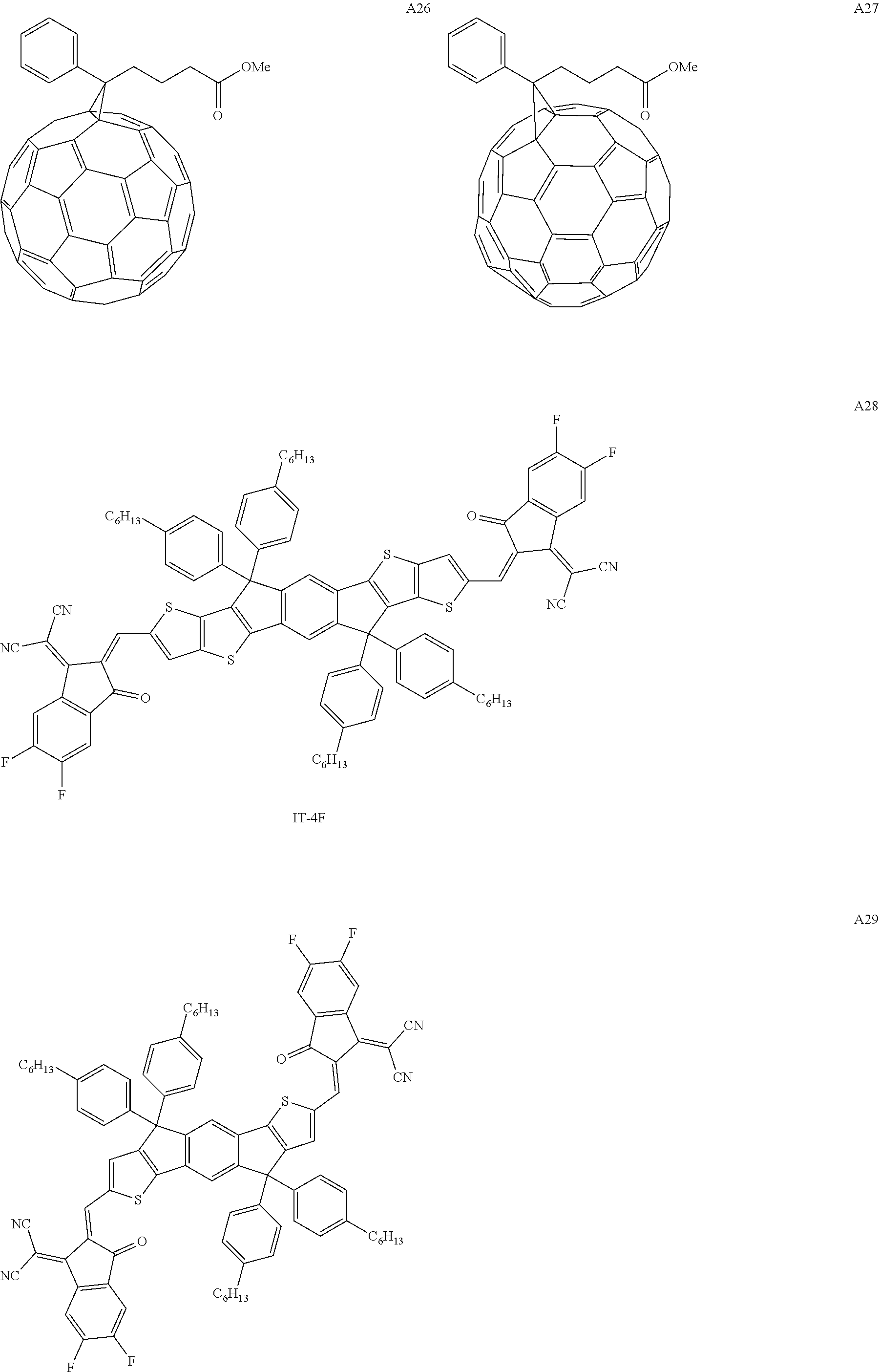

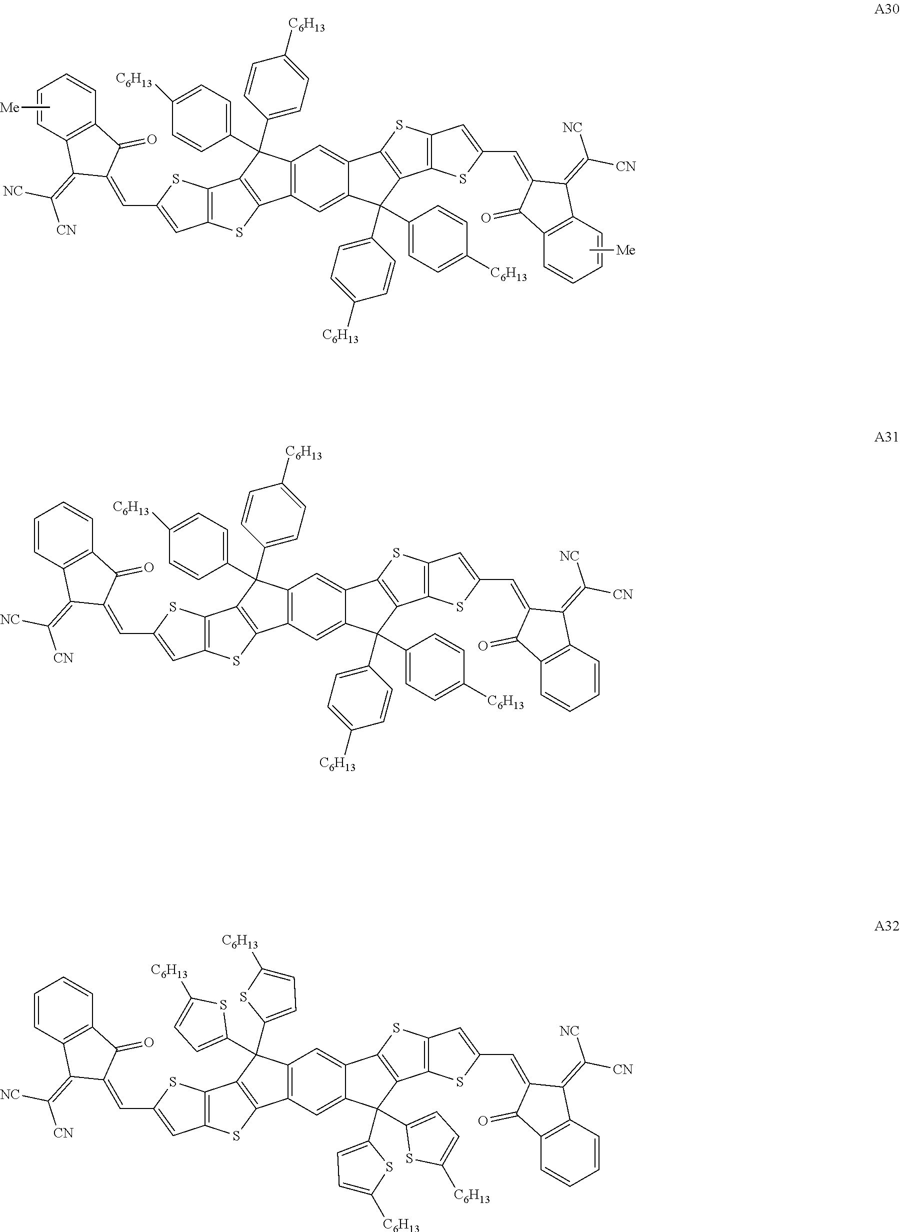

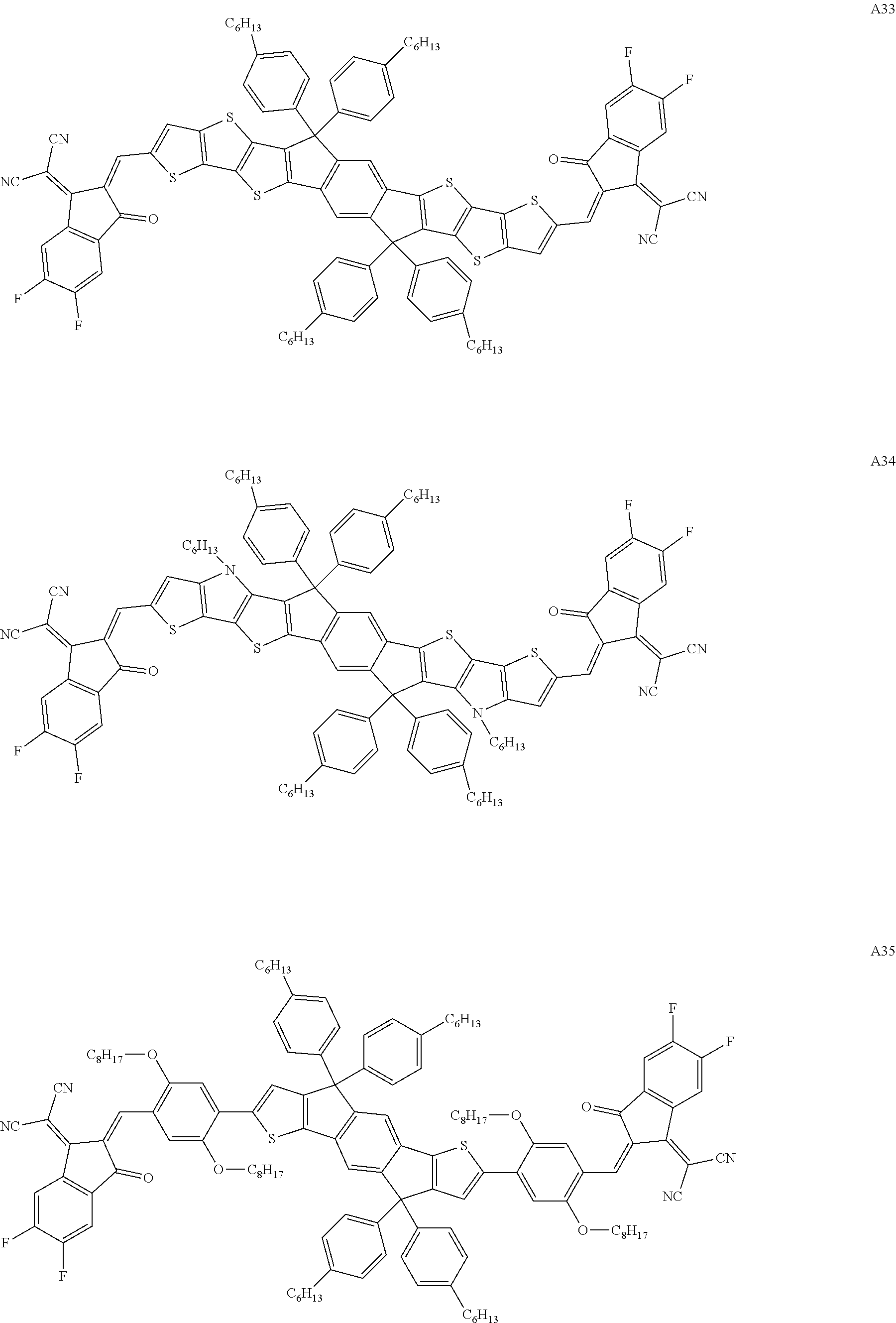

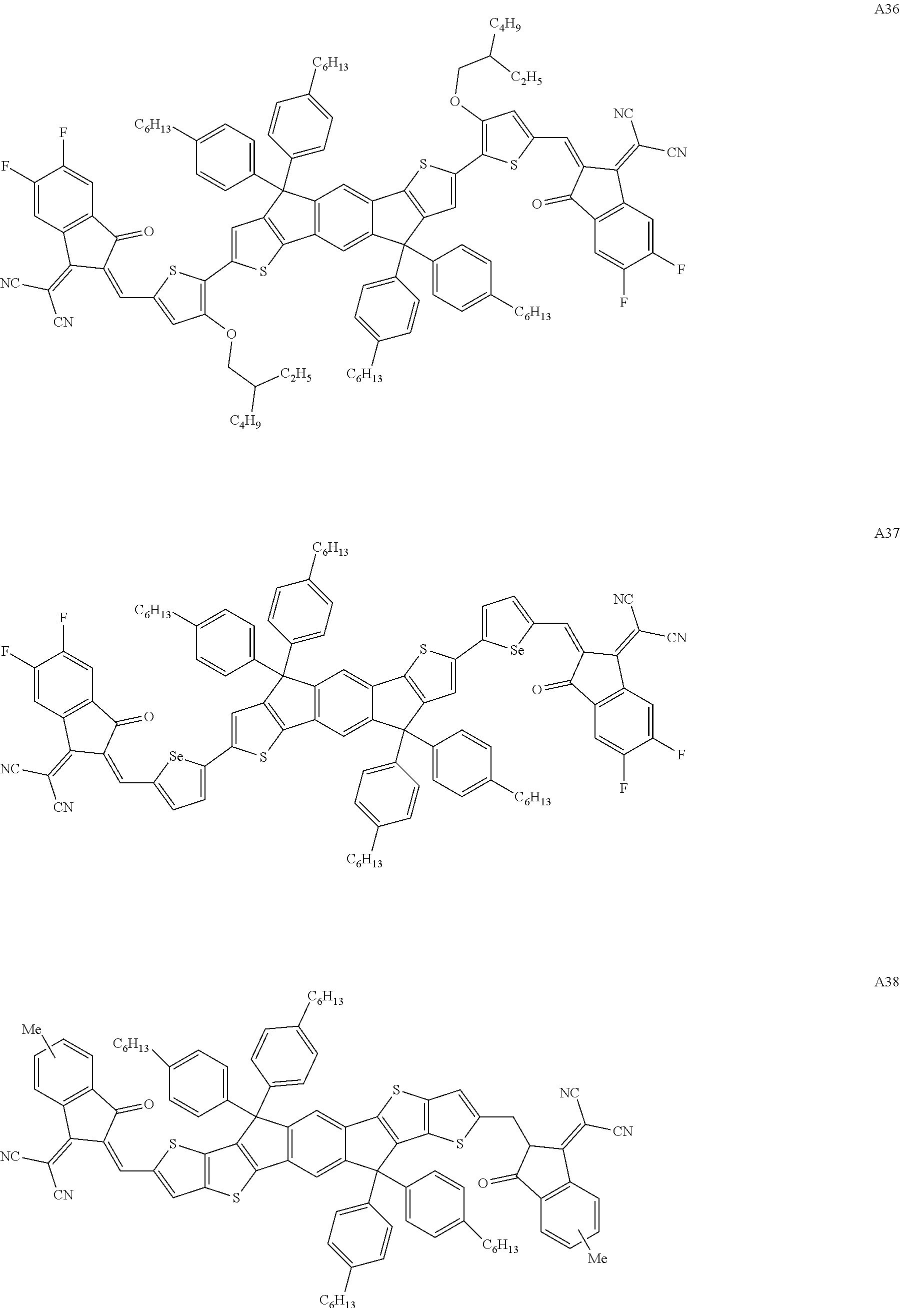

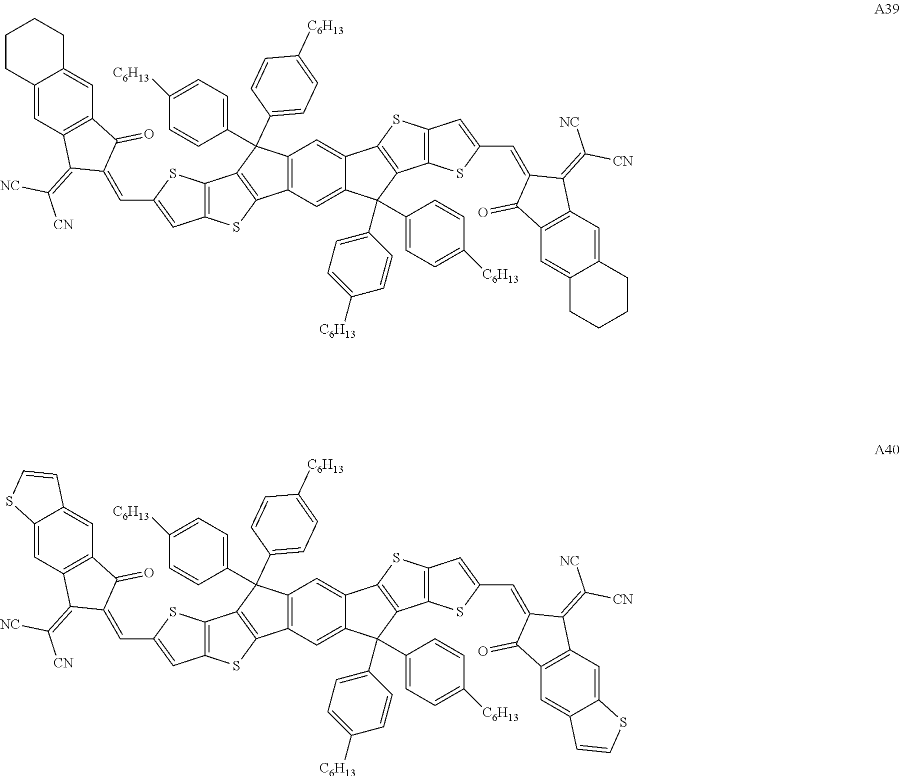

In a preferred embodiment, the weight ratio of the second electron acceptor is less than the weight ratio of the first electron acceptor in the organic semiconductor device.

In a preferred embodiment, the hole transport layer of the organic semiconductor device is prepared by wet processes.

In a preferred embodiment, the electron donor of the organic semiconductor device has a band gap greater than 1.50 eV, and the band gap of the first electron acceptor is less than 1.49 eV.

In a preferred embodiment, the organic semiconductor device is selected from organic field-effect transistor (OFET), integrated circuit (IC), thin-film transistor (TFT), radio frequency identification (RFID) tags, organic light-emitting diode (OLED), organic light-emitting transistor (OLET), electroluminescent display (ELD), organic photovoltaic (OPV) cells, organic solar cells (OSC), flexible OPV and OSC, organic laser diodes (O-laser), organic integrated circuit (OIC), light devices, sensors, electrode materials, photoconductors, light sensors, electro-optical recording devices, capacitors, charge injection layers, Schottky diodes, planarization layers, antistatic films, conductive substrates, conductive patterns, organic memory, biosensors and biochips.

To achieve the secondary object mentioned above, the present invention discloses a formulation of an organic semiconductor device which comprises the electron donor and the electron acceptor from the above organic semiconductor device and at least one solvent selected from aromatic solvents.

In a preferred embodiment, the aromatic solvent included in the formulation is selected from methylbenzene, ortho-xylene, para-xylene, meta-xylene, trimethylbenzenes, chlorobenzene, dichlorobenzene, trichlorobenzene or tetrahydronaphthalene, anisole, methoxytoluene and its derivatives, naphthalene, 1-methylnaphthalene, and its derivatives.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1a is a schematic drawing showing structure of an embodiment of an organic semiconductor device according to the present invention;

FIG. 1b is a schematic drawing showing structure of another embodiment of an organic semiconductor device according to the present invention;

FIG. 2a shows current density-voltage curves of sample C1 and sample 1 for electrical performance comparison according to the present invention;

FIG. 2b shows current density-voltage curves of sample C2 and sample 2 for electrical performance comparison according to the present invention;

FIG. 2c shows current density-voltage curves of sample C3 and sample 3 for electrical performance comparison according to the present invention; and

FIG. 3 is a result of the service life test of sample 1 according to the present invention.

### DETAILED DESCRIPTION OF THE PREFERRED EMBODIMENT

The term “polymer” used herein is a molecule of high relative molecular mass, the structure of which essentially comprises the multiple repetition of units derived, actually or conceptually, from molecules of low relative molecular mass. The term “oligomer” is a molecule of intermediate relative molecular mass, the structure of which essentially comprises a small plurality of units derived, actually or conceptually, from molecules of lower relative molecular mass (Pure Appl. Chem., 1996, 68, 2289). As to the preferred meaning used herein, polymer is a compound which includes more than 1 (>1), at least 2 repeat units, preferably ≥5 repeat units, and more preferably ≥10 repeat units while the oligomer is a compound which includes >1 and <10 repeat units, preferably <5 repeat units.

Moreover, the term “polymer” used herein means a molecule with a main chain of one or more different repeat units (the smallest constitutional unit), usually including commonly used terms such as oligomer, copolymer, homopolymer, atactic polymer, etc. Further, it is understood that the term polymer is inclusive of, in addition to the polymer itself, residues from initiators, catalysts and other elements attendant to the synthesis of such a polymer, where such residues are understood as not being covalently incorporated thereto. Further, such residues and other elements, while normally removed during post polymerization purification processes, are typically mixed or co-mingled with the polymer such that they generally remain with the polymer when it is transferred between vessels or between solvents or dispersion media.

The terms used herein “repeat units” and “monomer” are used interchangeably and will be understood to mean the constitutional repeating unit (CRU), which is the smallest constitutional unit the repetition of which constitutes a regular macromolecule, a regular oligomer molecule, a regular block, or a regular chain (Pure Appl. Chem., 1996, 68, 2291). As further used herein, the term “unit” will be understood to mean a structural unit which can be a repeating unit on its own or can together with other units form a constitutional repeating unit.

International Union of Pure and Applied Chemistry, Compendium of Chemical Technology, Gold Book, Ver. 2.3.2, 2012 Aug. 19, 477-480. As used herein, the terms “donor” or “donating” and “acceptor” or “accepting” will be understood to mean an electron donor or electron acceptor, respectively. “Electron donor” should be understood to mean a chemical entity that donates electrons to another compound or another group of atoms of a compound. “Electron acceptor” should be understood to mean a chemical entity that accepts electrons transferred to it from another compound or another group of atoms of a compound. See also International Union of Pure and Applied Chemistry, Compendium of Chemical Technology, Gold Book, Version 2.3.2, 2012 Aug. 19, 477-480.

As used herein, the term “n-type” or “n-type semiconductor” is understood to mean an extrinsic semiconductor in which the conduction electron density is in excess of the mobile hole density, and the term “p-type” or “p-type semiconductor” is understood to mean an extrinsic semiconductor in which mobile hole density is in excess of the conduction electron density (see also, J. Thewlis, Concise Dictionary of Physics, Pergamon Press, Oxford, 1973).

As used herein, the term “conjugated” will be understood to mean a compound (such as a polymer) that contains mainly C atoms with sp²-hybridization (or optionally sp-hybridization), and wherein the C atoms may be replaced by hetero atoms. In the simplest case, this is, for example, a compound with alternating C—C single and double (or triple) bonds, or a compound with aromatic groups such as 1,4-phenylene. The term “mainly” in this connection will be understood to mean that a compound with naturally (spontaneously) occurring defects, or with defects included by design, which may lead to interruption of the conjugation, is still regarded as a conjugated compound.

As mentioned above, the organic semiconductor devices used now has great energy barrier between the HOMO level of the electron donor and the work function of PEDOT:PSS due to low HOMO level of the active layer, thus resulting in the poor electrical performance of the inverted device. Through research, it is found that excellent electrical performance/properties may be obtained once the energy barrier between the HOMO level of the electron donor and the energy level of the electron transport layer is less than 0.4 eV. Therefore, an organic semiconductor device with specific combination of semiconductor materials is introduced.

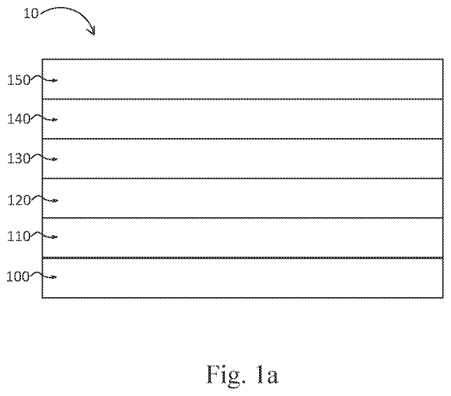

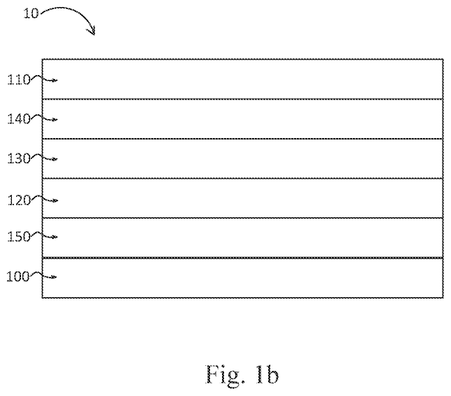

Refer to FIG. 1, a schematic drawing showing structure of an embodiment of the present invention is revealed.

As shown in Figures, an organic semiconductor device 10 according to the present invention includes a substrate 100, a first electrode 110, an electron transport layer 120, an active layer 130, a hole transport layer 140, and a second electrode 150. The first electrode 110 is disposed on the substrate 100 and the electron transport layer 120 is disposed on the first electrode 110. The active layer 130 is disposed on the electron transport layer 120 and the hole transport layer 140 is disposed on the active layer 130 while the second electrode 150 is disposed on the hole transport layer 140.

As the main photoelectric layer, the active layer 130 of the organic semiconductor device 10 includes an electron donor and at least one electron acceptor. The material for the electron donor is a conjugated polymer which is formed by at least two monomers, wherein the monomers comprise a first monomer and a second monomer.

The first monomer of the conjugated polymer is selected from the group consisting of the following moieties: a benzodithiophene moiety, a carbazole moiety, a silylpentadithiophene moiety, a thiophene moiety, a cyclopentadithiophene moiety, a selenophene moiety, a dithieno[3,2-b:2′,3′-d]pyrrole (DTP) moiety, a cyclopentadithiazole moiety, and a dibenzosilazole moiety.

The second monomer of the conjugated polymer is selected from the group consisting of the following moieties: a benzodithiophene moiety, a thiadiazoloquinoxaline moiety, a benzoisothiazole moiety, a benzothiazole moiety, a thienothiophene moiety, a tetrahydroisoindole moiety, a thiazolothiazole moiety, a thienopyrazine moiety, a benzoxazole moiety, a quinoxaline moiety, a thiadiazolepyridine moiety, a benzoxadiazole moiety, a benzoselenadiazole moiety, a thienothiadiazole moiety, a thienopyridone moiety, a benzodithiophenedione (BDD) moiety, and a pyrazine moiety.

In a preferred embodiment, the conjugated polymer which is consisting of polymerization of the above monomers is selected from the group consisting of the following chemical structures D1-D25.

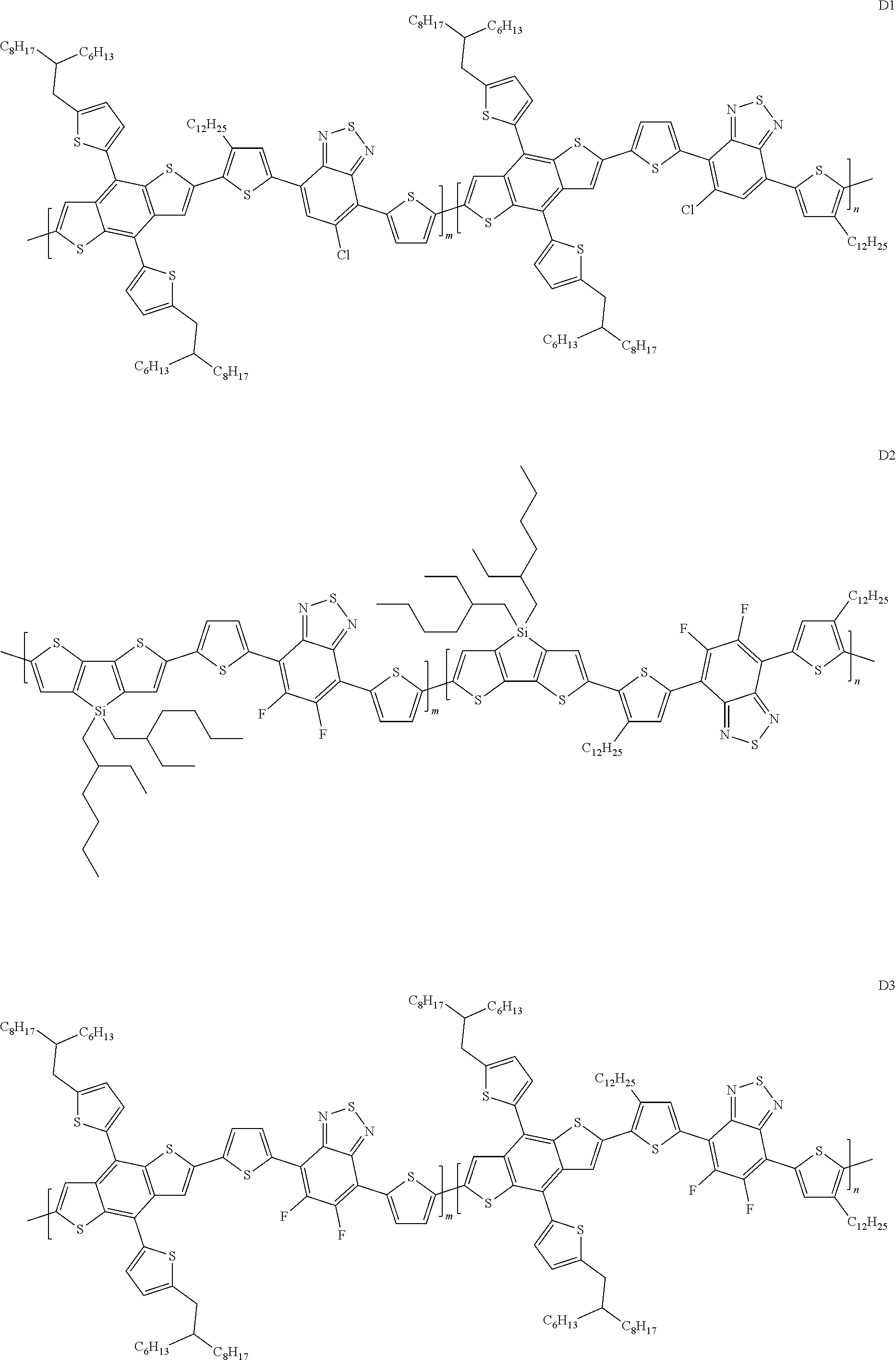

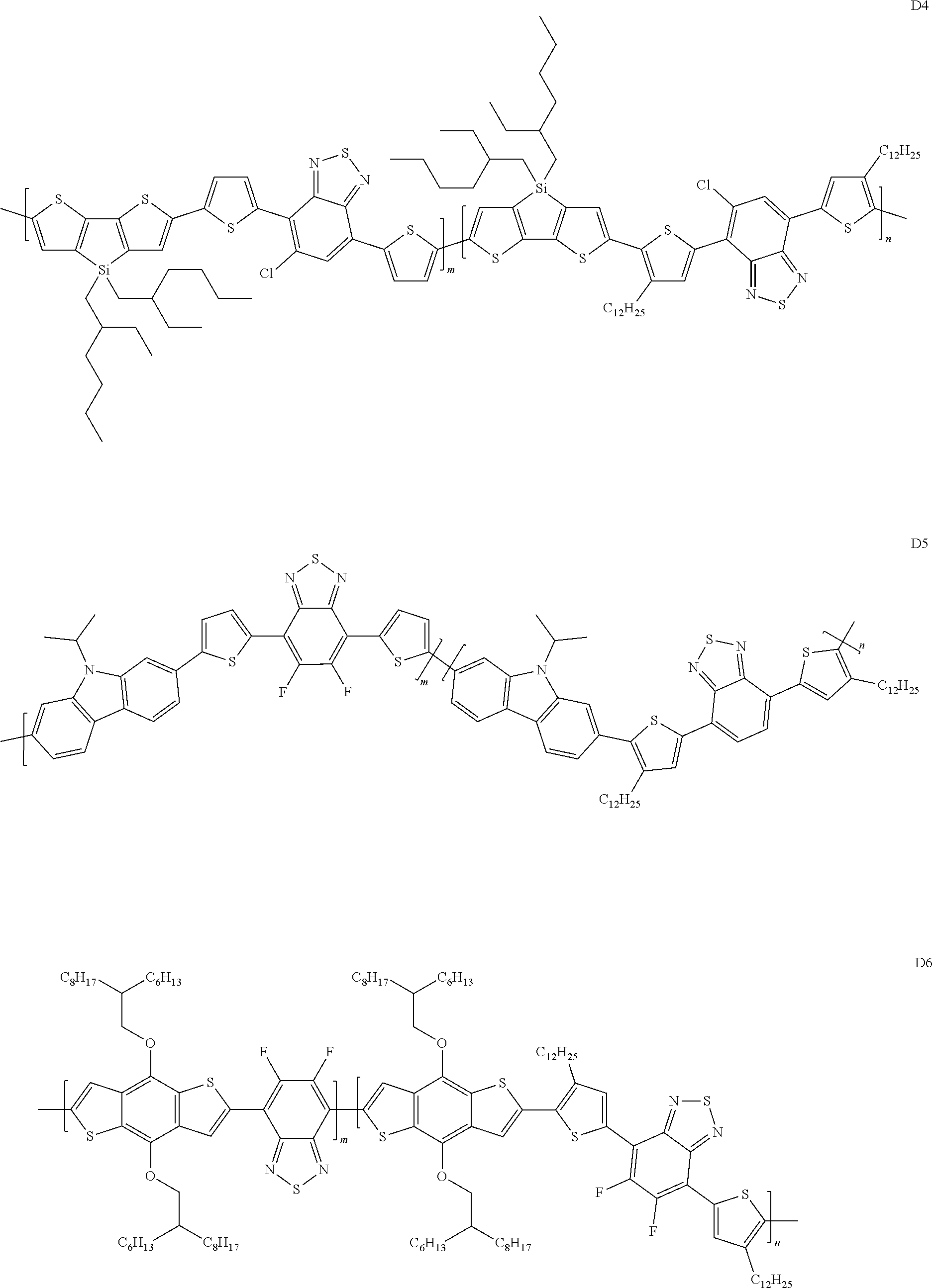

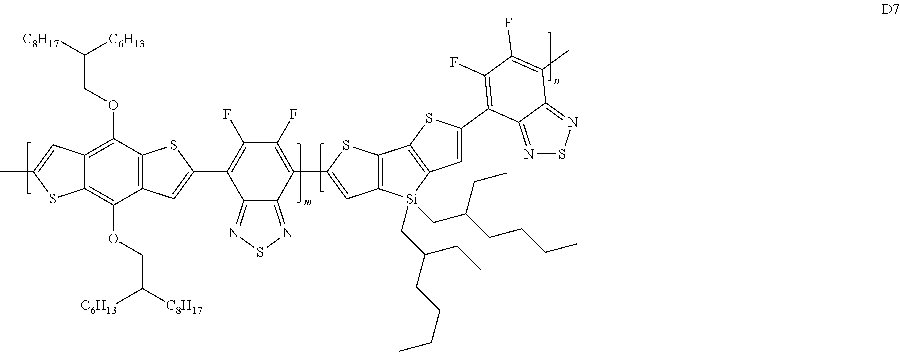

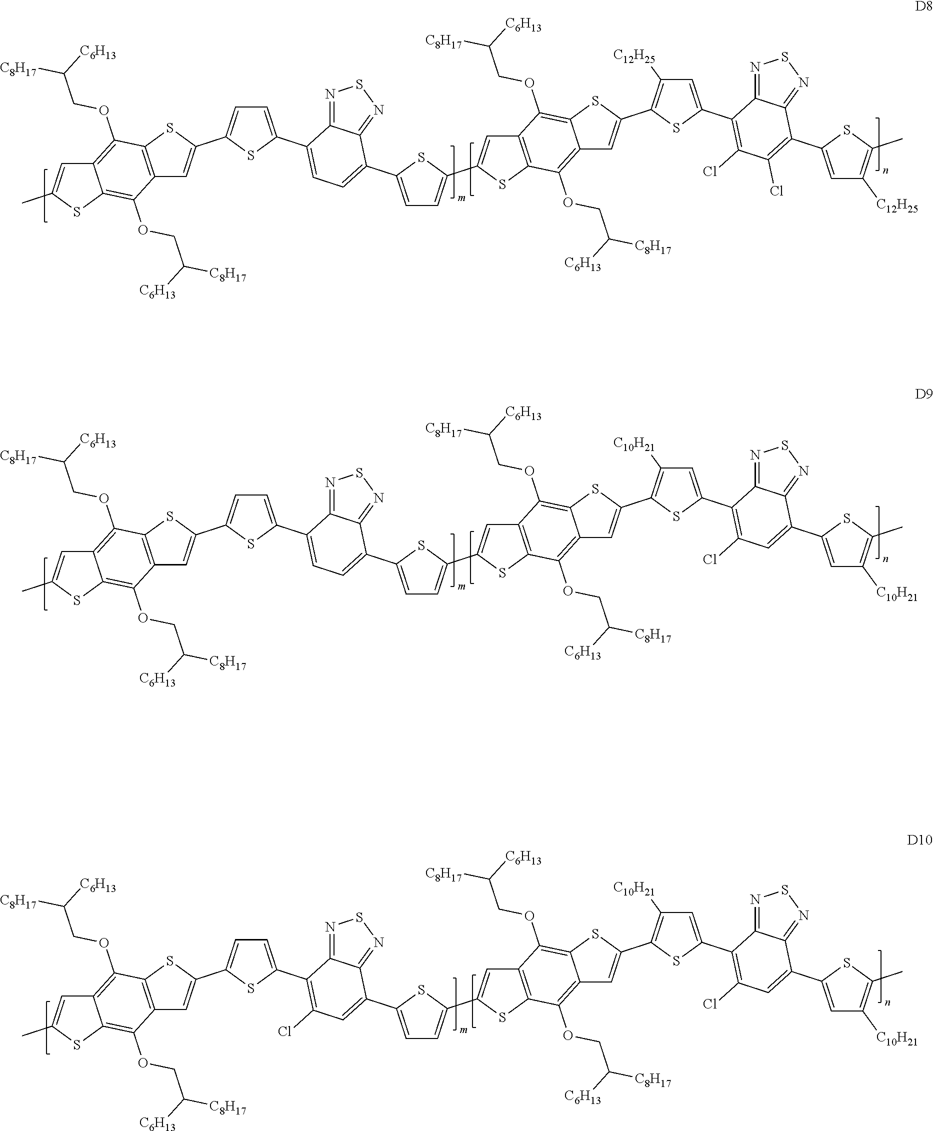

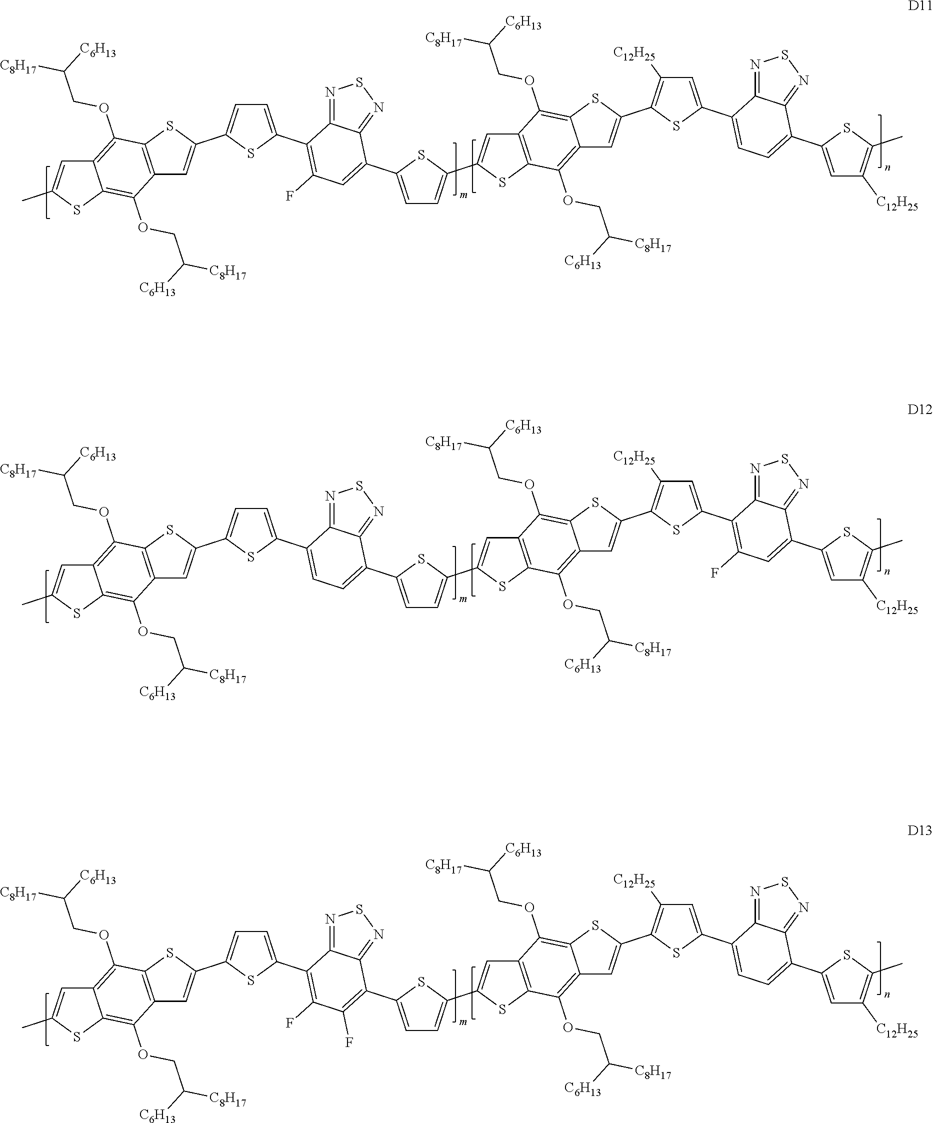

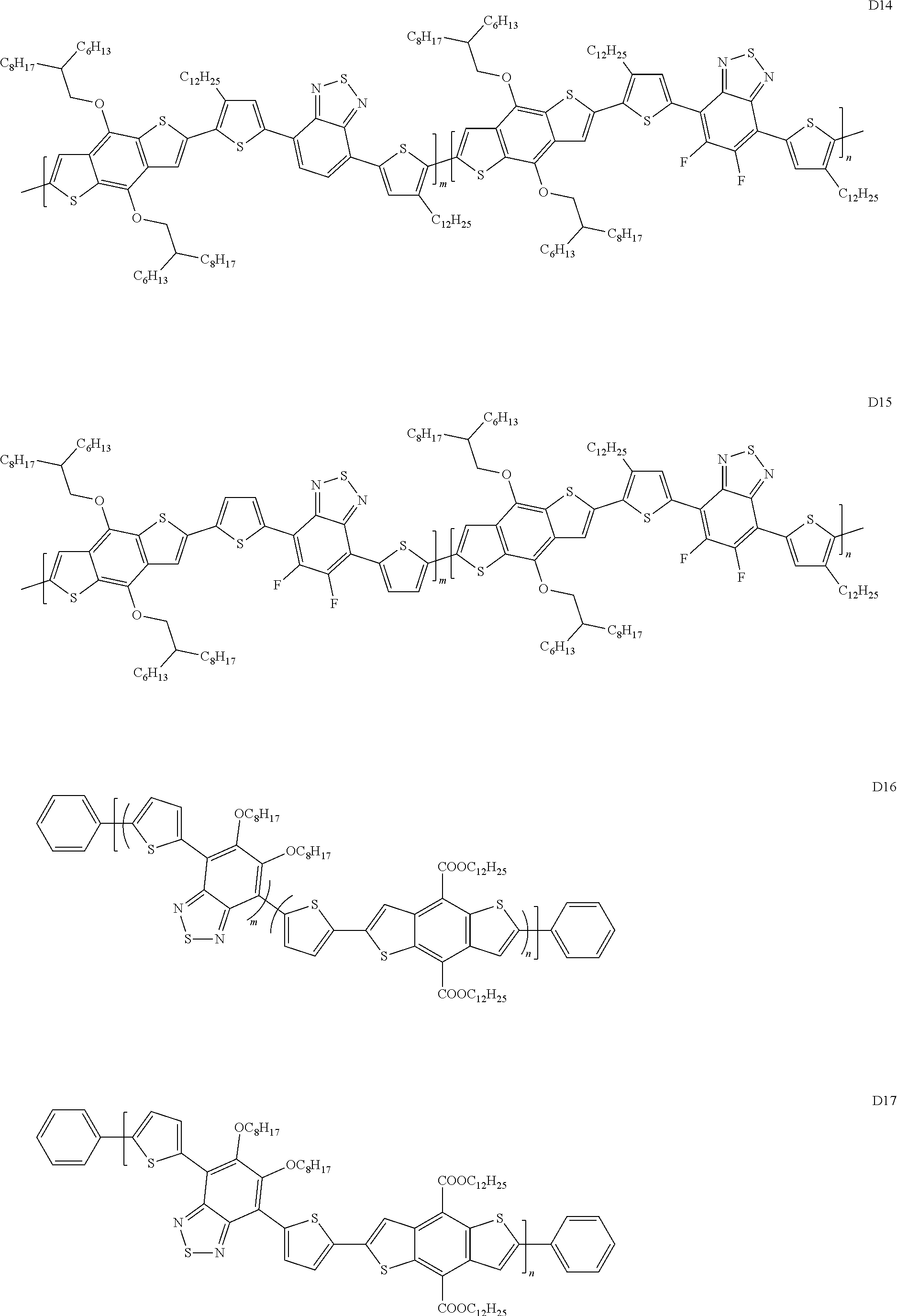

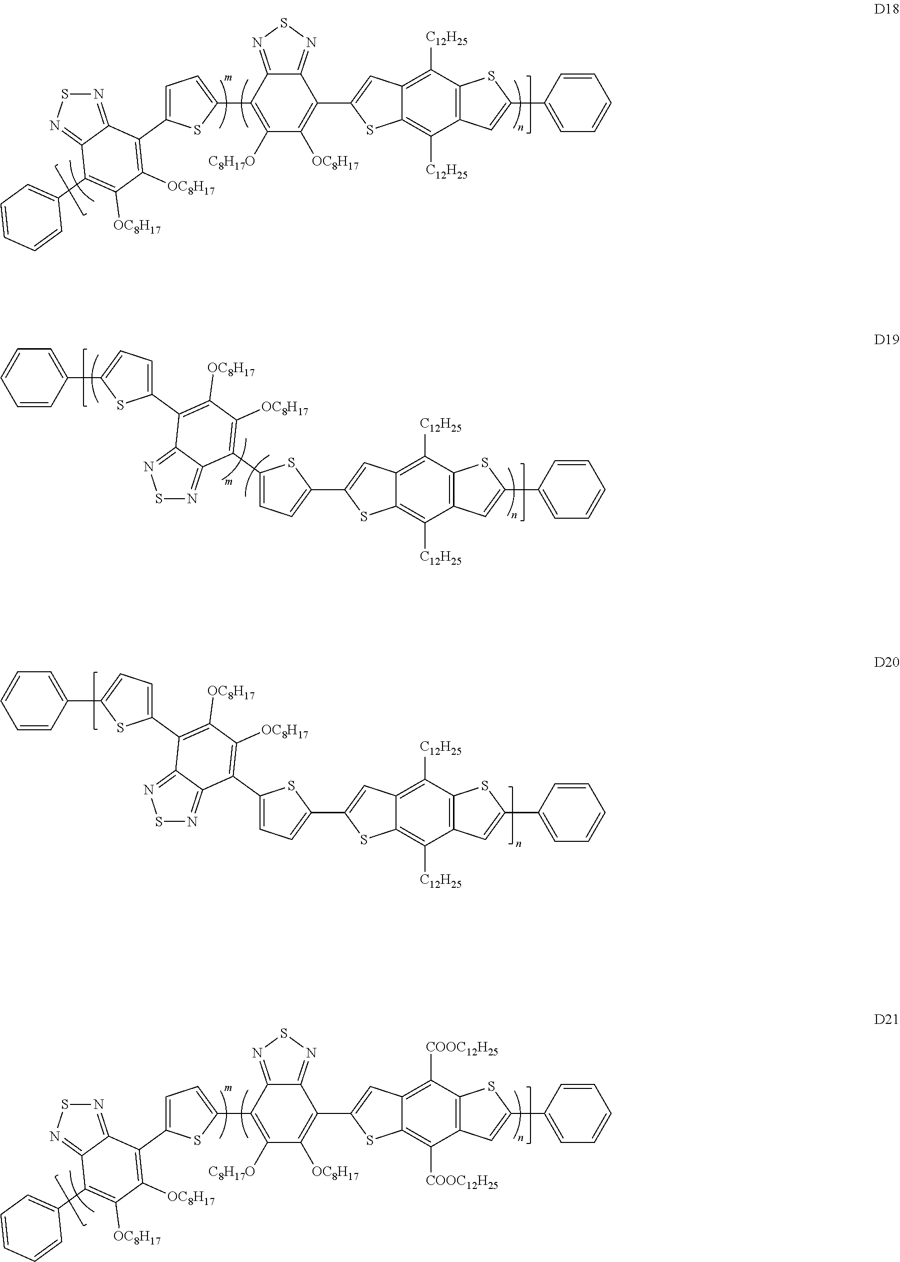

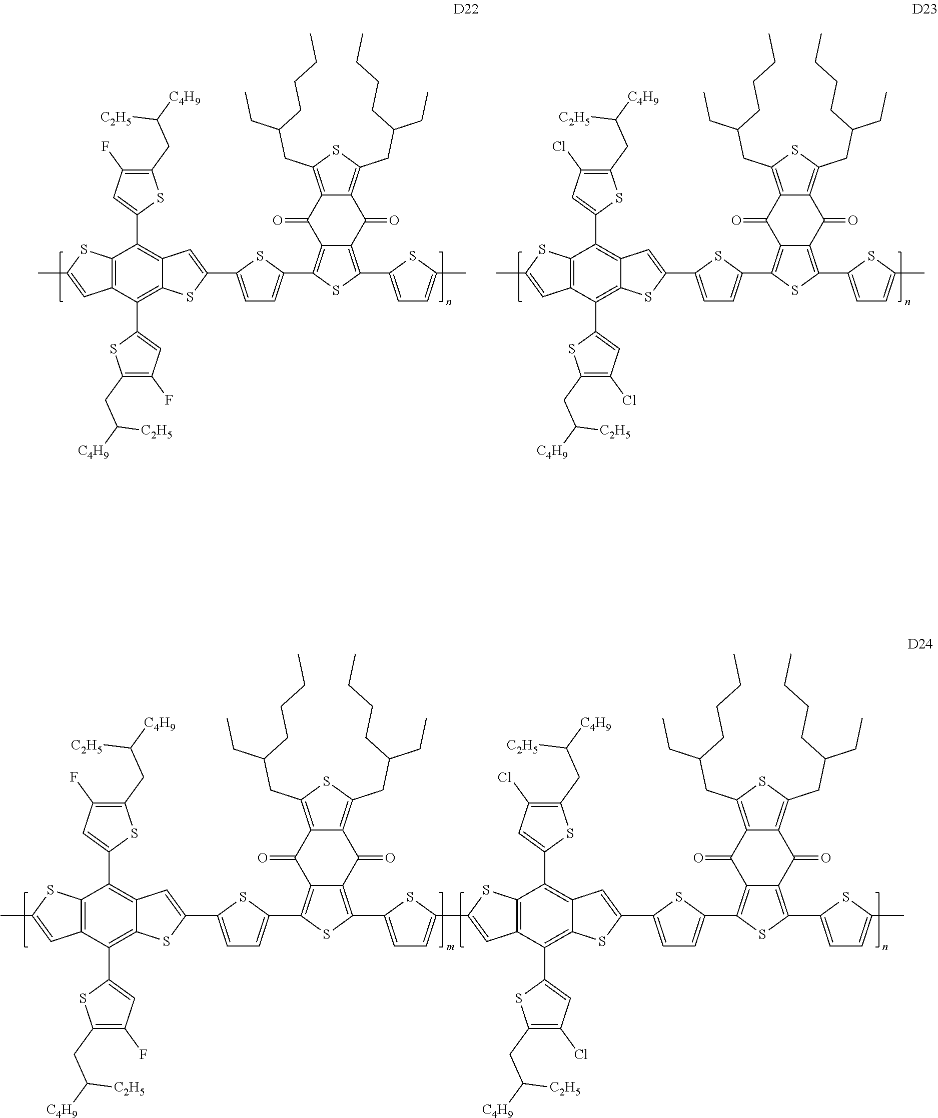

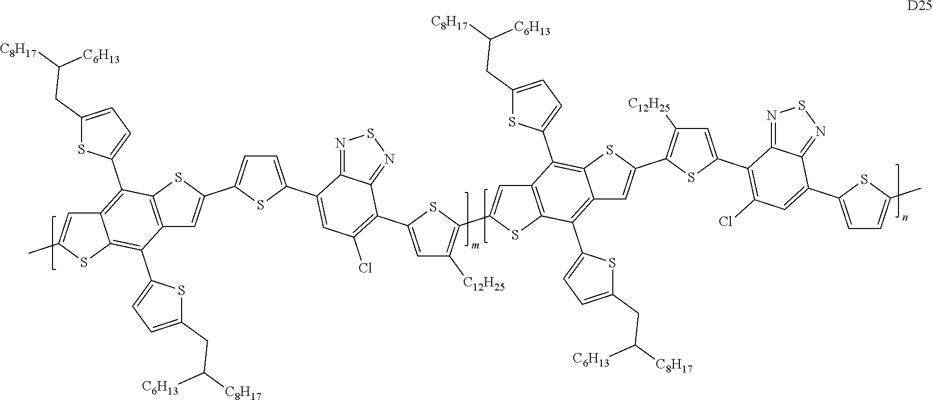

Moreover, the active layer 130 includes at least one electron acceptor. In a preferred embodiment of the present invention, the active layer 130 has a first electron acceptor which is selected from the group consisting of the following chemical structures A1-A25.

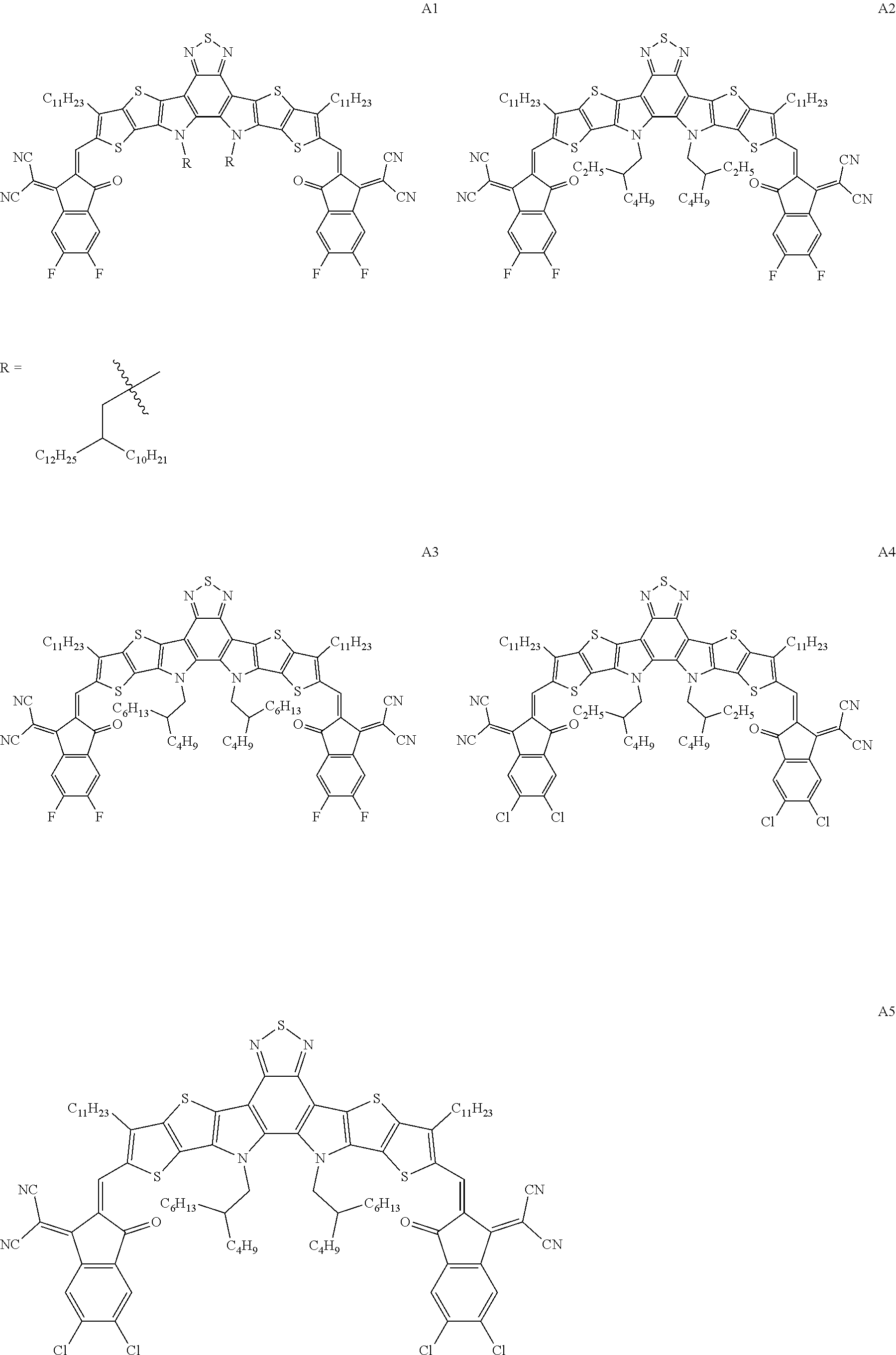

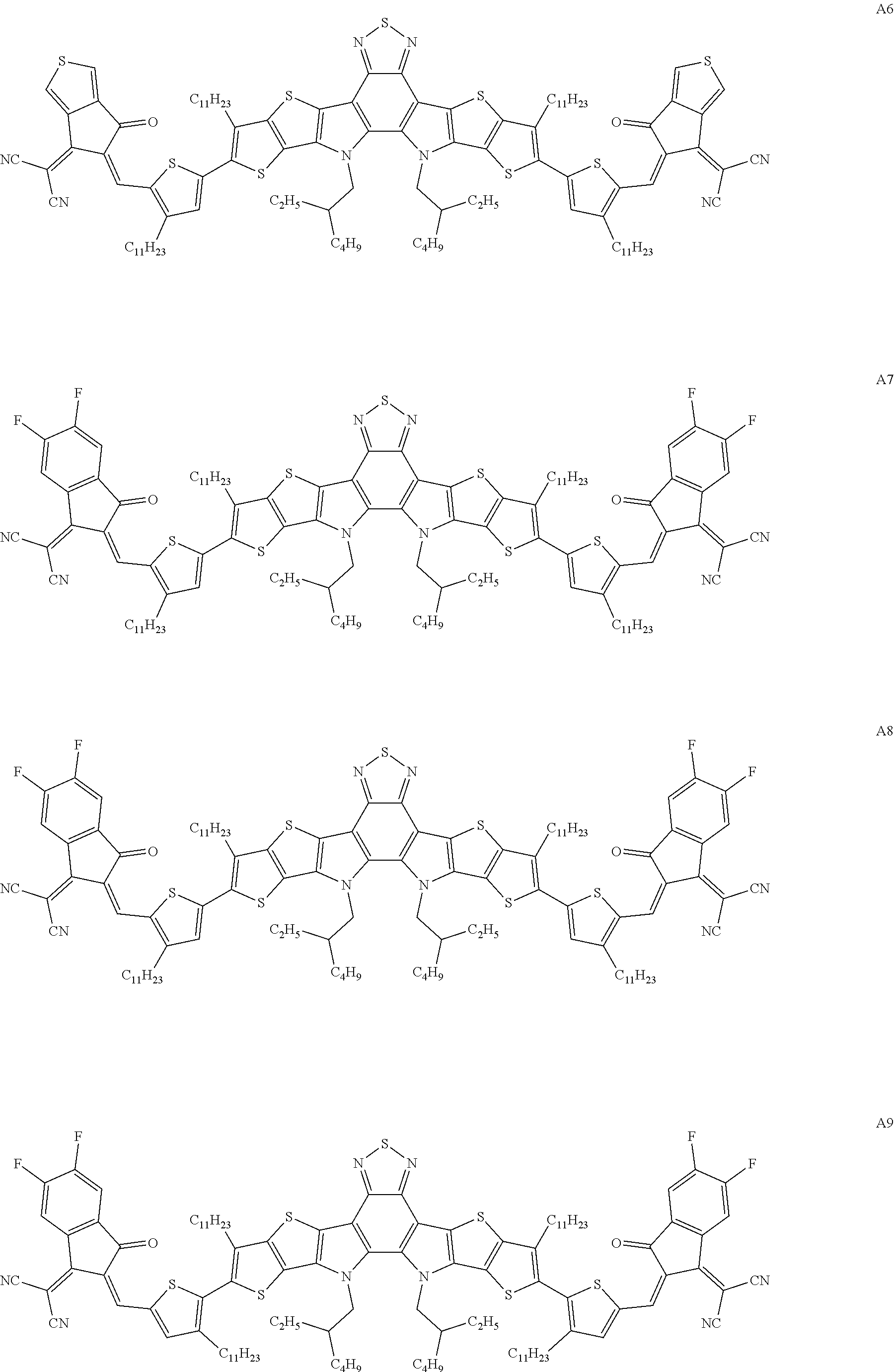

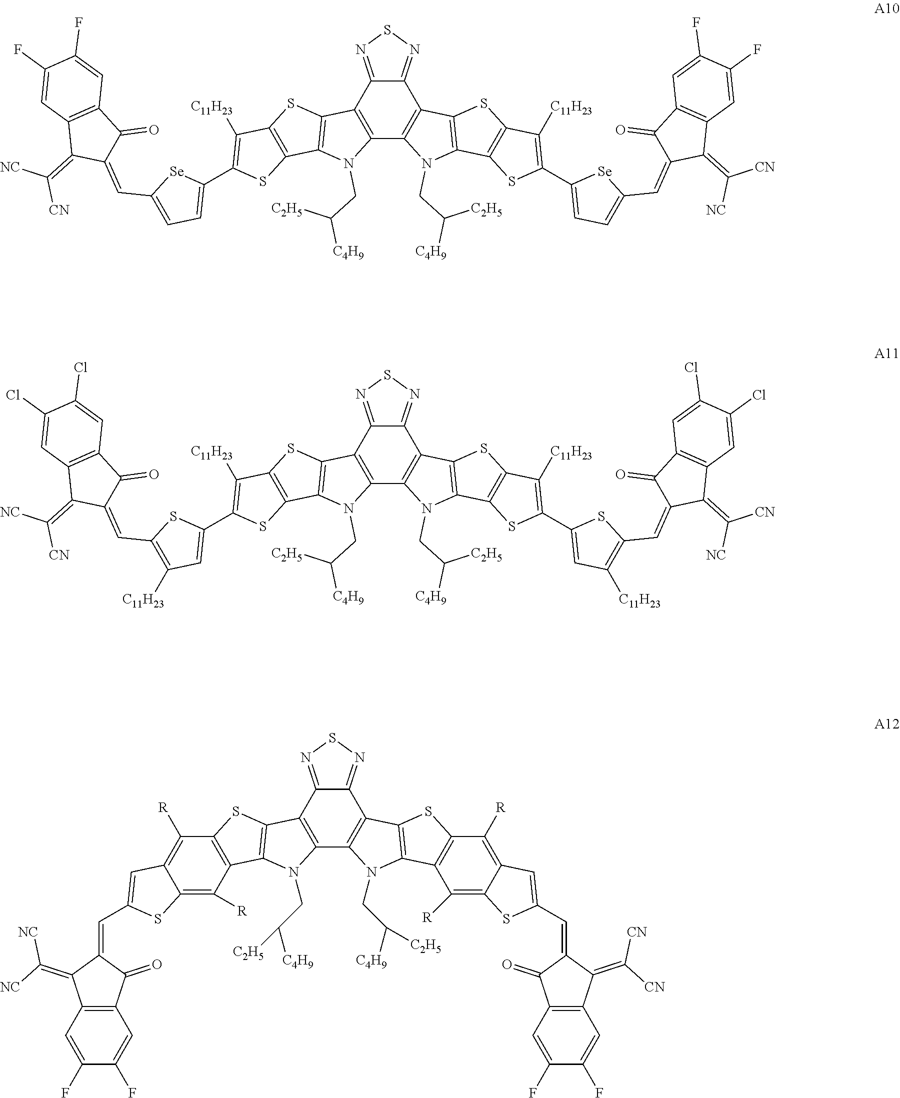

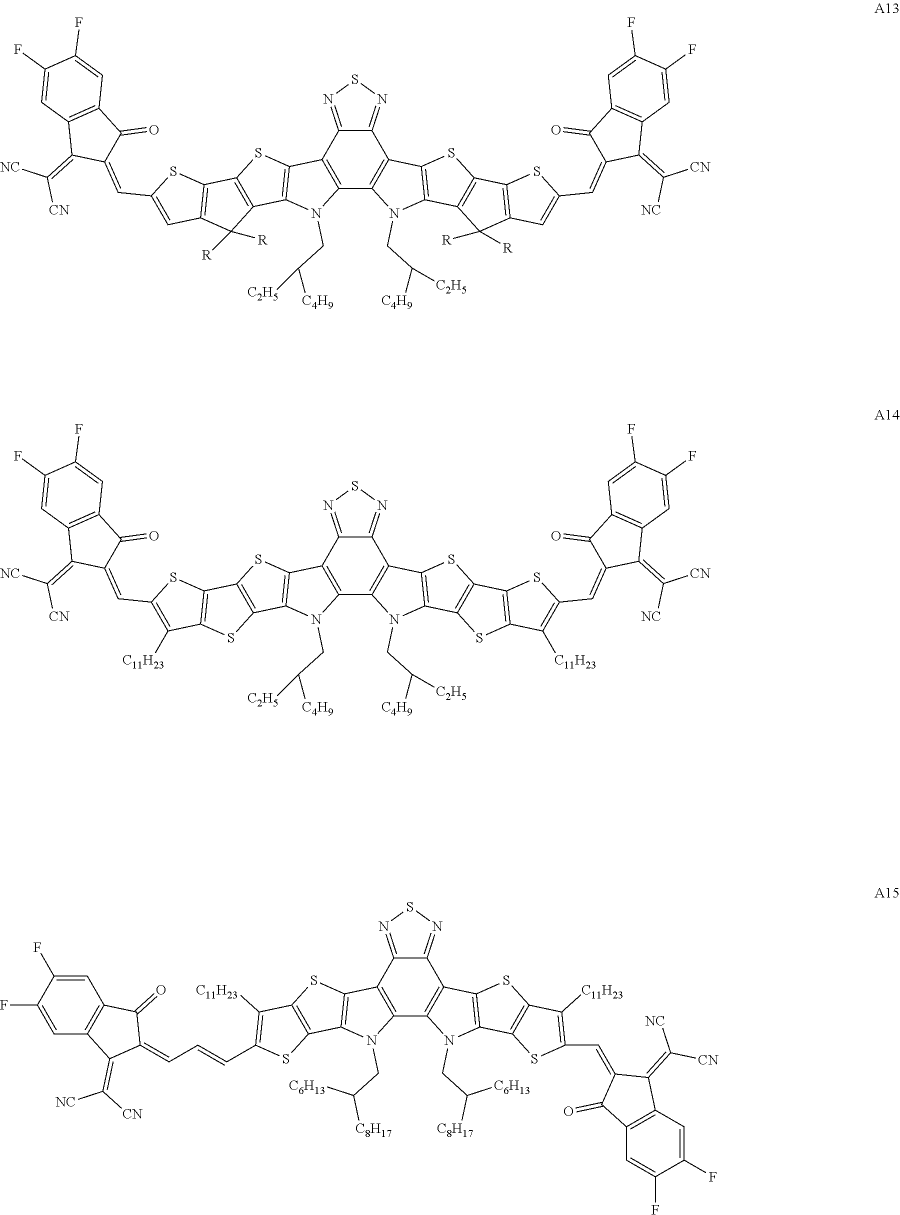

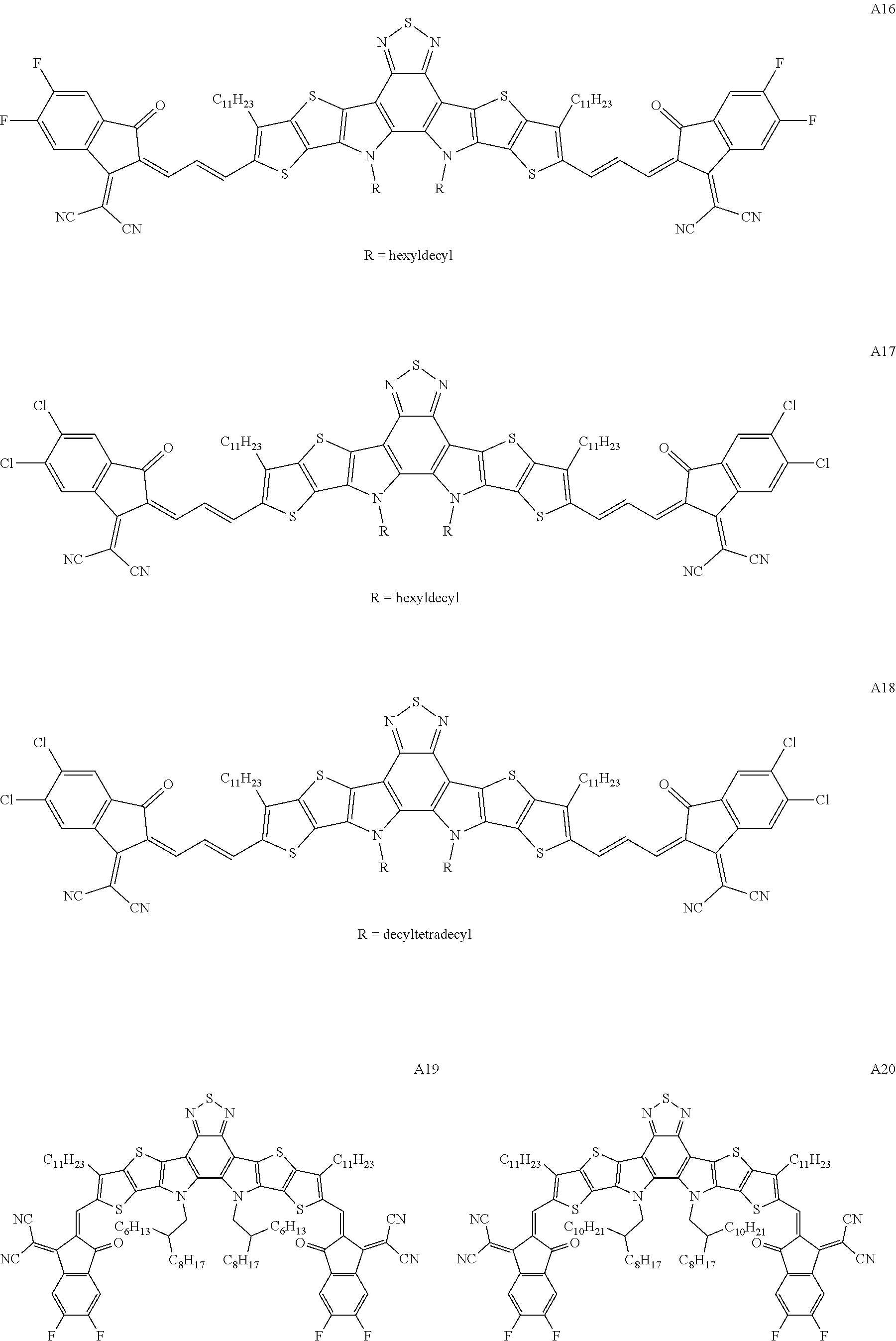

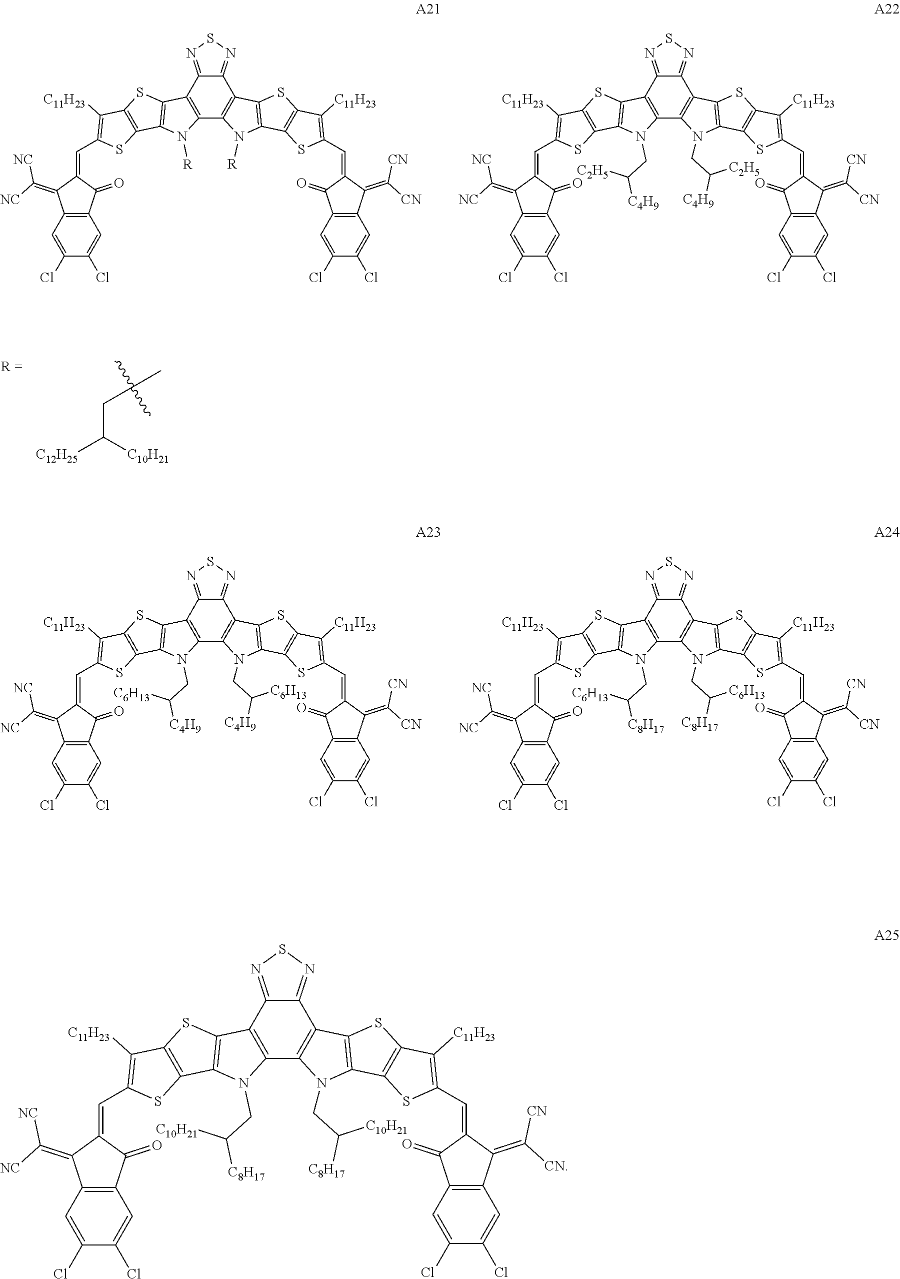

In another embodiment of the present invention, besides the first electron acceptor, the active layer 130 further includes a second electron acceptor which is selected from the group consisting of the following chemical structures A26-A40.

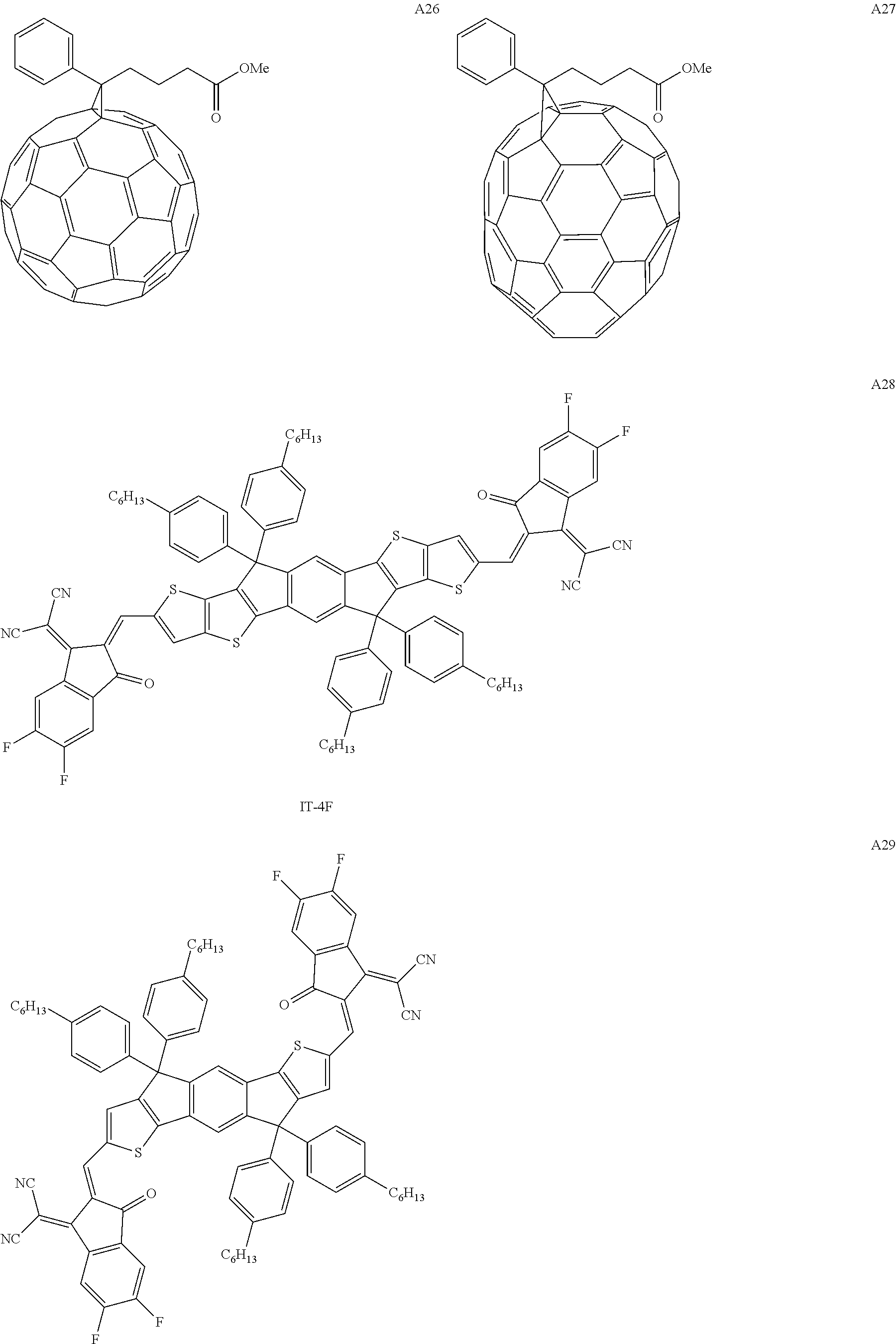

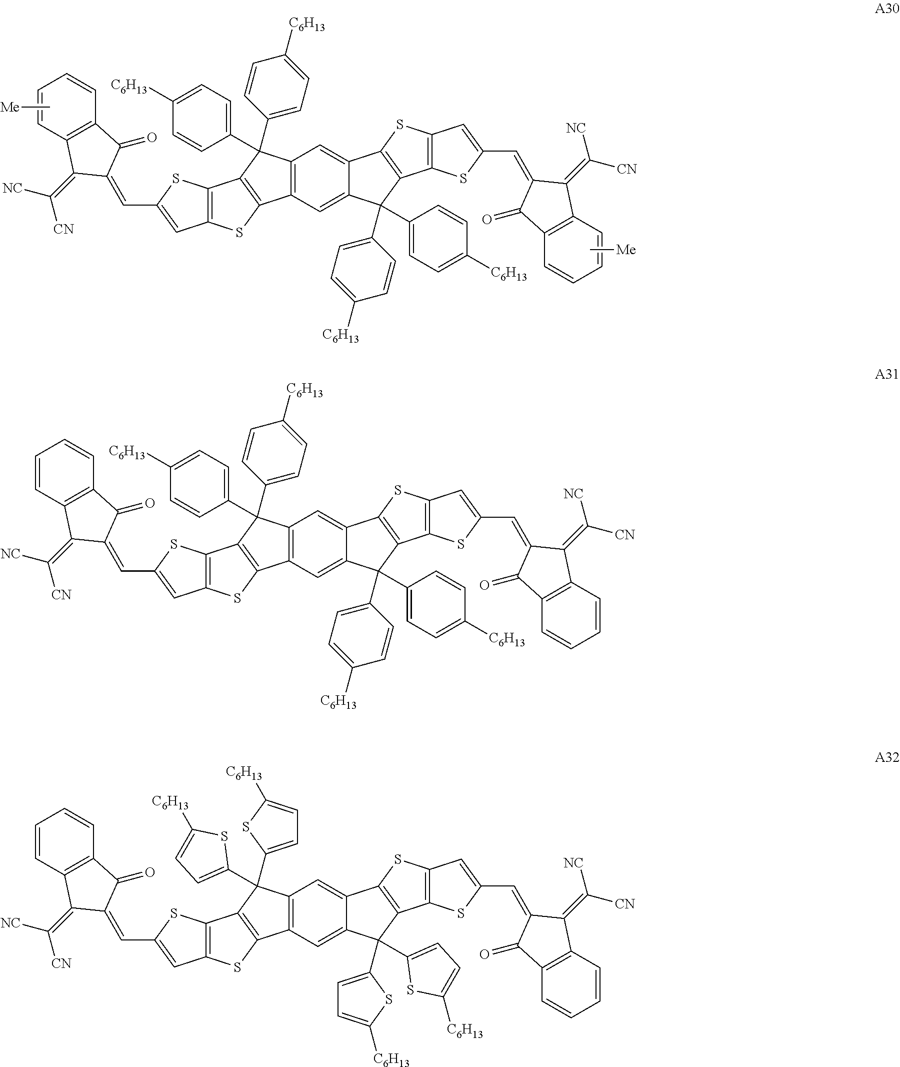

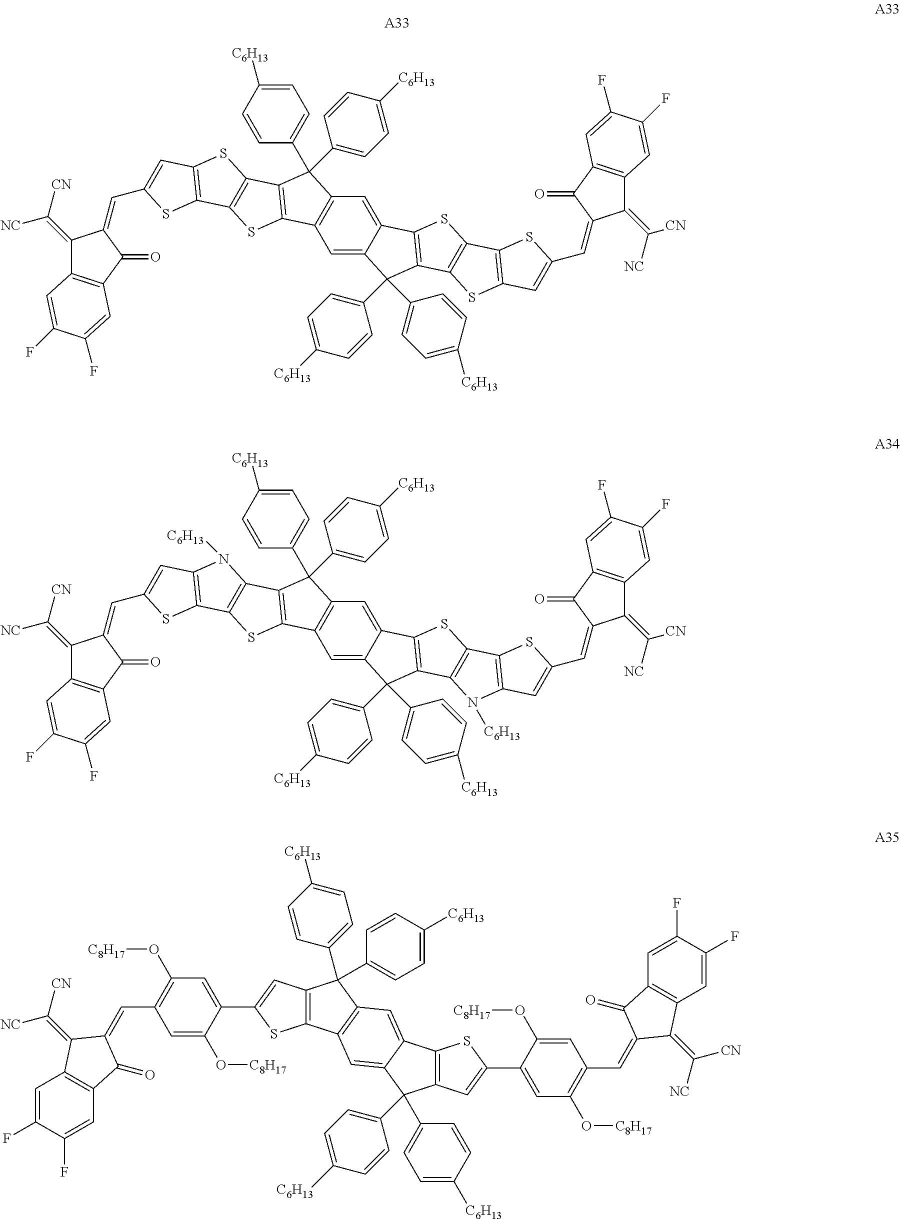

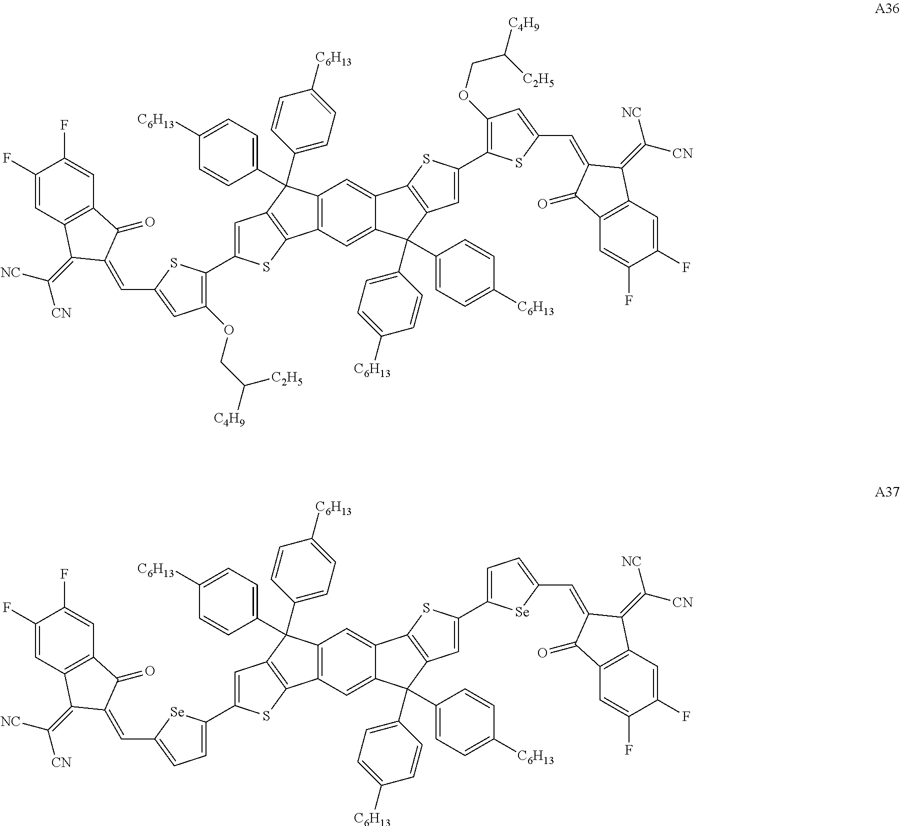

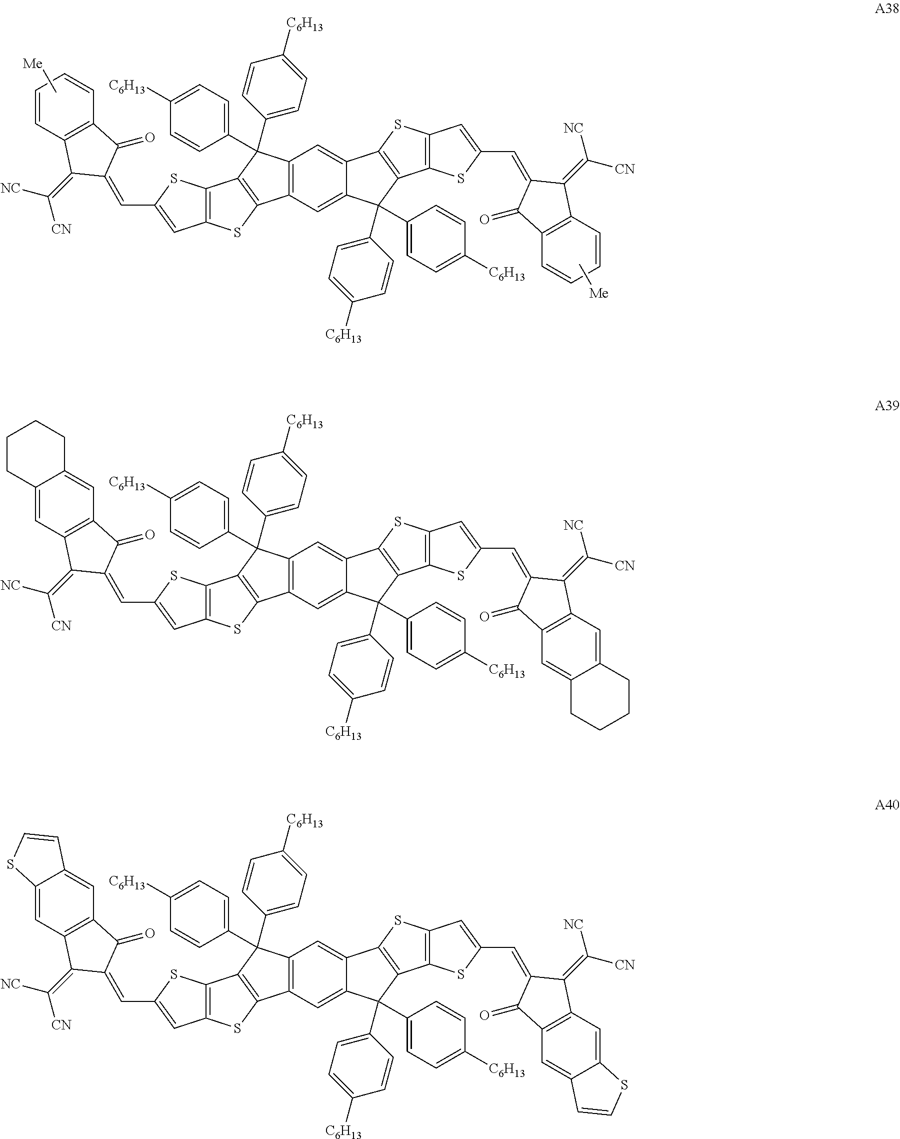

Preferably, in the active layer 130 of the organic semiconductor device 10, the weight ratio of the second electron acceptor is less than the weight ratio of the first electron acceptor.

Preferably, the electron donor in the active layer 130 of the organic semiconductor device 10 has a band gap greater than 1.50 eV and a band gap of the first electron acceptor is less than 1.49 eV.

Materials for the hole transport layer 140 used in combination with the electron donors in the active layer 130 are selected from PEDOT:PSS and its derivatives. The PEDOT:PSS has a higher vacuum level (about −5.00 eV) compared with conventional molybdenum trioxide (MoO₃) (−5.50 eV) so that the loss in power conversion efficiency is minimized when PEDOT:PSS is applied to the organic semiconductor device 10.

More specifically, the hole transport layer 140 of the organic semiconductor device 10 can be formed in various ways while wet processes are preferred. For example, the hole transport layer 140 can be prepared by solution processing techniques and wet processes such as, but not limited to, rotary casting, dip-coating, inkjet printing, nozzle printing, relief printing, screen printing, intaglio printing, blade coating, roller printing, reverse roller printing, lithography, web-fed printing, spray coating, curtain coating, brush coating, slot die coating, pad printing, etc. Spin coating is preferred for processing of the hole transport layer 140.

In order to meet requirements for durability and high transparency, the substrate is a glass substrate, or a transparent and flexible substrate made of transparent materials with higher mechanical strength and thermal strength. The transparent and flexible material is preferably selected from the group consisting of polyethylene, ethylene-vinyl acetate copolymer, ethylene vinyl alcohol copolymer, polypropylene, polystyrene, poly(methyl methacrylate), polyvinyl chloride, polyvinyl alcohol, polyvinyl butyrate, nylon, polyetheretherketone, polysulfone, poly(ether sulfones), tetrafluoroethylene-perfluorinated alkylvinylether copolymer, polyvinyl fluoride, polytetrafluoroethylene, tetrafluoroethylene-hexafluoropropylene copolymer, polychlorotrifluoroethylene, polyvinylidene difluoride, polyester, polycarbonate, polyurethane, polyimide, and a combination thereof.

Refer to FIG. 1a, in a preferred embodiment, materials for the first electrode 110 should have relative stability with respect to the hole transport layer 140 and good transparency is also preferred. Thus, transparent conductive material is commonly used and selected from the following conductive materials: indium oxides, tin oxides, derivatives of fluorine doped tin oxide (FTO), or composite metal oxide such as indium tin oxide (ITO) and indium zinc oxide (IZO). Materials for the second electrode 150 are selected from conductive metals, preferably from silver or aluminum, more preferred are silver.

Refer to FIG. 1b, in another preferred embodiment, the first electrode 110 of the organic semiconductor device 10 is disposed over the hole transport layer 120 while the second electrode 150 is arranged over the substrate 100 and the electron transport layer 140 is mounted over the second electrode 150.

The materials for the active layer 130 of the present organic semiconductor device 10 are prepared by solution processing. According to the ratio required, the above electron donor and the electron acceptor are dissolved in a solvent to form a formulation for further processing. The solvent used in the formulation includes at least one aromatic solvent which is preferably selected from methylbenzene, ortho-xylene, para-xylene, meta-xylene, trimethylbenzenes, chlorobenzene, dichlorobenzene, trichlorobenzene, tetrahydronaphthalene or its mixtures, anisole, methoxytoluene and its derivatives, naphthalene, 1-methylnaphthalene and its derivatives.

Owing to excellent electrical properties/performance, the present organic semiconductor device can be broadly applied to various products which is selected from organic field-effect transistor (OFET), integrated circuit (IC), thin-film transistor (TFT), radio frequency identification (RFID) tags, organic light-emitting diode (OLED), organic light-emitting transistor (OLET), electroluminescent display (ELD), organic photovoltaic (OPV) cells, and organic solar cells (OSC), flexible OPV and OSC, organic laser diodes (O-laser), organic integrated circuit (OIC), light devices, sensors, electrode materials, photoconductors, light sensors, electro-optical recording devices, capacitors, charge injection layers, Schottky diodes, planarization layers, antistatic films, conductive substrates, conductive patterns, organic memory, biosensors, and biochips.

Please refer to the following embodiments for more details of the present invention.

### Example: Verification on Energy Level of Materials for Organic Photovoltaic (OPV) Cells Used in the Present Invention

In this embodiment, energy level of materials D1 and D17 for the present organic photovoltaic (OPV) cells is verified by electrochemical instrumentation of CH Instruments using cyclic voltammetry (CV). During experiment, glassy carbon electrode is used as a working electrode, silver/silver chloride electrode is used as a reference electrode, and 0.1 M tetrabutylammonium hexafluorophosphate dissolved in anhydrous acetonitrile is electrolyte. CV curve of ferrocene is used for internal calibration. With respect to HOMO energy level of vacuum level which is 4.7 Ev, the HOMO energy level of the OPV cells is calculated by equation I:

HOMO=−(Eₒₓ^{onset}−E_{(Ferrocene)}^{onset}+4.7) eV I,

The LUMO energy level is calculated by equation II:

LUMO=(−E_{g}+HOMO) eV II.

The verification results of the materials D1 and D17 are shown in Table 1.

TABLE 1
results of band gap of the materials used

| material | band gap (eV) | HOMO (eV) | LUMO (eV) |
|---|---|---|---|
| D1 | 1.70 | 5.35 | 3.65 |
| D17 | 1.75 | 5.38 | 3.63 |

### Example 2: Preparation of Control Group C1 of OPV Cells

Prepare a control group C1 of OPV cells. First an ITO glass substrate is cleaned and pretreated for being used as the first electrode. A precursor solution of zinc oxide is coated on the glass by spin coating to form a thin layer and then the thin layer is treated by annealing at 120° C. for 10 minutes to form the electron transport layer. Next a material for the active layer is coated on the zinc oxide layer by spin coating. The material for the active layer is a mixture of D1, A1, and A26 in a ratio of 1:1:0.2. After being dissolved in o-xylene, the mixture is processed by spin coating and then treated by annealing in a nitrogen atmosphere at 125° C. for 5-10 minutes to form the active layer. Then the semi product is transferred to an evaporator and an 8-nm-thick layer of molybdenum trioxide (MoO₃) is deposited on the active layer by thermal evaporation at 10⁻⁷ Torr to form the hole transport layer. Next a 100-nm-thick layer of silver is arranged over the molybdenum trioxide layer to form the second electrode. Thereby the control group C1 of the OPV cell is obtained. An active area of the OPV cell is determined by a shadow mask with an aperture mask added.

After the respective layers being prepared and disposed, an outer glass and peroxidized sealant are used for packaging to get the OPV cell.

### Example 3: Preparation of OPV Cell Sample 1

In order to prepare OPV cell sample 1, a ITO glass substrate is cleaned and pretreated to be used as the first electrode. A precursor solution of Zinc oxide is coated on the glass by spin coating to form a thin layer and then the thin layer is treated by annealing at 120° C. for 10 minutes to form the electron transport layer. Next a material for the active layer is coated on the zinc oxide layer by spin coating. The material for the active layer is a mixture of D1, A1, and A26 in a ratio of 1:1:0.2. After being dissolved in o-xylene, the mixture is processed by spin coating and then treated by annealing in a nitrogen atmosphere at 125° C. for 5-10 minutes to form the active layer. After formation of the active layer, PEDOT:PSS (product name: Clevios™ HTL Solar #388) is spin coated in an air atmosphere at 3000 rpm, 21° C., and 40% humidity and then baked at 110° C. for 5 min in nitrogen to form a thin film with thickness between 60 nm and 70 nm. Then the semi product is transferred to an evaporator and a 100-nm-thick layer of silver is deposited on the active layer by thermal evaporation at 10⁻⁷ Torr to form the second electrode. Thereby the OPV cell sample 1 is obtained.

An active area of the OPV cell is determined by a shadow mask with an aperture mask added.

After the respective layers being prepared and disposed, an outer glass and peroxidized sealant are used for packaging to get the OPV cell.

### Example 4: Preparation of Control Group C2 of OPV Cells

A control group C2 of OPV cells is prepared by the same method mentioned in the second embodiment. The active layer is formed by a mixture of D1 and A26 in a ratio of 1:1.5 being dissolved in o-xylene, spin coated and annealed in nitrogen at 125° C. for 5-10 minutes. The hole transport layer is formed by deposition of molybdenum trioxide (MoO₃) by thermal evaporation and the second electrode is made of silver.

### Example 5: Preparation of OPV Cell Sample 2

A OPV cell sample 2 is prepared by the same method mentioned in the third embodiment. The active layer is formed by a mixture of D1 and A26 in a ratio of 1:1.5 being dissolved in o-xylene, spin coated and annealed in nitrogen at 125° C. for 5-10 minutes. The hole transport layer is formed by PEDOT:PSS (product name: Clevios™ HTL Solar #388) treated by spin coating and baking at 120° C. for 3 min and the second electrode is made of silver.

### Example 6: Preparation of Control Group C3 of OPV Cells

A control group C3 of OPV cells is prepared by the same method mentioned in the second embodiment. The active layer is formed by a mixture of D17 and A26 in a ratio of 1:2 being dissolved in o-xylene/1-Methyl Naphthalene (1-MN), spin coated and annealed in nitrogen at 125° C. for 5-10 minutes. The hole transport layer is formed by deposition of molybdenum trioxide (MoO₃) by evaporation and the second electrode is made of silver.

### Example 7: Preparation of OPV Cell Sample 3

An OPV cell sample 3 is prepared by the same method mentioned in the third embodiment. The active layer is formed by a mixture of D1, A1, and A26 in a ratio of 1:1:0.2 being dissolved in o-xylene, spin coated and annealed in nitrogen at 125° C. for 5-10 minutes. The hole transport layer is formed by PEDOT:PSS (product name: Clevios™ HTL Solar #388) being spin coated and baked at 120° C. for 3 min while the second electrode is made of silver.

### Example Conversion Efficiency Test for Control Groups and Samples of OPV Cells

Perform efficiency test for the respective OPV cell control groups C1-C3 and samples 1-3. During the test, use a metal halide lamp as a light source to emit the OPV cells with an intensity of 100 mW/cm² and record their power conversion efficiency (PCE) to calculate their PCE loss by using the following equation:

**[(PCE_{MoO3}−PCE_{PEDOT:PSS})/PCE_{MoO3}]*100 III

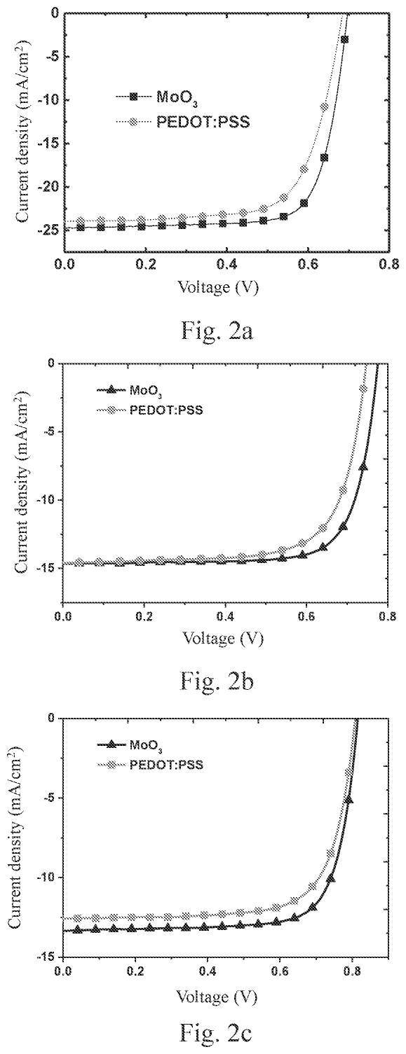

The results are show in FIG. 2a, FIG. 2b, and FIG. 2c and the data is displayed in Table 2.

TABLE 2
Performance comparison of the respective
OPV control groups and cells

| | | | | | PCE |
|---|---|---|---|---|---|
| OPV | Voc | Jsc | FF | PCE | loss** |
| cell # | (V) | (mA/cm²) | (%) | (%)* | (%) |
| C1 | 0.70 | 24.7 | 75.1 | 13.0 | STD |
| 1 | 0.69 | 24.0 | 69.8 | 11.6 | 10.7% |
| C2 | 0.78 | 14.7 | 76.1 | 8.72 | STD |
| 2 | 0.75 | 14.6 | 71.7 | 7.83 | 10.2% |
| C3 | 0.82 | 13.3 | 75.5 | 8.23 | STD |
| 3 | 0.81 | 12.6 | 72.5 | 7.38 | 10.3% |

The results in the Table 2 show that reduction of the efficiency of the samples 1-3 of the present organic semiconductor device is ranging from 10.2% to 10.7% compared with the control groups C1-C3 which use molybdenum trioxide as the hole transport layer. The efficiency of the present invention is excellent than the prior techniques.

### Example 9: Service Life Test for OPV Cells

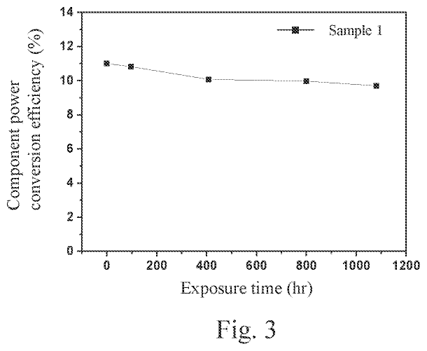

Prepare the OPV cell sample 1 by the steps shown in the third embodiment and then perform service life test for the OPV cell sample 1. During the test, use a metal halide lamp as a light source to emit the OPV cells with an intensity of 100 mW/cm² continuously and record the power conversion efficiency with different illumination/exposure time. The results are shown in FIG. 3 and the data is displayed in Table 3.

TABLE 3
relationship between long term illumination and
change of component efficiency of sample 1

| | component |
|---|---|
| | power |
| Illumination | conversion |
| time(hour) | efficiency(%) |
| 0 | 11.0 |
| 96 | 10.82 |
| 408 | 10.07 |
| 800 | 9.97 |
| 1080 | 9.70 |

The control group of the present OPV cell is an organic solar cell disclosed by J. Cai et al. in J. Mater. Chem. A, 2020, 8, 4230-4238. The organic solar cell is an inverted organic semiconductor device which uses molybdenum trioxide (MoO₃) as the hole transport layer. The results show that the power conversion efficiency of the organic solar cell after 30 days dropped to 80% of the initial value (as show in FIG. 6 of the paper). As to the OPV cell of the present invention, the power conversion efficiency remains 88.2% after 1080 hours of exposure. Therefore, the device of the present invention is significantly superior to the control group from J. Cai et al . . . .

According to the above embodiments, it is learned that the drop of the power conversion efficiency of the respective present OPV cell samples is less than the control group. Moreover, the result of the long term light exposure test for the present OPV cell sample 1 also shows that the present invention reduces the loss in power conversion efficiency and increases the component stability significantly compared with the conventional organic semiconductor device.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. An organic semiconductor device comprising:
a substrate,
a first electrode,
an electron transport layer disposed on the first electrode,
an active layer disposed on the electron transport layer,
a hole transport layer disposed on the active layer and containing
a compound selected from PEDOT:PSS or the derivatives thereof,
and
a second electrode disposed on the hole transport layer;
wherein the active later includes an electron donor and at least one electron acceptor while an energy barrier between highest occupied molecular orbital (HOMO) level of the electron donor and an energy level of the electron transport layer is less than 0.4 eV.

2. The organic semiconductor device according to claim 1, wherein the electron donor is a conjugated polymer formed by at least two monomers, a first monomer and a second monomer.

3. The organic semiconductor device according to claim 2, wherein the first monomer of the conjugated polymer is selected from the group consisting of: a benzodithiophene moiety, a carbazole moiety, a silylpentadithiophene moiety, a thiophene moiety, a cyclopentadithiophene moiety, a selenophene moiety, a dithieno[3,2-b:2′,3′-d]pyrrole (DTP) moiety, a cyclopentadithiazole moiety, and a dibenzosilazole moiety.

4. The organic semiconductor device according to claim 2, wherein the second monomer of the conjugated polymer is selected from the group consisting of: a benzothiadiazole moiety, a thiadiazoloquinoxaline moiety, a benzoisothiazole moiety, a benzothiazole moiety, a thienothiophene moiety, a tetrahydroisoindole moiety, a thiazolothiazole moiety, a thienopyrazine moiety, a benzoxazole moiety, a quinoxaline moiety, a thiadiazolepyridine moiety, a benzoxadiazole moiety, a benzoselenadiazole moiety, a thienothiadiazole moiety, a thienopyridone moiety, a benzodithiophenedione (BDD) moiety, and a pyrazine moiety.

5. The organic semiconductor device according to claim 2, wherein the electron donor is selected from the group consisting of chemical formulas D1-D25:

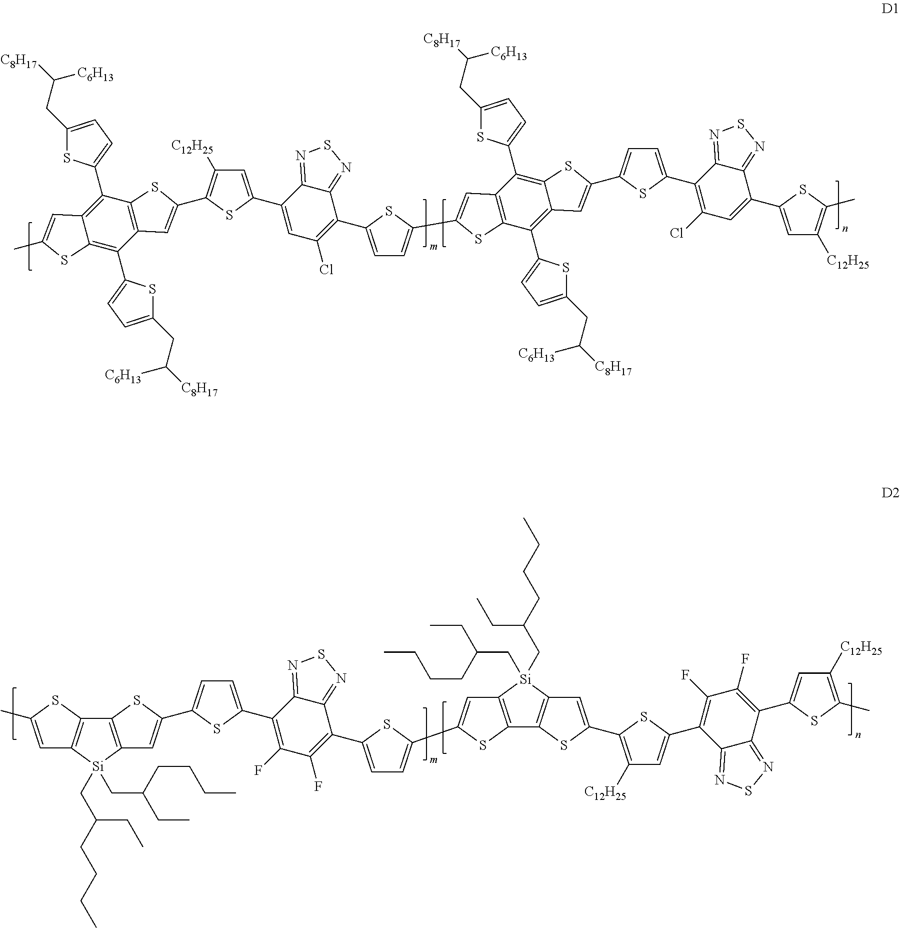

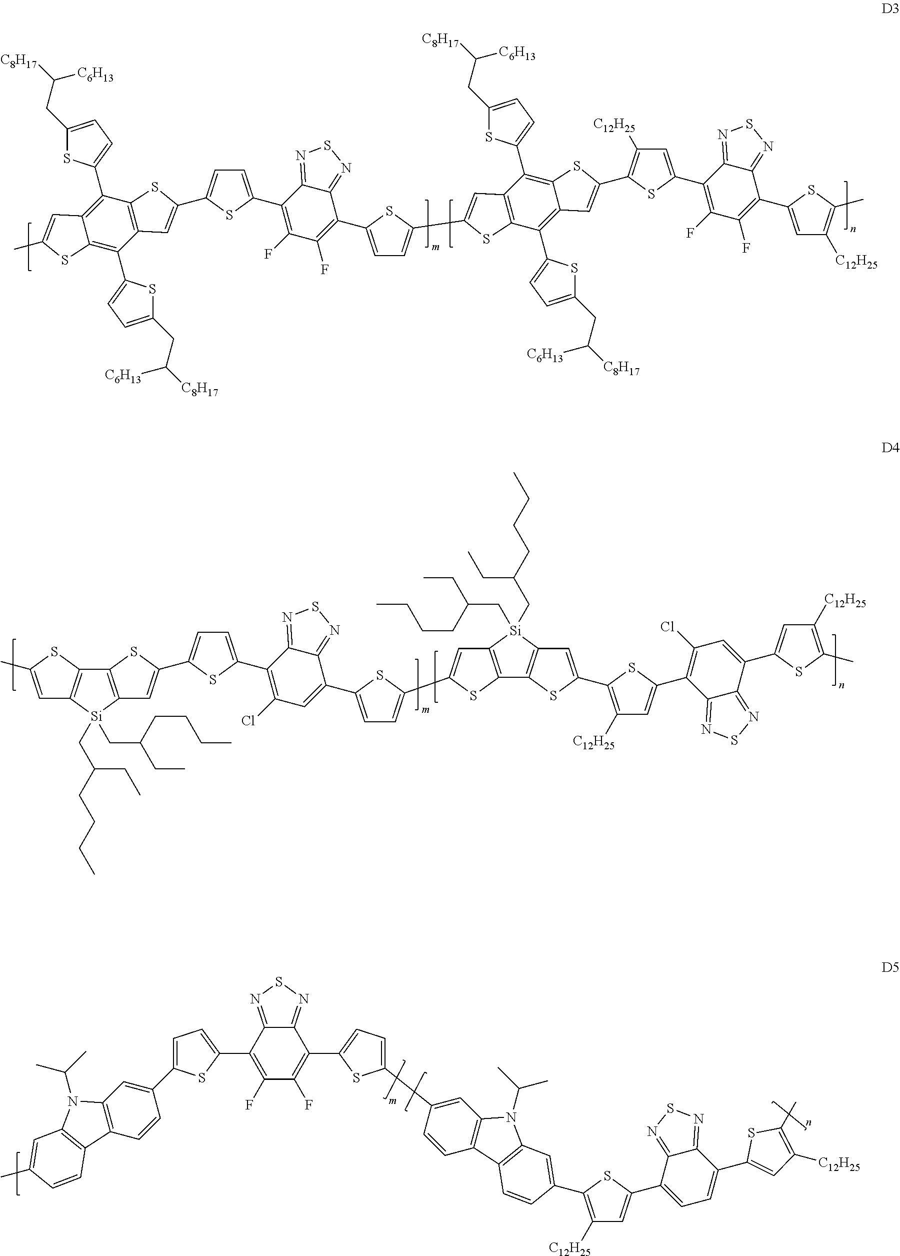

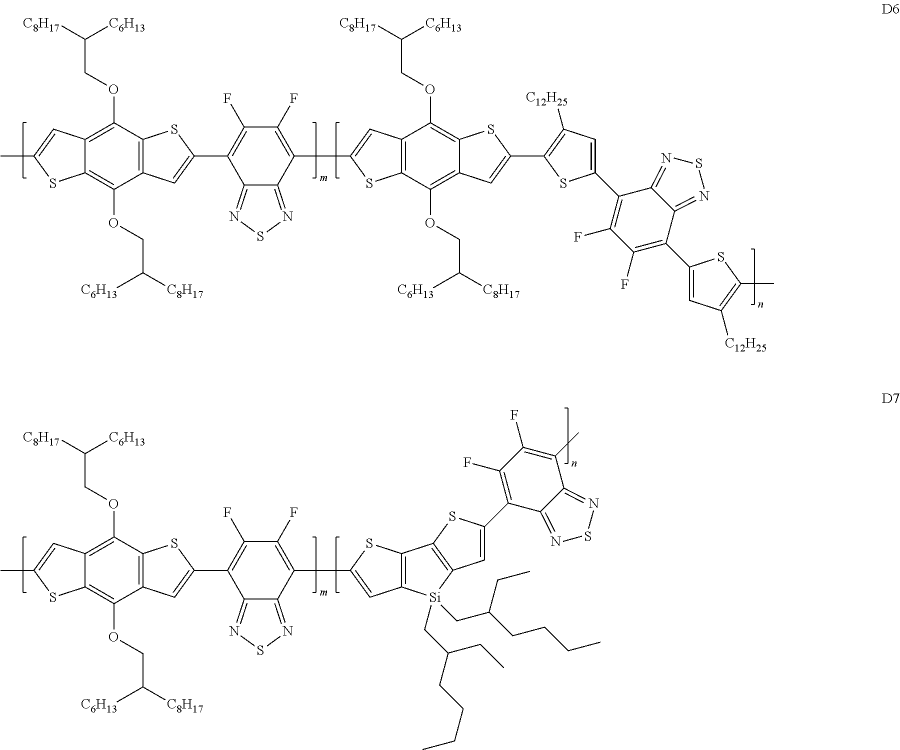

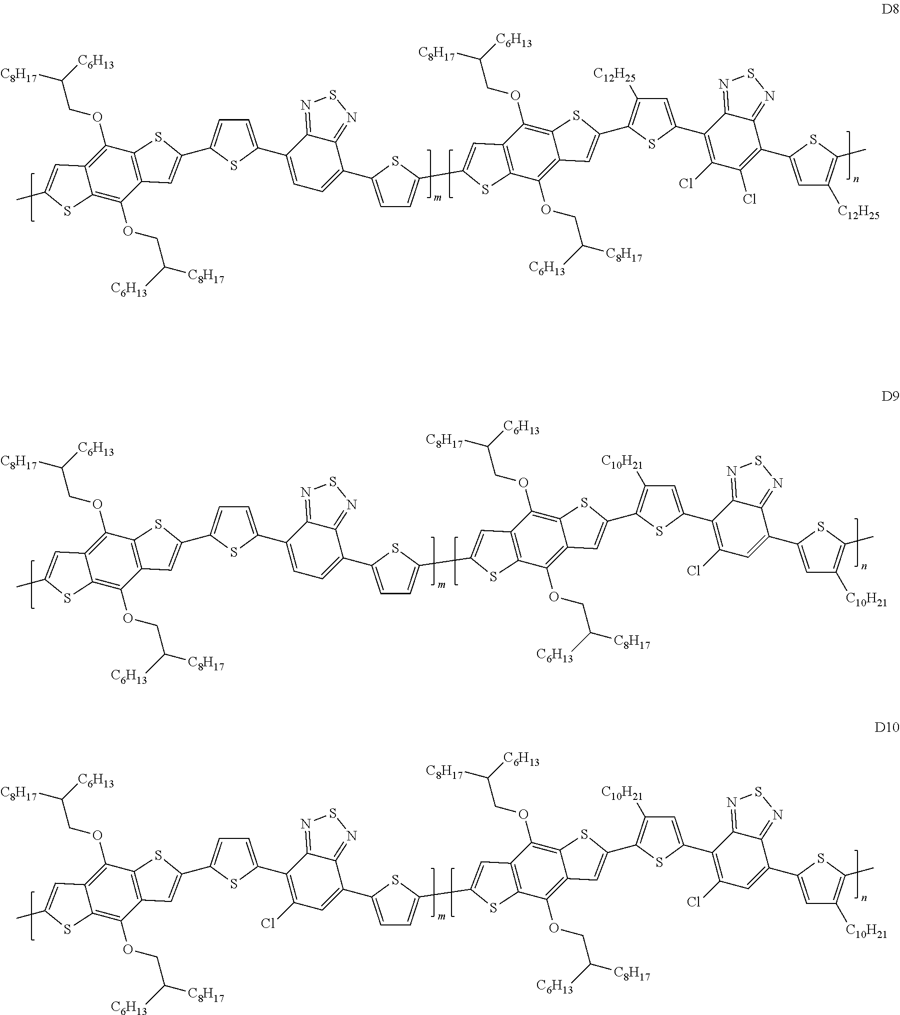

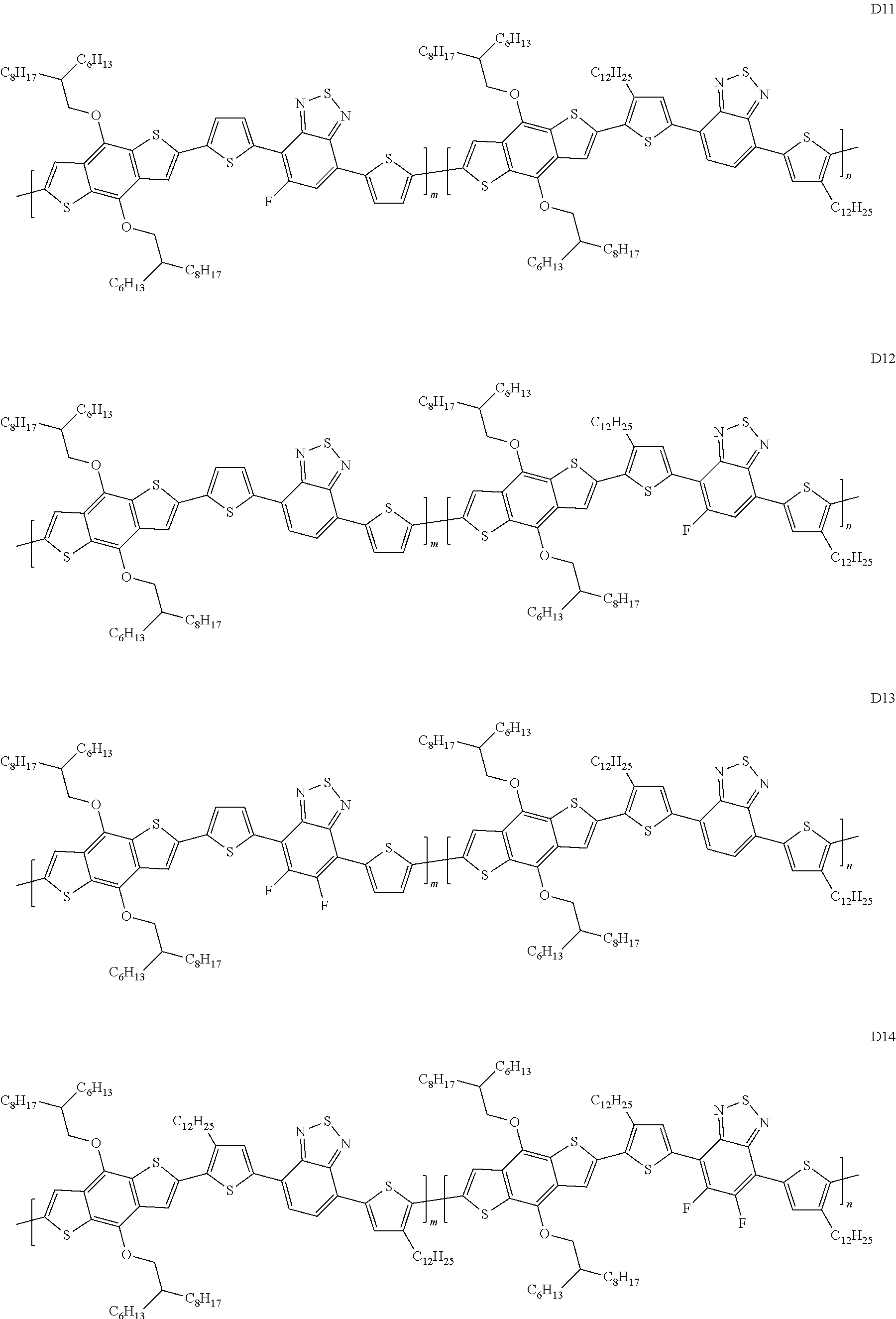

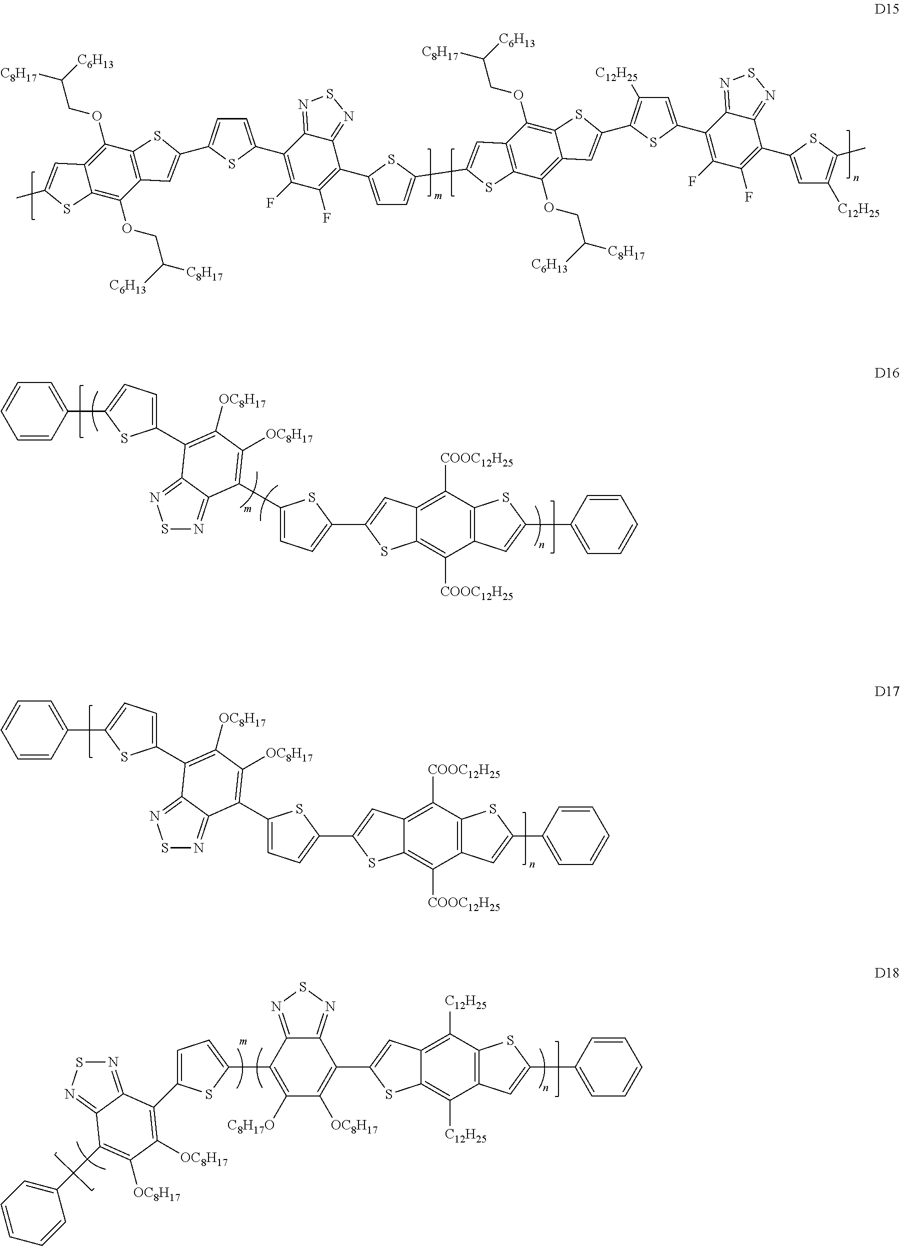

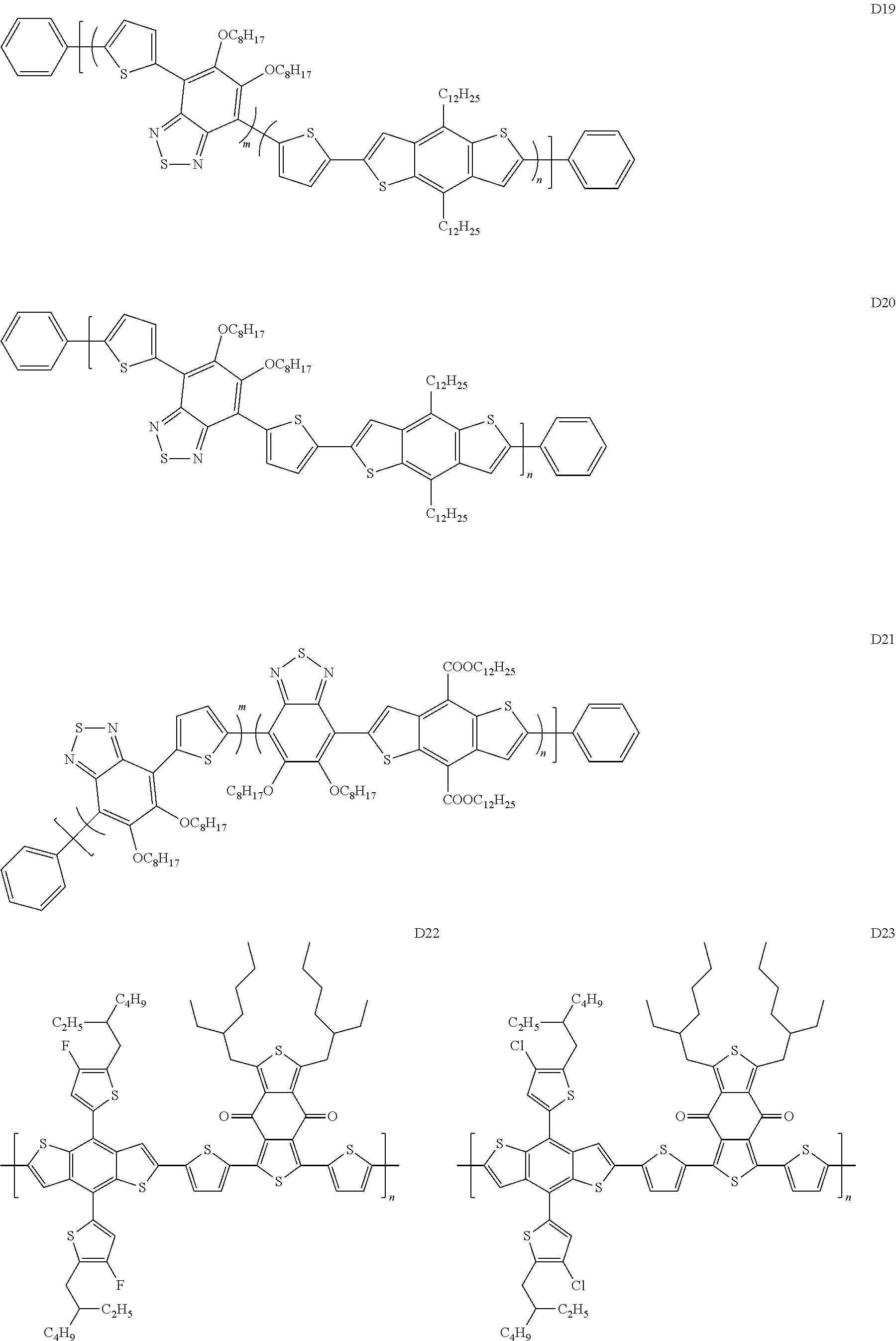

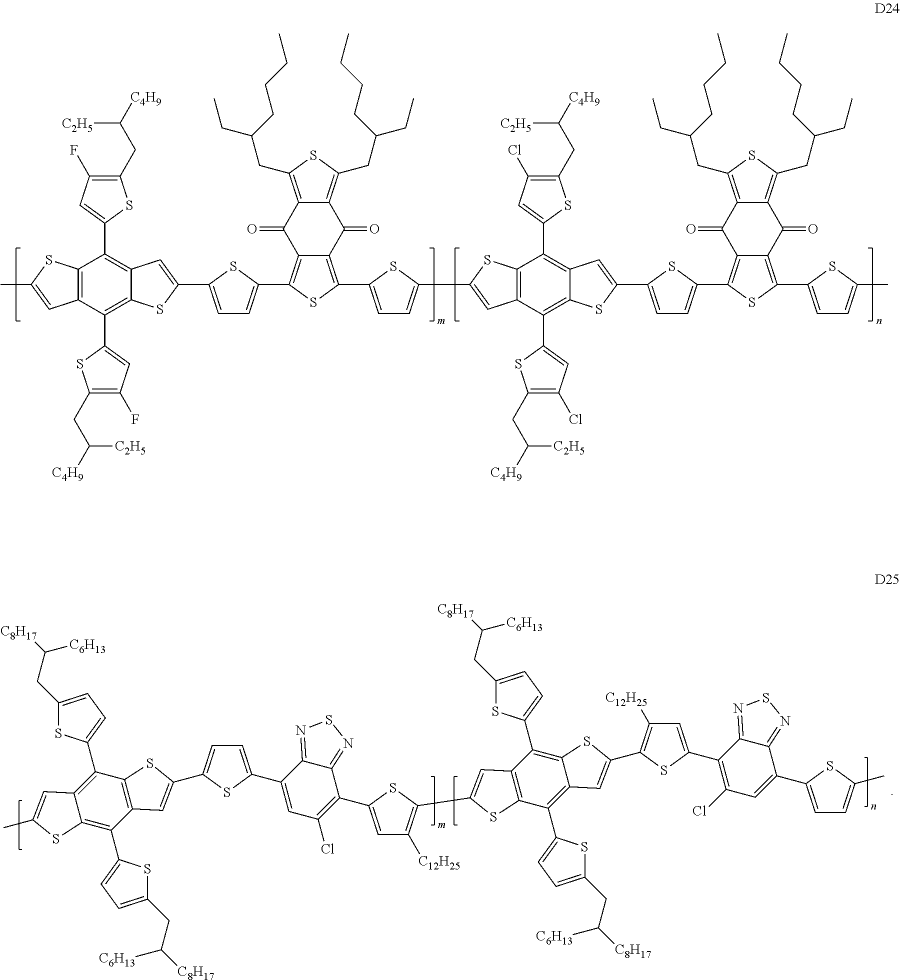

6. The organic semiconductor device according to claim 1, wherein the electron acceptor includes a first electron acceptor and a second electron acceptor.

7. The organic semiconductor device according to claim 6, wherein the first electron acceptor is selected from the group consisting of the following chemical structures A1-A25:

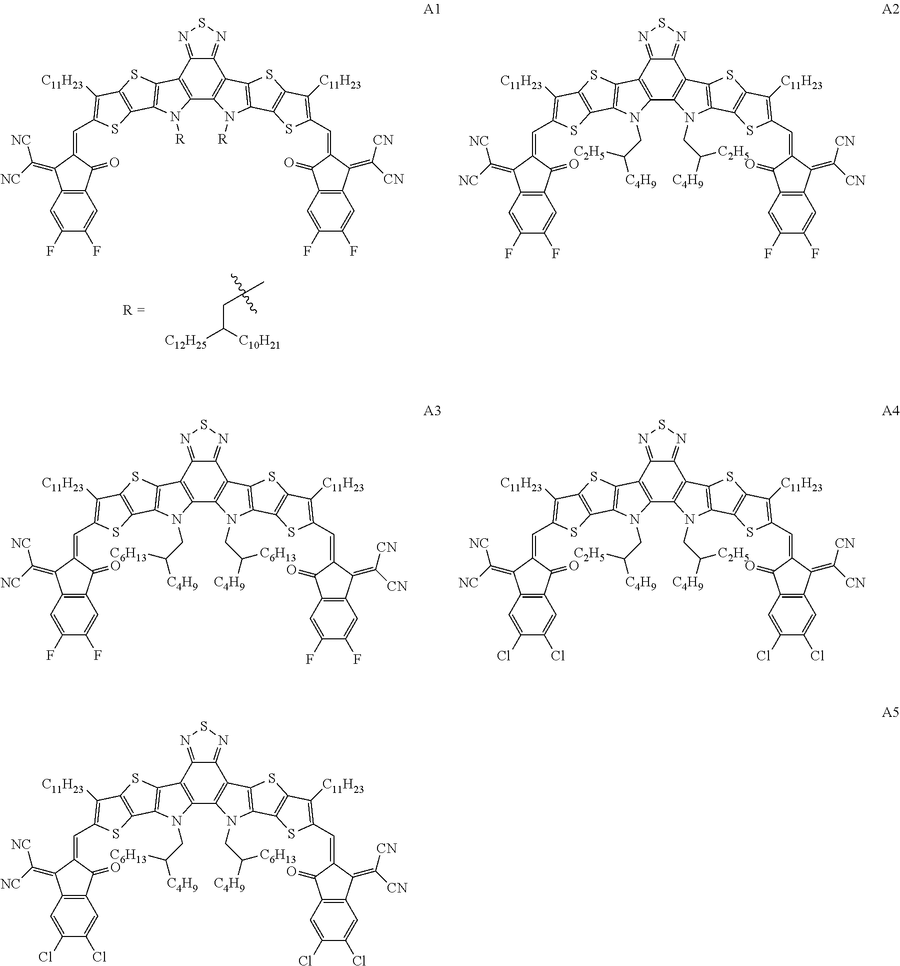

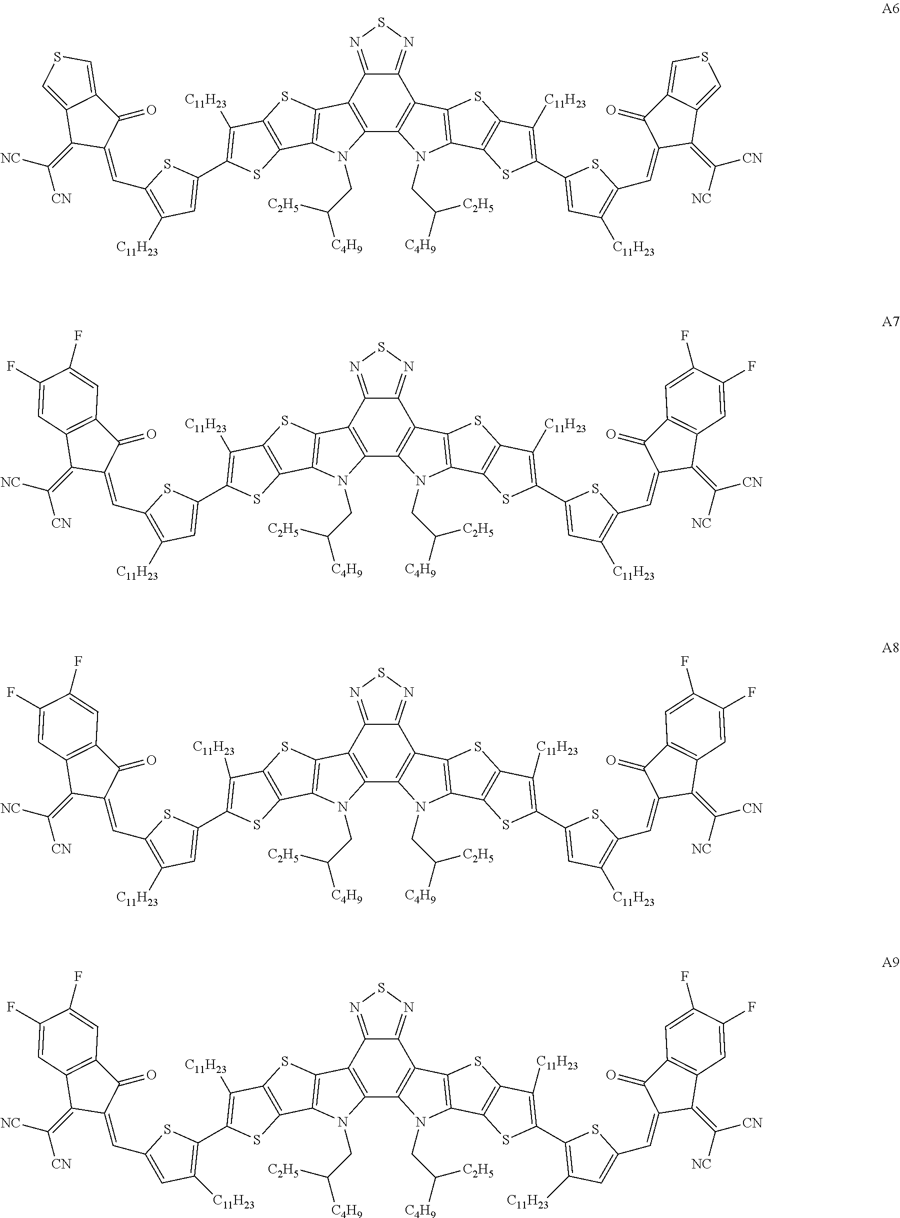

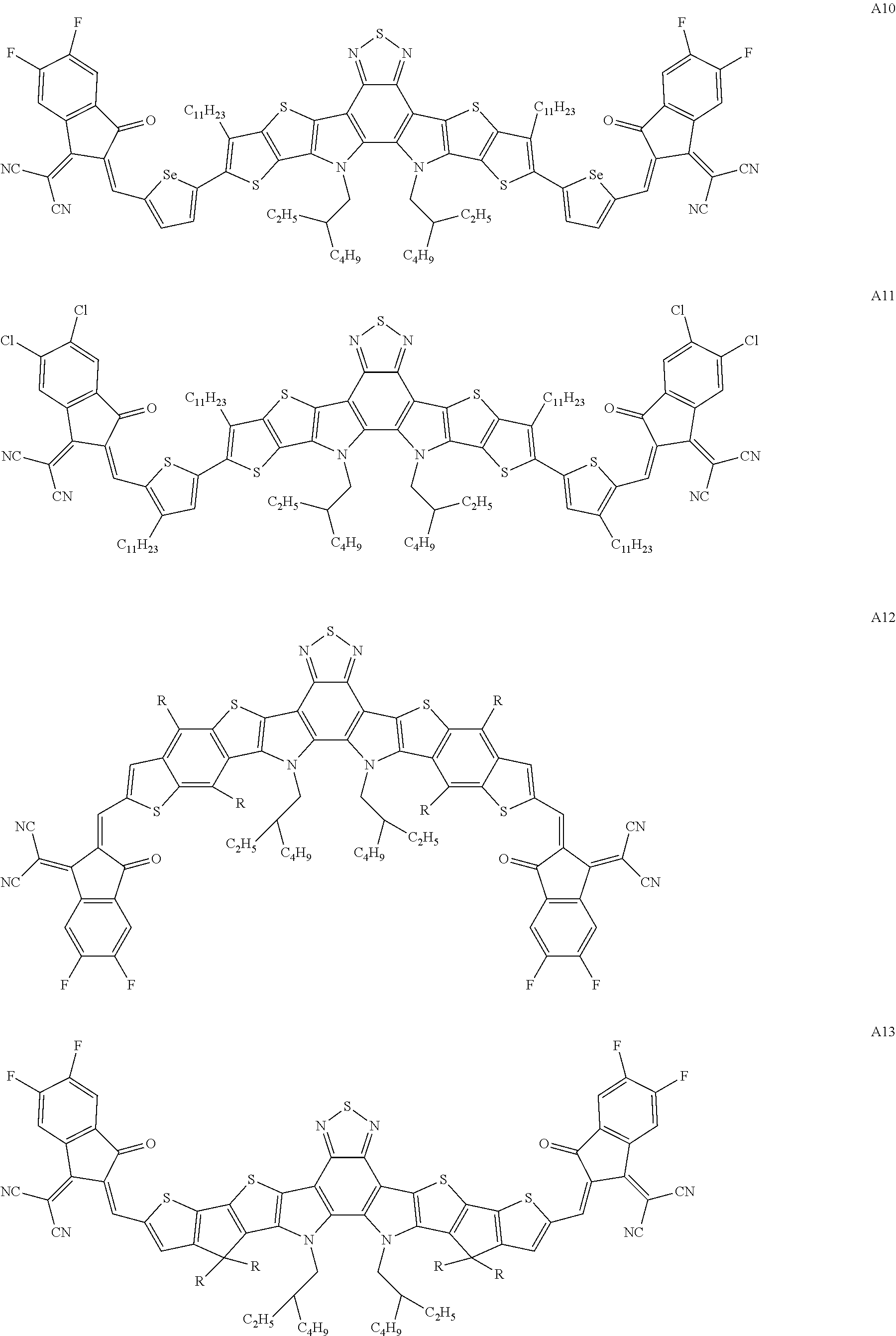

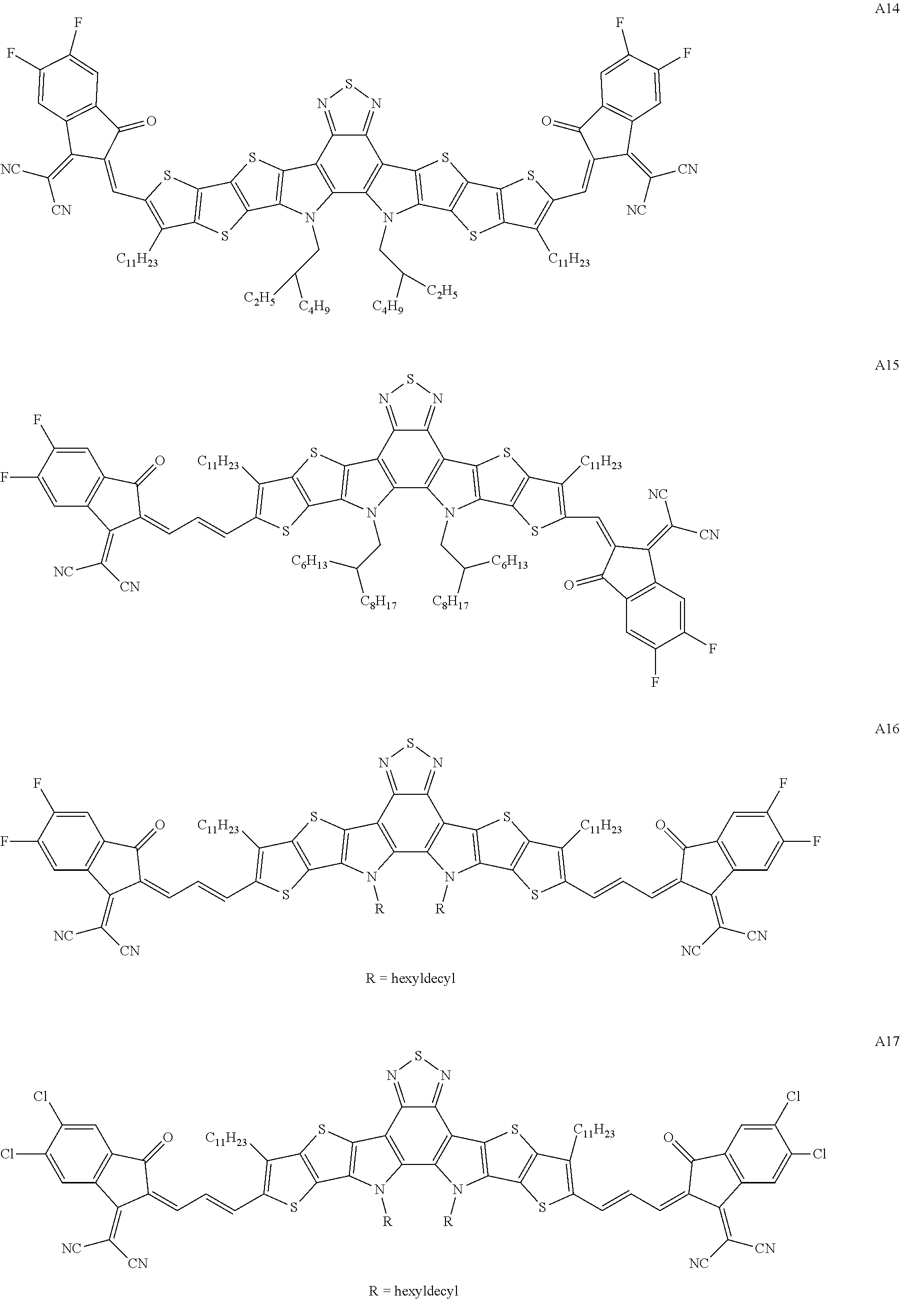

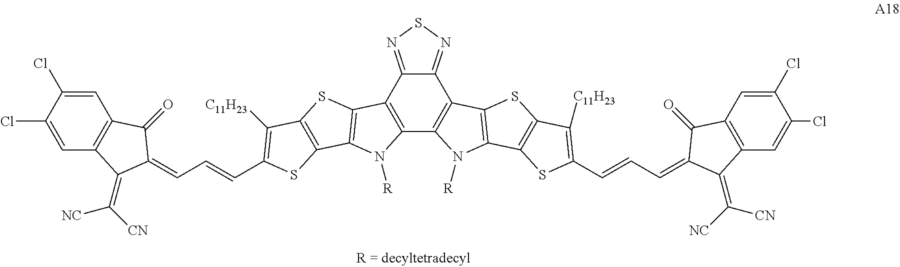

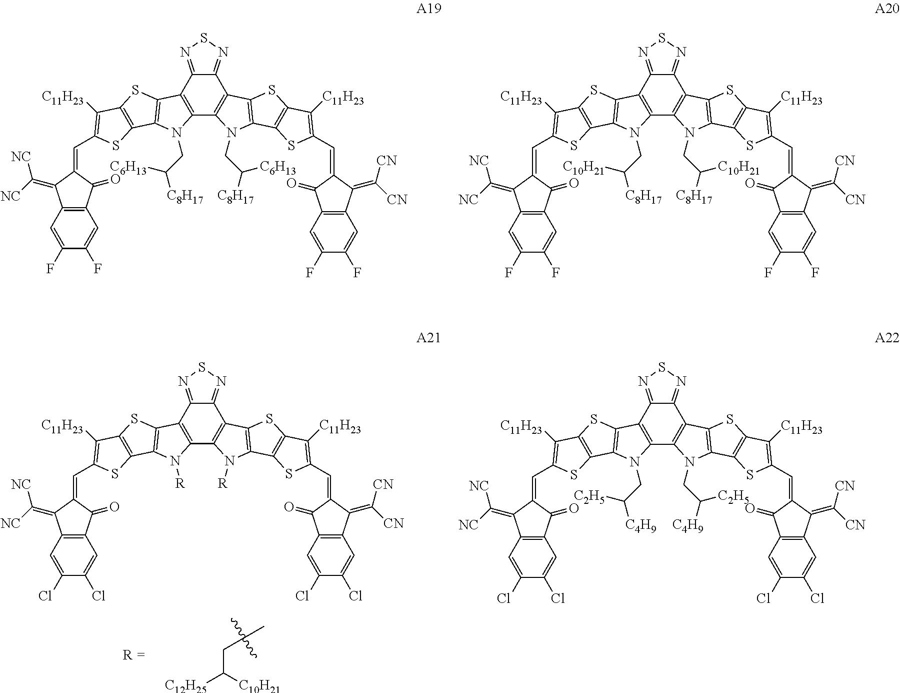

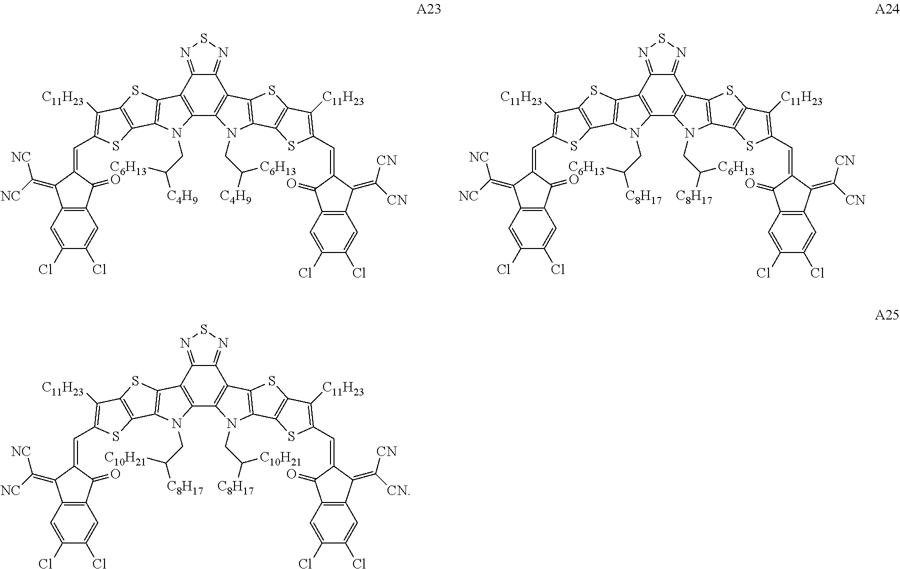

8. The organic semiconductor device according to claim 6, wherein the second electron acceptor is selected from the group consisting of the following chemical structures A26-A40:

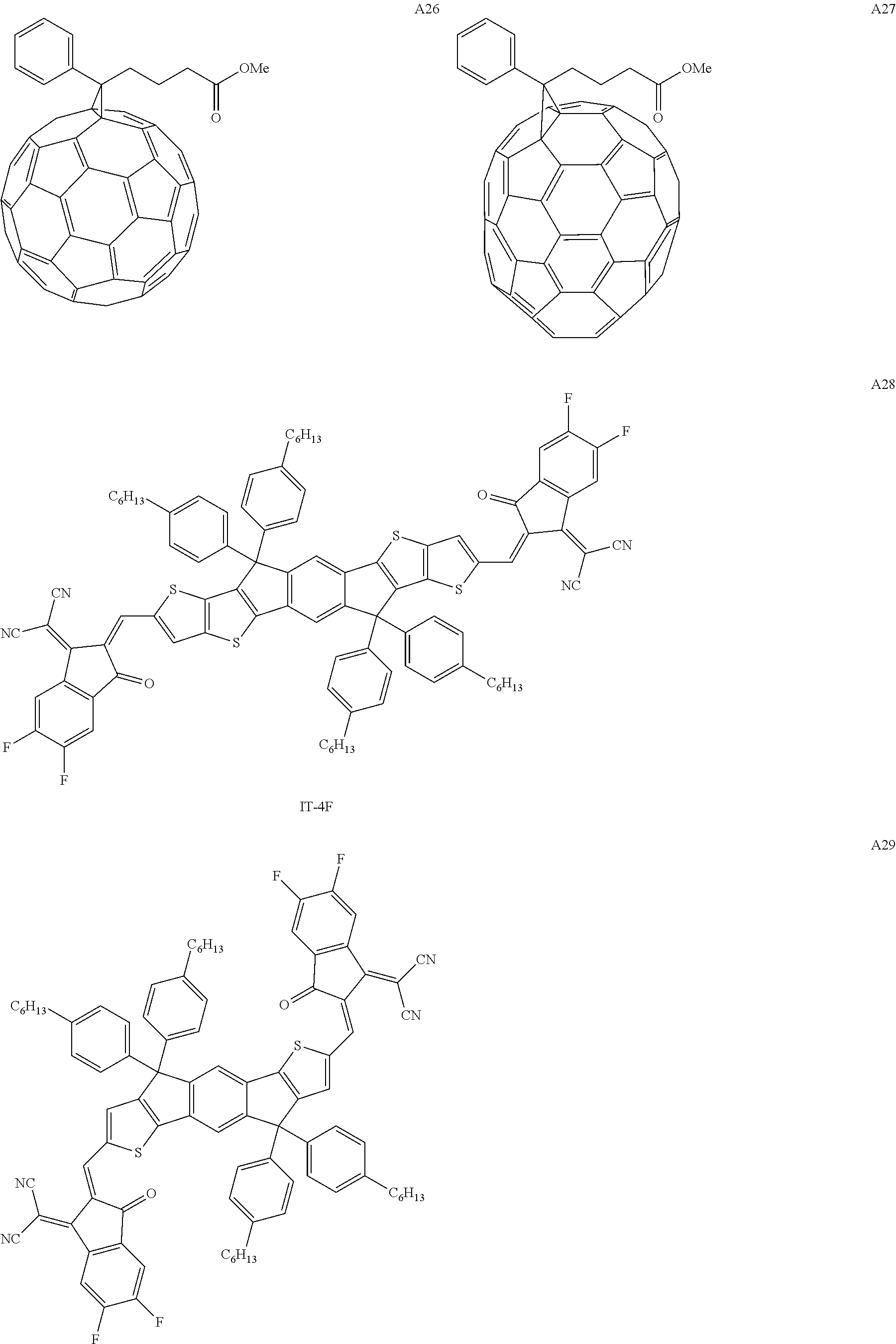

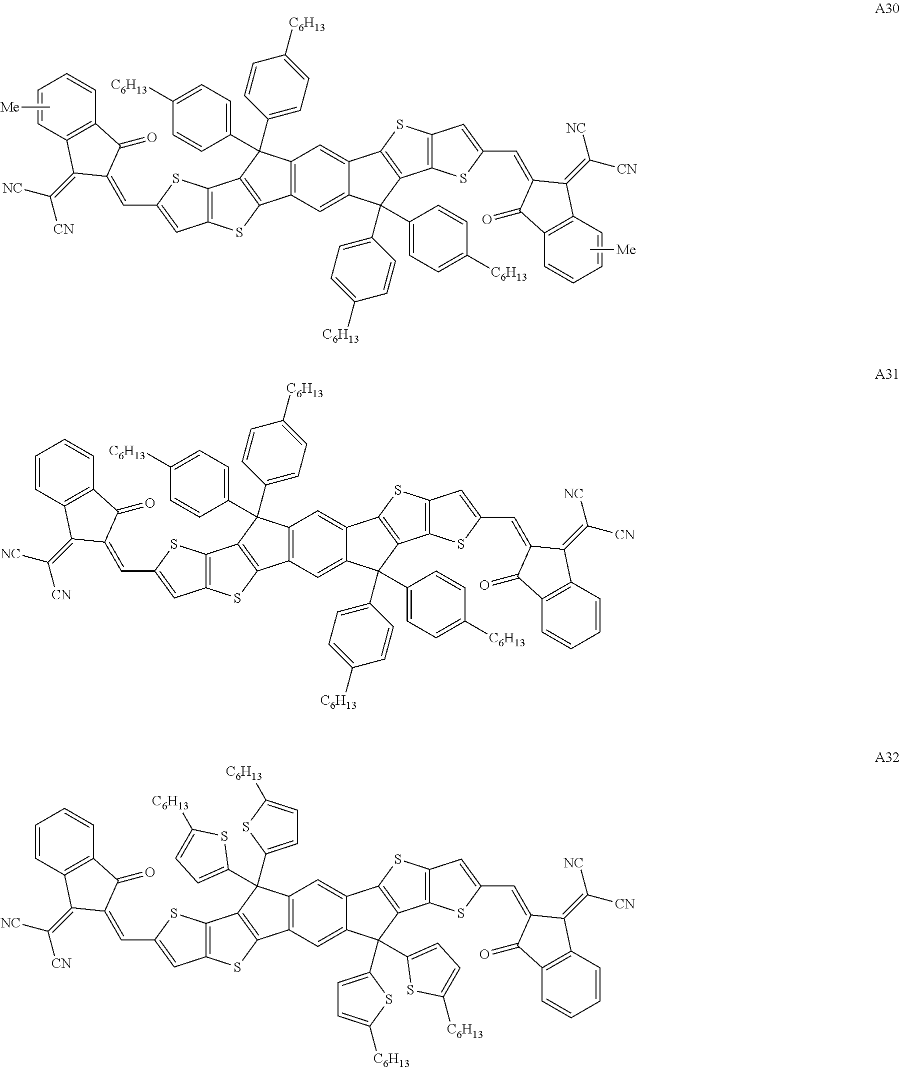

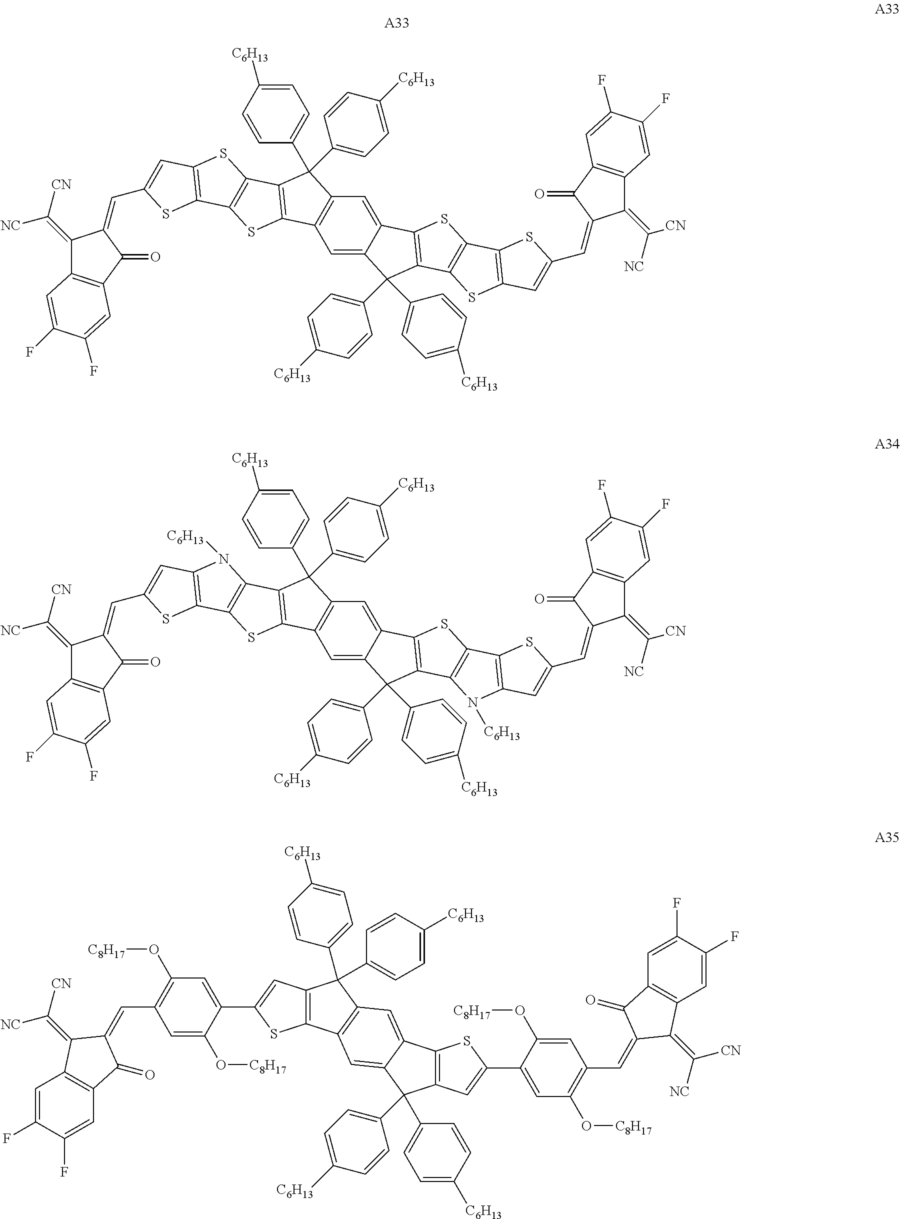

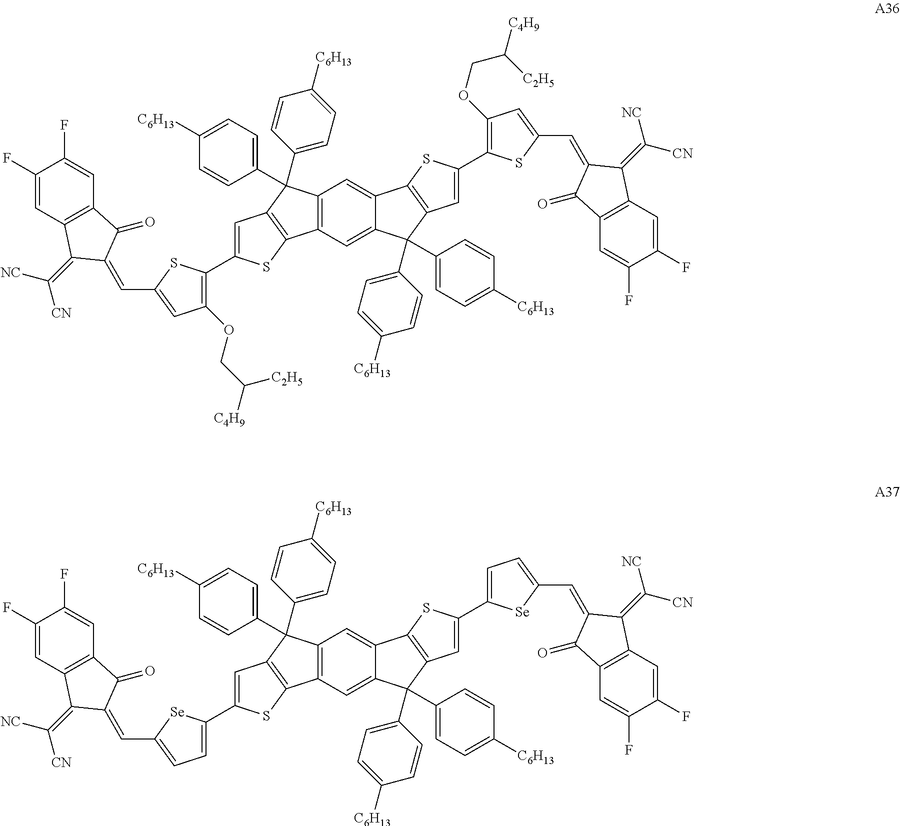

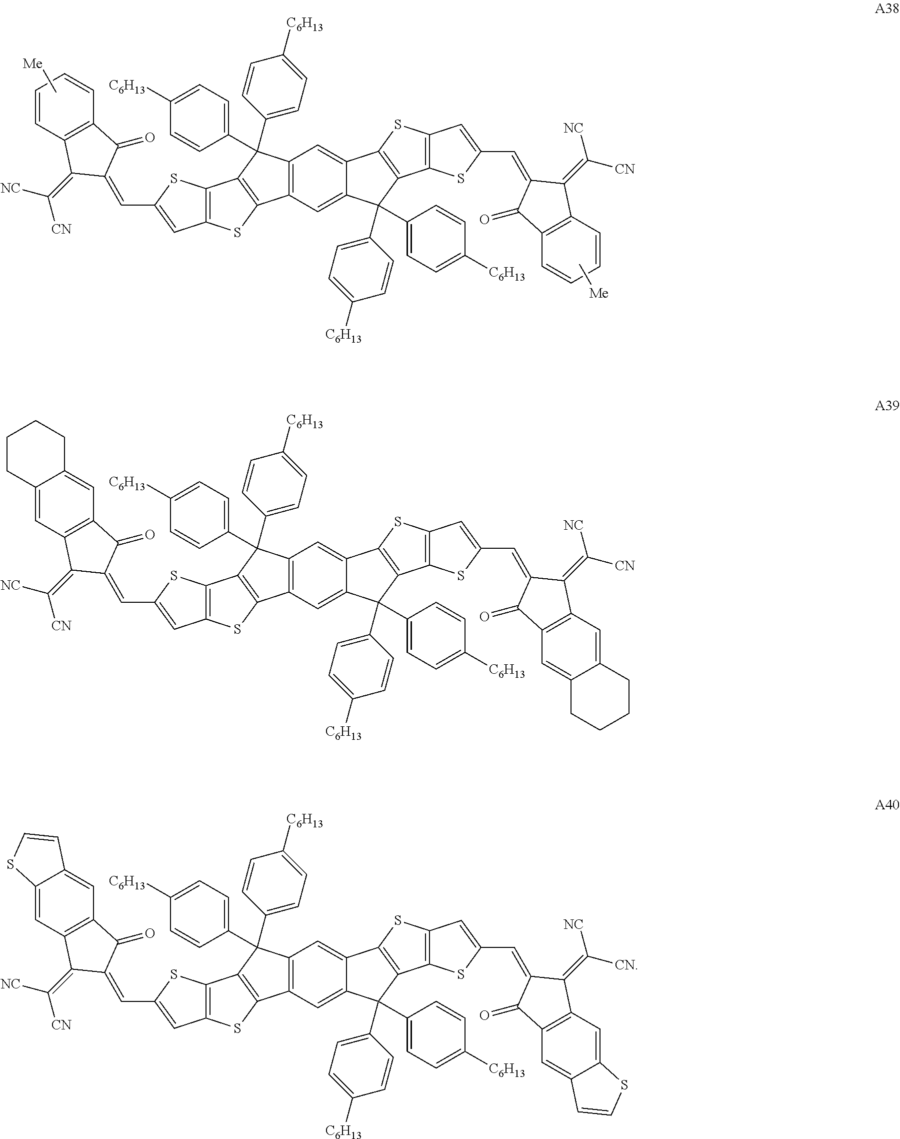

9. The organic semiconductor device according to claim 6, wherein weight ratio of the second electron acceptor is less than weight ratio of the first electron acceptor.

10. The organic semiconductor device according to claim 1, wherein the hole transport layer of the organic semiconductor device is prepared by wet processes.

11. The organic semiconductor device according to claim 1, wherein the band gap of the electron donor is greater than 1.50 eV and the band gap of the first electron acceptor is less than 1.49 eV.

12. The organic semiconductor device according to claim 1, wherein a material for the first electrode is selected from the group consisting of indium oxides, tin oxides, derivatives of fluorine doped tin oxide (FTO), indium tin oxide (ITO), and indium zinc oxide (IZO).

13. The organic semiconductor device according to claim 1, wherein a material for the second electrode is selected from silver or aluminum.

14. The organic semiconductor device according to claim 1, wherein the organic semiconductor device is selected from the group consisting of organic field-effect transistor (OFET), integrated circuit (IC), thin-film transistor (TFT), radio frequency identification (RFID) tags, organic light-emitting diode (OLED), organic light-emitting transistor (OLET), electroluminescent display (ELD), organic photovoltaic (OPV) cells, and organic solar cells (OSC), flexible OPV and OSC, organic laser diodes (O-laser), organic integrated circuit (OIC), light devices, sensors, electrode materials, photoconductors, light sensors, electro-optical recording devices, capacitors, charge injection layers, Schottky diodes, planarization layers, antistatic films, conductive substrates, conductive patterns, organic memory, biosensors, and biochips.

15. An organic semiconductor formulation comprising an electron donor and at least one electron acceptor according to claim 1, wherein the formulation contains at least one aromatic solvent.

16. The organic semiconductor formulation according to claim 15, wherein the aromatic solvent is selected from the group consisting of: methylbenzene, ortho-xylene, para-xylene, meta-xylene, trimethylbenzenes, chlorobenzene, dichlorobenzene, trichlorobenzene or tetrahydronaphthalene, anisole, methoxytoluene and derivatives thereof, naphthalene, 1-methylnaphthalene and derivatives thereof.
